(19) United States
(12) Patent Application Publication
(10) Pub. No.: US 2008/0100199 A1
(43) Pub. Date: May 1, 2008

(54) Polymer Material and Device Using the Same

(76) Inventors: Chizu Sekine, Ibaraki (JP); Satoshi Mikami, Ibaraki (JP)

Correspondence Address: SUGHRUE MION, PLLC, 2100 PENNSYLVANIA AVENUE, N.W., SUITE 800, WASHINGTON, DC, 20037, US

(21) Appl. No.: 11/720,214

(22) PCT Filed: Dec. 6, 2005
(86) PCT No.: PCT/JP05/22728

§ 371 Date: Jun. 1, 2007

(30) Foreign Application Priority Data
Dec. 7, 2004 (JP) 2004-354115

(51) Int. Cl. H01J 1/62; C08L 45/00

(52) U.S. Cl. 313/498; 525/211

(57) ABSTRACT

Provided is a polymer material comprising a conjugated polymer and a dendrimer, which can give a light-emitting device excellent in practical utilities such as a capability of driving at lower voltage and the like when it is used for a light-emitting layer of a device.

### TECHNOLOGICAL FIELD

The present invention relates to a polymer material and a device using the same.

### BACKGROUND ART

Recently, a dendrimer is paid to attention as a functional material for device, and for example, as a material for polymer light-emitting device (polymer LED), there is known a polymer material comprising a dendrimer having a metal complex in a light-emitting core, and a non-conjugated polymer (Thin Solid Films vol. 416, p 212 (2002)).

The polymer light-emitting device using the above-mentioned polymer material was not practically sufficient in its performances such as rising of its driving voltage, etc.

### DISCLOSURE OF THE INVENTION

The object of the present invention is to provide a polymer material containing a dendrimer which can give a device excellent in practical utilities such as a capability of driving at lower voltage and the like when it is used in a device.

That is, the present invention provides a polymer material comprising a conjugated polymer (A) and a dendrimer (B).

### BEST MODES FOR CARRYING OUT THE INVENTION

The polymer material of the present invention comprises a conjugated polymer (A) and a dendrimer (B).

The dendrimer (B) may be contained in the molecule of the conjugated polymer (A) or may be contained as a mixture, and embodiments of the polymer material of the present invention include:

(i) a polymer material which is a composition comprising a conjugated polymer (A) and a dendrimer (B), and

(ii) a polymer material which comprises a polymer containing a structure of a conjugated polymer (A) and a structure of a dendrimer (B) in the same molecule. As (ii), there are mentioned, for example: a polymer material comprising a polymer containing a structure of a dendrimer (B) in the main chain of a conjugated polymer (A); a polymer material comprising a polymer containing a structure of a dendrimer (B) at the end of a conjugated polymer (A); a polymer material comprising a polymer containing a structure of a dendrimer (B) in the side chain of a conjugated polymer (A); and the like.

Among the polymer materials of the present invention, those satisfying the following formula (Eq1) are preferred.

ET_{A}−ES_{A0}≧(ET_{B}−ES_{B0})−0.2 eV (Eq1).

Here, ES_{A0} represents energy in the ground state of the conjugated polymer (A), ET_{A} represents energy in the lowest excited triplet state of the conjugated polymer (A), ES_{B0} represents energy in the ground state of the dendrimer (B) and ET_{B} represents energy in the lowest excited triplet state of the dendrimer (B).

Energy differences in (Eq1) between the ground state and the lowest excited triplet state, as for each of the conjugated polymer (A) and the dendrimer (B) showing light emission from the triplet excited state (ET_{A}−ES_{A0}, and ET_{B}−ES_{B0}, in this order) are determined by some actual measurement methods, however, in the present invention, relative magnitude correlation between the above-mentioned energy difference of the dendrimer (B) and the above-mentioned energy difference of the conjugated polymer (A) to be used as a matrix is usually important for obtaining higher light emission efficiency, thus, the differences are determined by computational chemical means.

Among others, it is preferred for obtaining higher light emission efficiency that the following formula (Eq1-2) is further satisfied in a range for satisfying the above-mentioned formula (Eq1).

ET_{A}−ES_{A0}≧ET_{B}−ES_{B0} (Eq1-2)

Here, ET_{A}, ES_{A0}, ET_{B} and ES_{B0} represent the same meanings as described above.

Further, it is preferred for obtaining higher light emission efficiency that:

an energy difference ET_{AB} between energy ET_{A} in the lowest excited triplet state of the conjugated polymer (A) and energy ET_{B} in the lowest excited triplet state of the dendrimer (B), and a difference EH_{AB} between the highest occupied molecular orbital (HOMO) energy EH_{A} in the ground state of the conjugated polymer (A) and the HOMO energy ET_{B} in the ground state of the dendrimer (B), satisfy the relation of

ET_{AB}≧EH_{AB} (Eq2);

and

the lowest excited singlet level ES_{A1} of the conjugated polymer (A), and the lowest excited singlet level ES_{B1} of the dendrimer (B) satisfy the relation of

ES_{A1}≧ES_{B1} (Eq3).

As the computational chemical means for calculating an energy difference between the vacuum level and LUMO, there are known a molecular orbital method, density function method and the like based on semi-empirical methods and non-empirical methods. For example, for obtaining excitation energy, the Hartree-Fock (HF) method or density function method may be used. Usually, using a quantum chemical calculation program Gaussian 98, obtained were an energy difference between the ground state and the lowest excited triplet state (hereinafter, referred to as lowest excited triplet energy), an energy difference between the ground state and the lowest excited singlet state (hereinafter, referred to as lowest excited singlet energy), HOMO energy level in the ground state and LUMO energy level in the ground state, of a triplet light-emitting compound and a conjugated polymer.

Calculations of the lowest excited triplet energy, lowest excited singlet energy, HOMO energy level in the ground state and LUMO energy level in the ground state of a conjugated polymer were performed for a monomer (n=1), a dimmer (n=2) and a trimer (n=3), and for the excitation energy of a conjugated polymer, a method was used in which results when n=1 to 3 are treated by a function E(1/n) for 1/n (wherein, E represents an excitation energy value to be obtained such as the lowest excited singlet energy, lowest excited triplet energy and the like) and extrapolated linearly into n=0. When a side chain having large chain length and the like, for example, is contained in a repeating unit of a conjugated polymer, the side chain portion of a chemical structure to be calculated can be simplified as a minimum unit (for example, when an octyl group is present as a side chain, the side chain is calculated as a methyl group). Further, for HOMO, LUMO, singlet excitation energy and triplet excitation energy of a copolymer, the minimum unit estimated from the copolymerization ratio is used as a unit, and the same calculation method can be used as for the above-described case of a homopolymer.

The conjugated polymer (A) contained in a polymer material of the present invention will be described.

The conjugated polymer is a molecule containing multiple bonds and single bonds long connected repeatedly as described, for example, in “Yuki EL no hanashi” (edited by Katsumi Yoshino, Nikkan Kogyo Shinbun, Ltd.), page 23, and mentioned as typical examples are polymers containing a repeating structure of the following structure and a structure including the following structures combined appropriately.

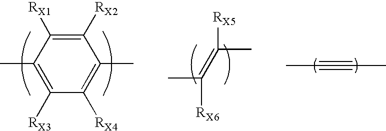

(wherein, the above-described R_{X1} to R_{X6} represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group or substituted silyloxy group, and R₁ to R₄ and R₅₁ to R₇₃ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group or halogen atom.)

As the conjugated polymer (A), those containing no aromatic ring in the main chain (for example, polyacetylenes) and those containing an aromatic ring in the main chain are mentioned.

Of those containing an aromatic ring in the main chain, polymers characterized by comprising at least one of repeating units of the following formula (1), (3), (4), (5) or (6) are mentioned, and further, those containing a repeating unit of the following formula (1) are preferable from the standpoint of high light emission efficiency.

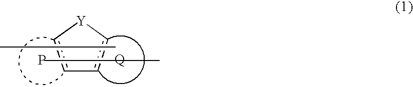

(wherein, the P ring and Q ring each independently represent an aromatic ring, but the P ring may be either existent or non-existent. Two connecting bonds exist on the P ring and/or Q ring when the P ring exists, and exist on the 5-membered ring containing Y and/or Q ring when the P ring does not exist. Further, a substituent may exist on the aromatic ring and/or 5-membered ring containing Y. Y represents —O—, —S—, —Se—, —B(R₃₁)—, —C(R₁)(R₂)—, —Si(R₁)(R₂)—, —P(R₃)—, —PR₄(═O)—, —C(R₅₁)(R₅₂)—C(R₅₃)(R₅₄)—, —O—C(R₅₅)(R₅₆)—, —S—C(R₅₇)(R₅₈)—, —N—C(R₅₉)(R₆₀)—, —Si(R₆₁)(R₆₂)—C(R₆₃)(R₆₄)—, —Si(R₆₅)(R₆₆)—, Si(R₆₇)(R₆₈)—, —C(R₆₉)═C(R₇₀)—, —N═C(R₇₁)—, or —Si (R₇₂)═C(R₇₃)—, R₃₁ represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group or substituted silyloxy group, and R₁ to R₄ and R₅₁ to R₇₃ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group or halogen atom.)

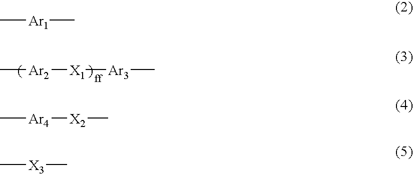

(wherein, Ar₁, Ar₂, Ar₃ and Ar₄ each independently represent an arylene group, divalent heterocyclic group or divalent group having a metal complex structure. X₁, X₂ and X₃ each independently represent —CR₁₅═CR₁₆—, —C═C—, —N(R₁₇)— or —(SiR₁₈R₁₉)_{ff}—. R₁₅ and R₁₆ each independently represent a hydrogen atom, alkyl group, aryl group, monovalent heterocyclic group, carboxyl group, substituted carboxyl group or cyano group. R₁₇, R₁₈ and R₁₉ each independently represent a hydrogen atom, alkyl group, aryl group, monovalent heterocyclic group, arylalkyl group or substituted amino group. ff represents 1 or 2. m represents an integer of 1 to 12. When R₁₅, R₁₆, R₁₇, R₁₈ and R₁₉ are present each in plural number, they may be the same or different.).

As the aromatic ring in the above-described formula (1), mentioned are aromatic hydrocarbon rings such as a benzene ring, naphthalene ring and the like; and heteroaromatic rings such as a pyridine ring, bipyridine ring, phenanthroline ring, quinoline ring, isoquinoline ring, thiophene ring, furan ring, pyrrole ring and the like.

It is preferable that the above-mentioned repeating unit of the formula (1) has, as a substituent, a group selected from alkyl groups, alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, acyloxy group, imine residue, amide group, acid imide group, monovalent heterocyclic group, carboxyl group and substituted carboxyl groups.

As the above-mentioned structure of the formula (1), mentioned are structures of the following formula (1-1), (1-2) or (1-3):

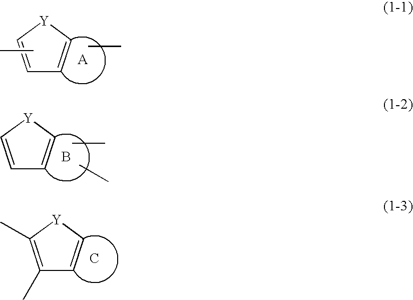

(wherein, the A ring, B ring and C ring each independently represent an aromatic ring. The formula (1-1), formula (1-2) and (1-3) may each have a substituent selected from the group consisting of alkyl groups, alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, halogen atoms, acyl group, acyloxy group, imine residue, amide group, acid imide group, monovalent heterocyclic group, carboxyl group, substituted carboxyl groups and cyano group. Y represents the same meaning as described above.).

Mentioned are structures of the following formula (1-4) or (1-5):

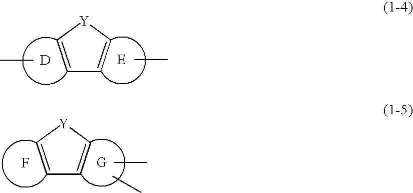

(wherein, the D ring, E ring, F ring and G ring each independently represent an aromatic ring optionally having a substituent selected from the group consisting of alkyl groups, alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, halogen atoms, acyl group, acyloxy group, imine residue, amide group, acid imide group, monovalent heterocyclic group, carboxyl group, substituted carboxyl groups and cyano group. Y represents the same meaning as described above.), and preferable are structures of the formula (1-4) or (1-5).

It is preferable for obtaining high light emission efficiency that Y represents —S—, —O— or —C(R₁)(R₂)—, and further preferably, Y represents —S— or —O—. Here, R₁ and R₂ represent the same meanings as described above.

As the aromatic ring in the above-mentioned formulae (1-1), (1-2), (1-3), (1-4) and (1-5), mentioned are aromatic hydrocarbon rings such as a benzene ring, naphthalene ring, anthracene ring, tetracene ring, pentacene ring, pyrene ring, phenanthrene ring and the like; and heteroaromatic rings such as a pyridine ring, bipyridine ring, phenanthroline ring, quinoline ring, isoquinoline ring, thiophene ring, furan ring, pyrrole ring and the like.

It is preferable that the repeating unit of the formulae (1-1), (1-2), (1-3), (1-4) and (1-5) has as a substituent a group selected from alkyl groups, alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, acyloxy group, imine residue, amide group, acid imide group, monovalent heterocyclic group, carboxyl group and substituted carboxyl groups.

Among specific examples of the formula (1-1), examples as described below are mentioned as those having no substituent.

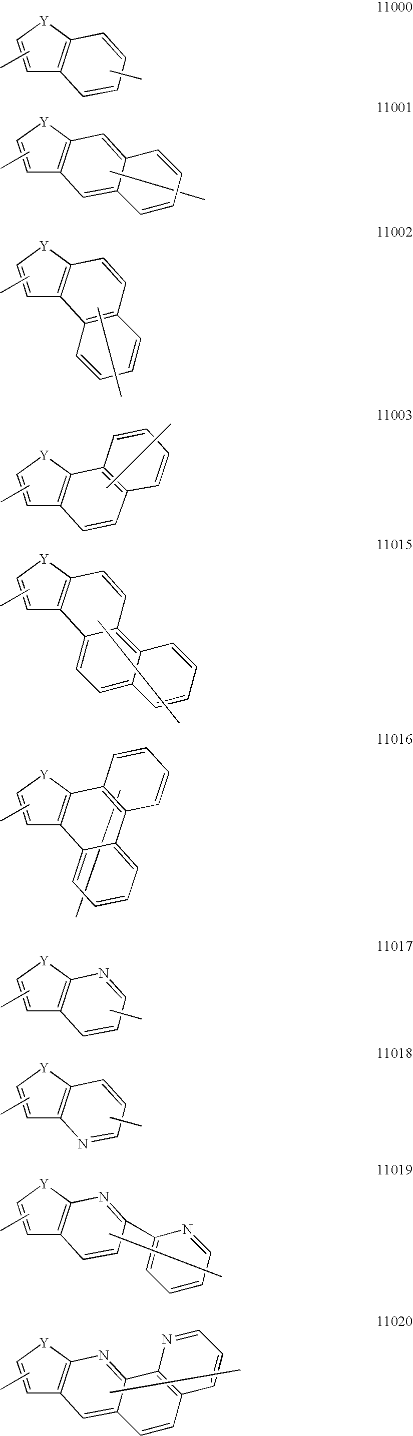

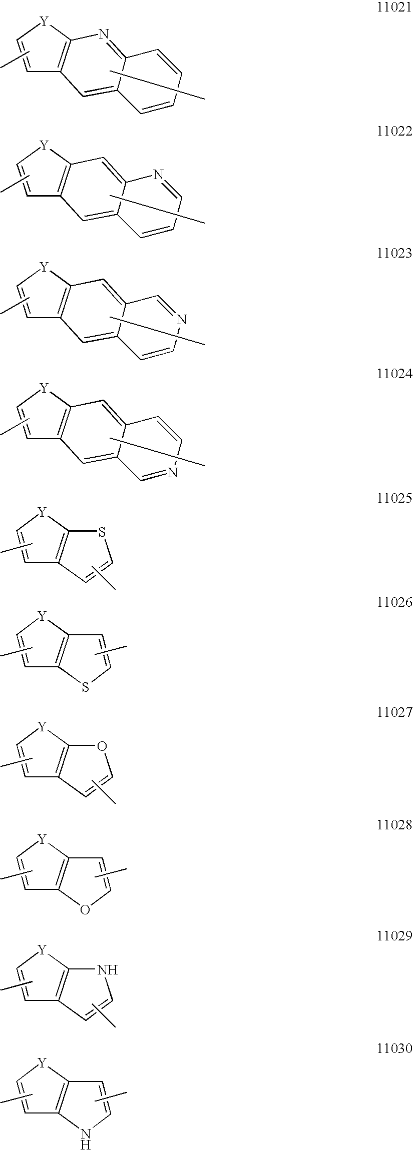

As specific examples of the formula (1-2), examples as described below are mentioned as those having no substituent.

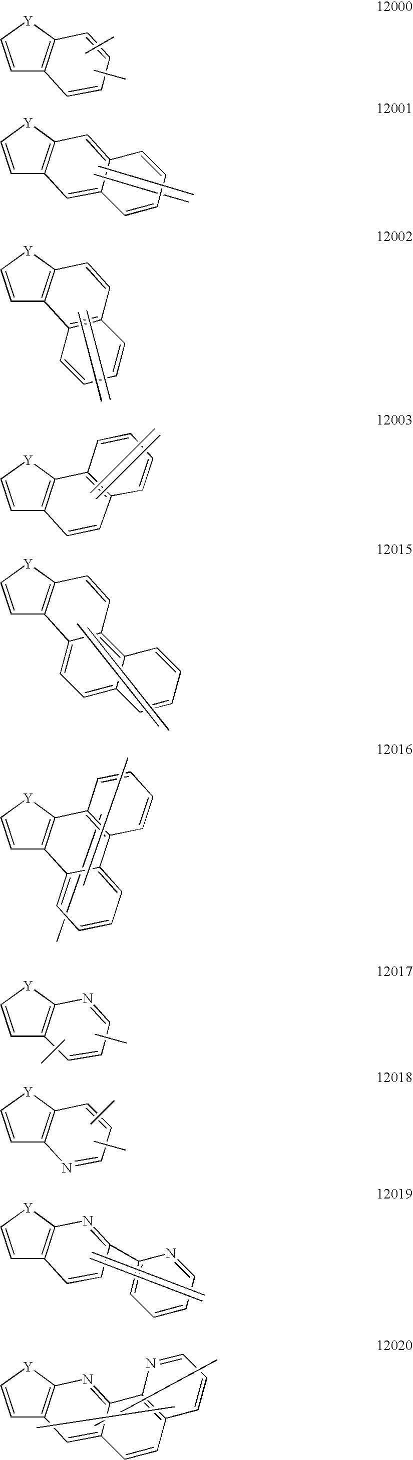

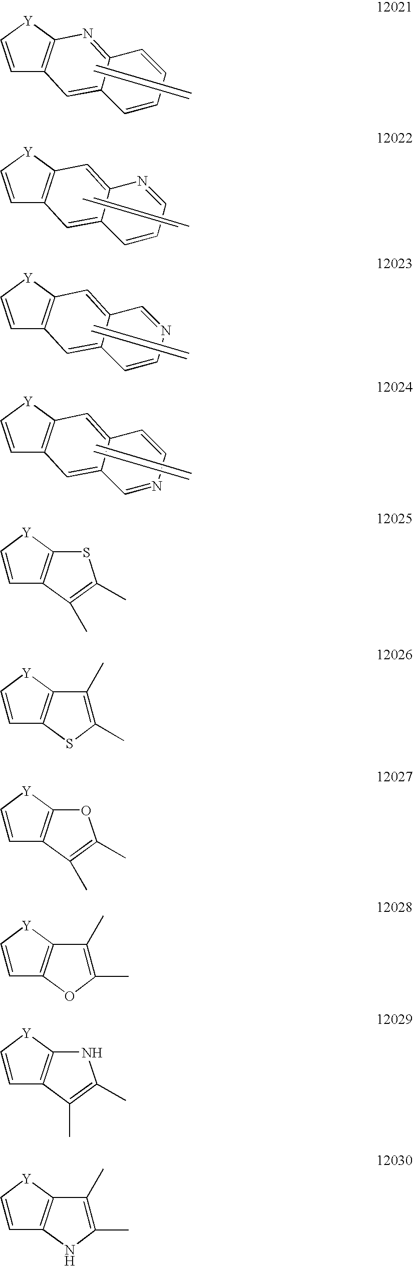

As specific examples of the formula (1-3), examples as described below are mentioned as those having no substituent.

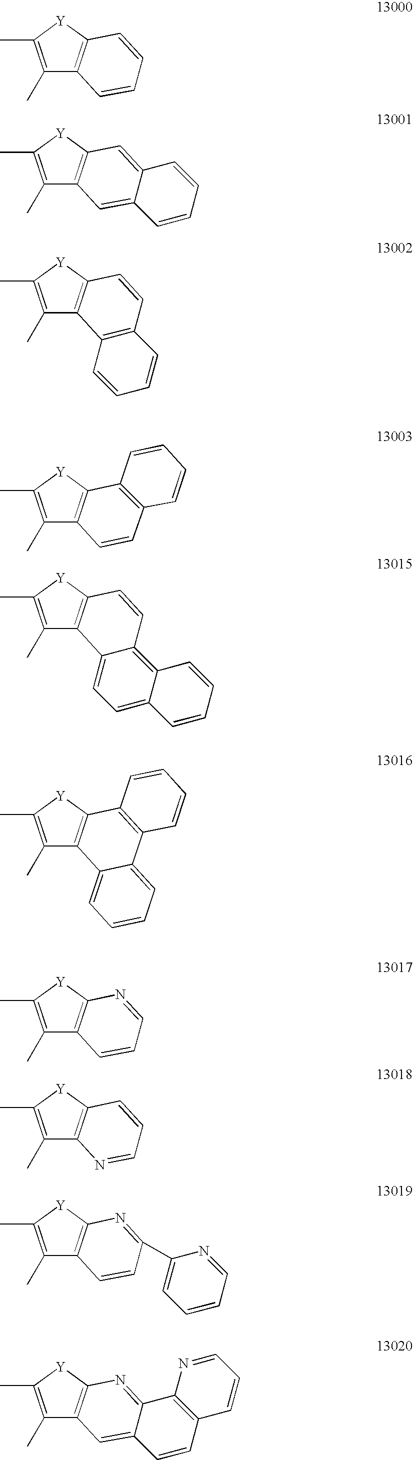

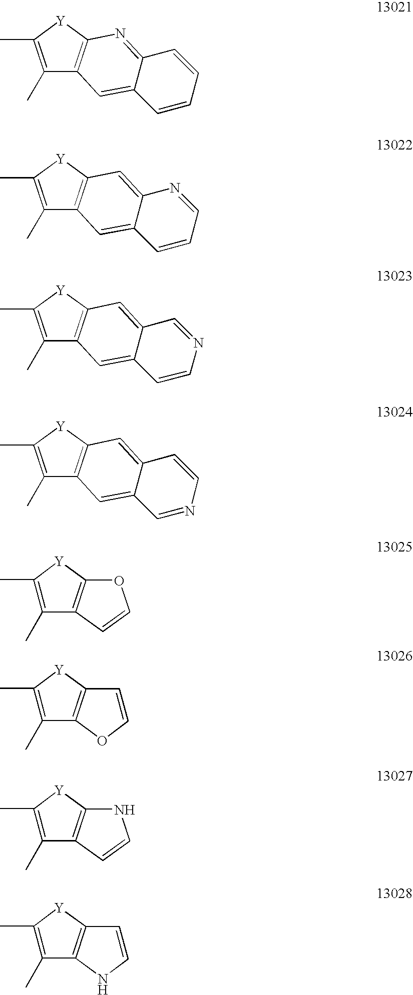

As specific examples of the formula (1-4), examples as described below are mentioned as those having no substituent.

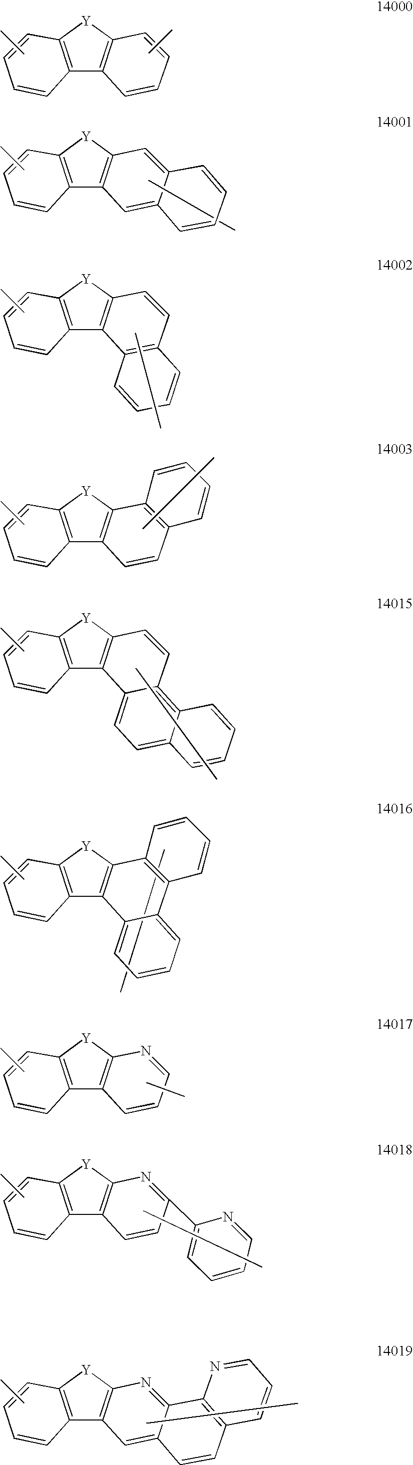

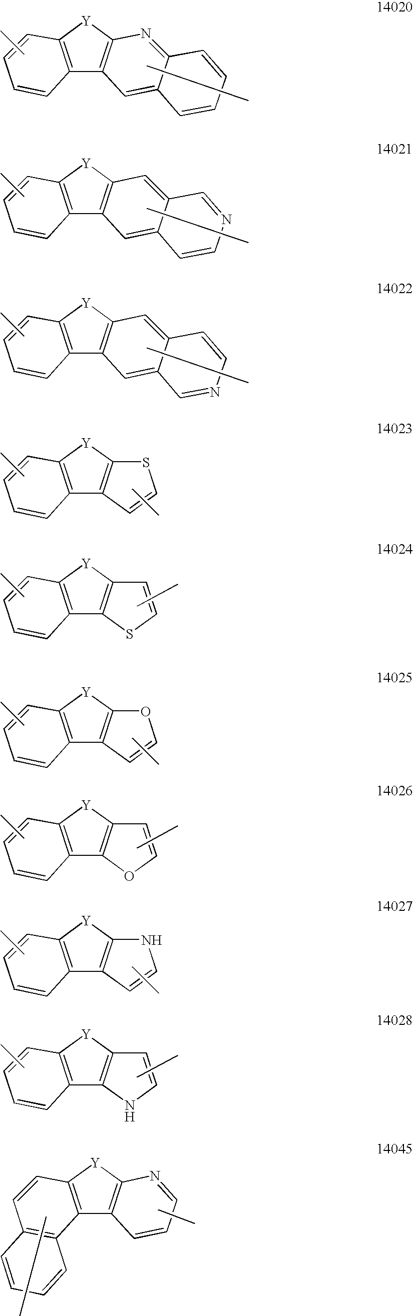

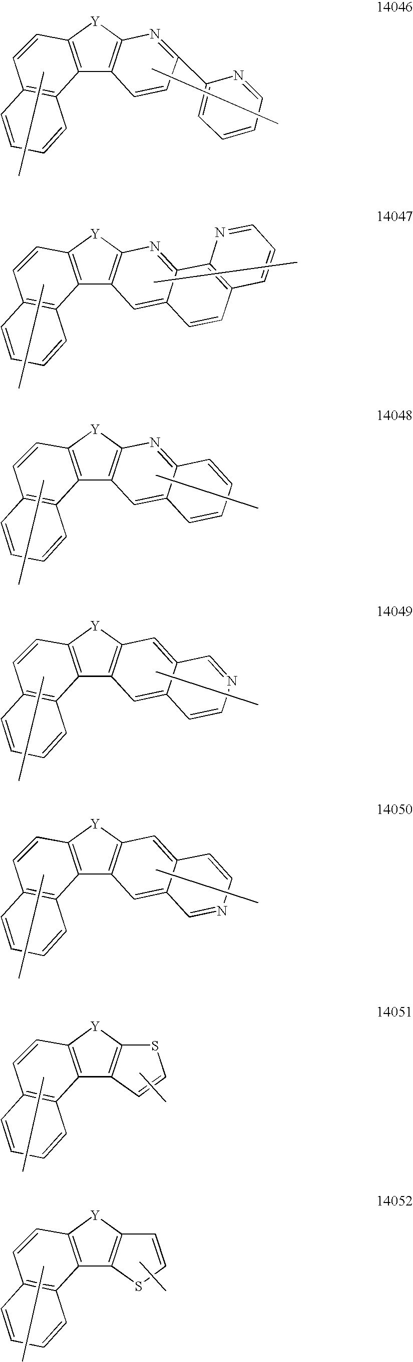

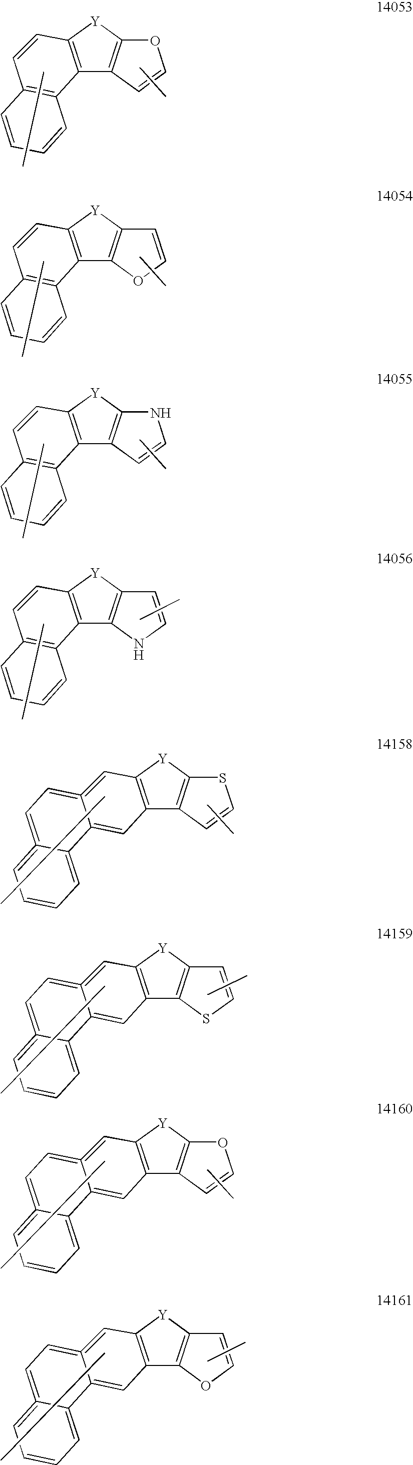

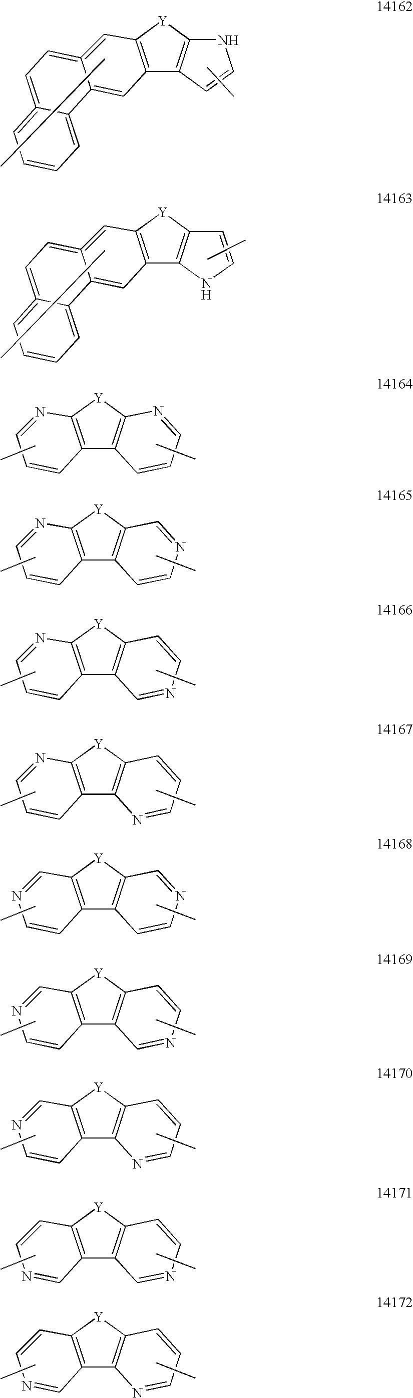

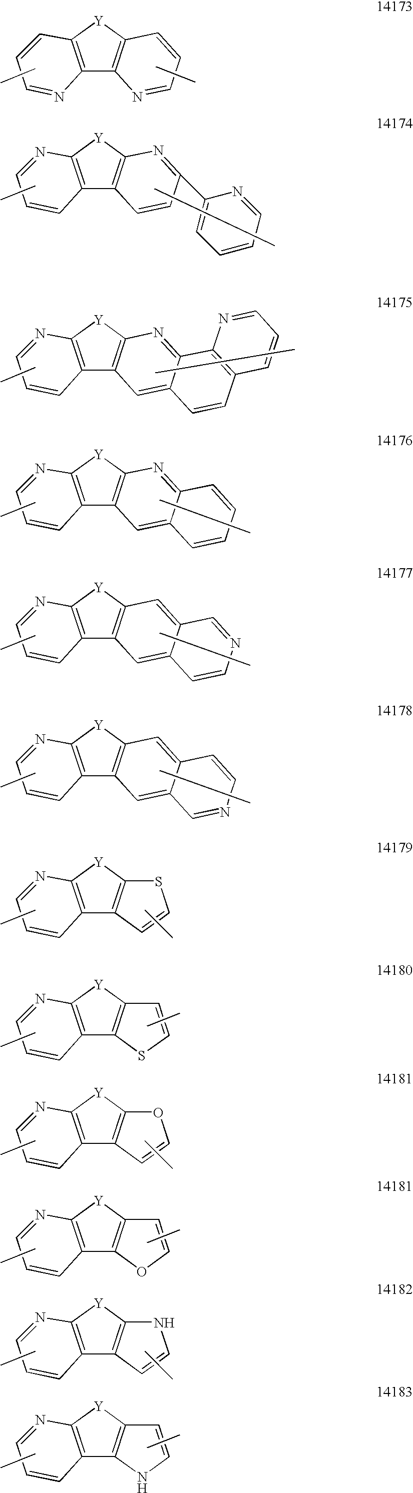

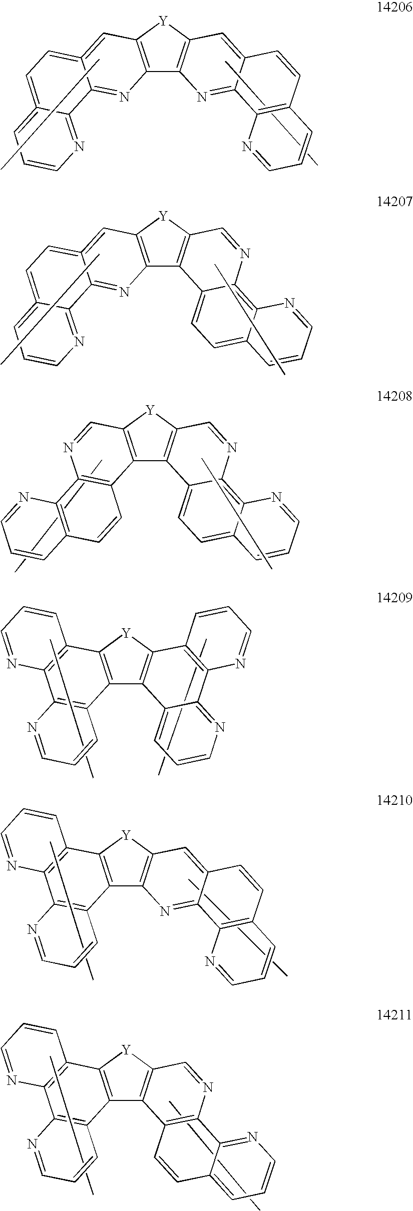

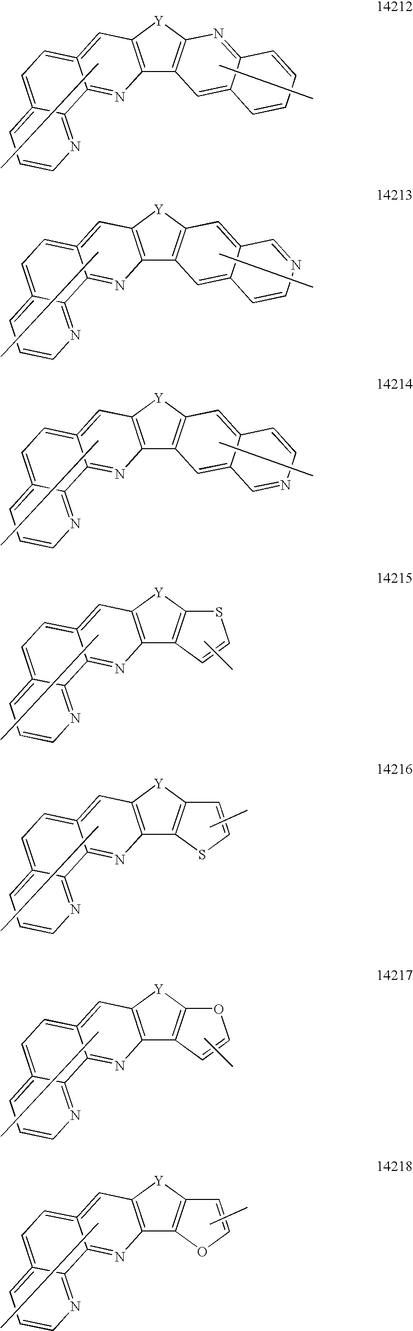

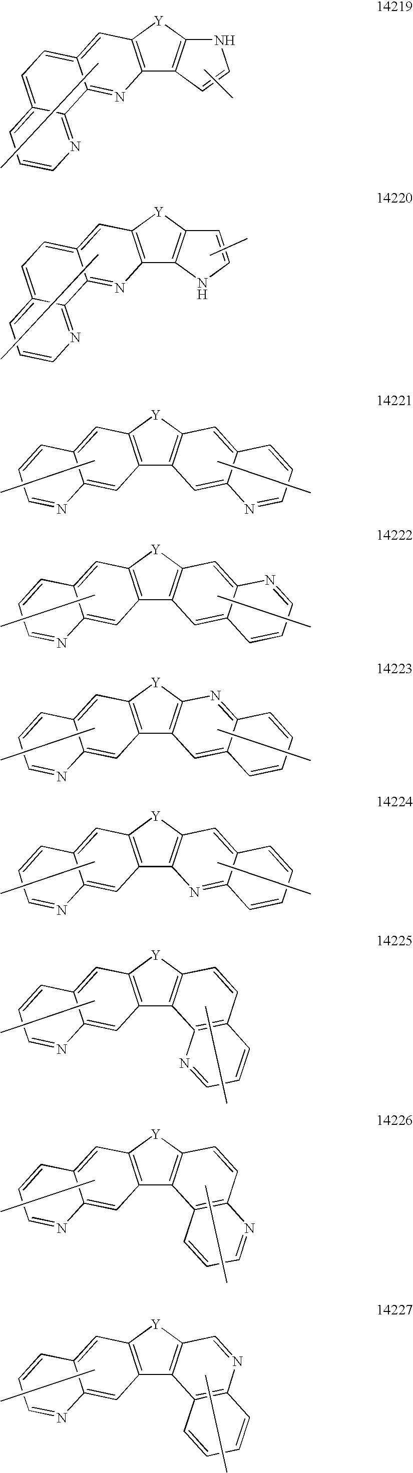

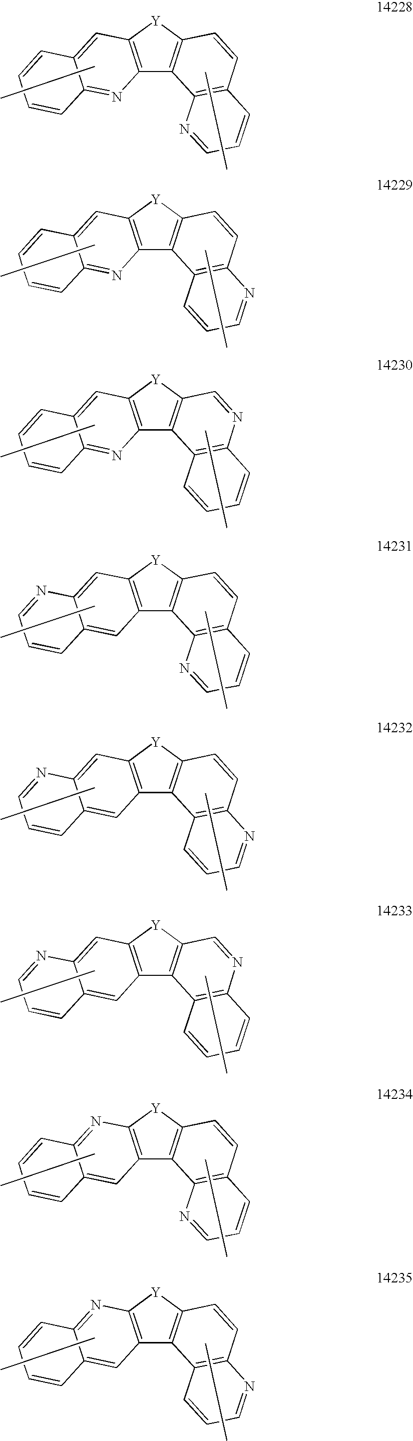

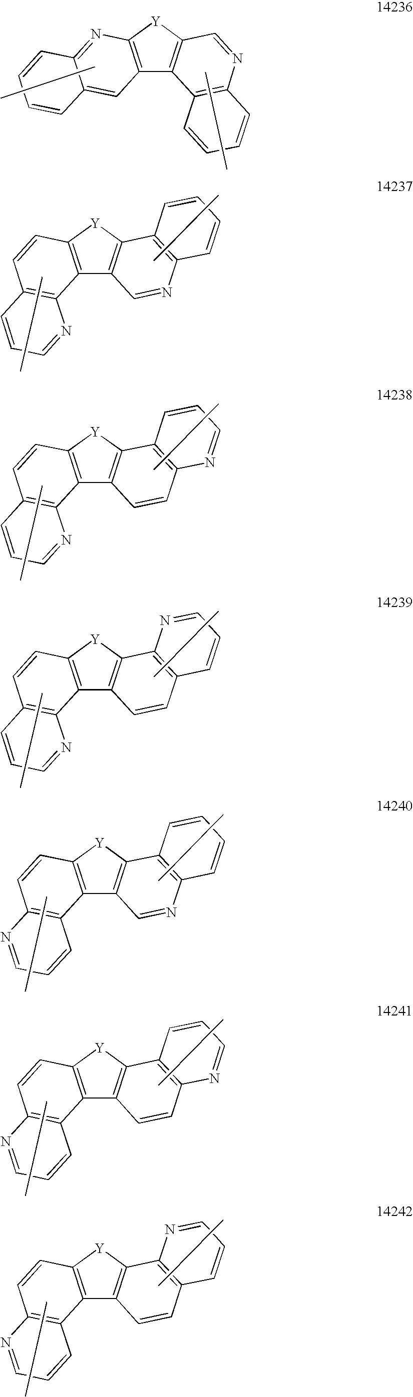

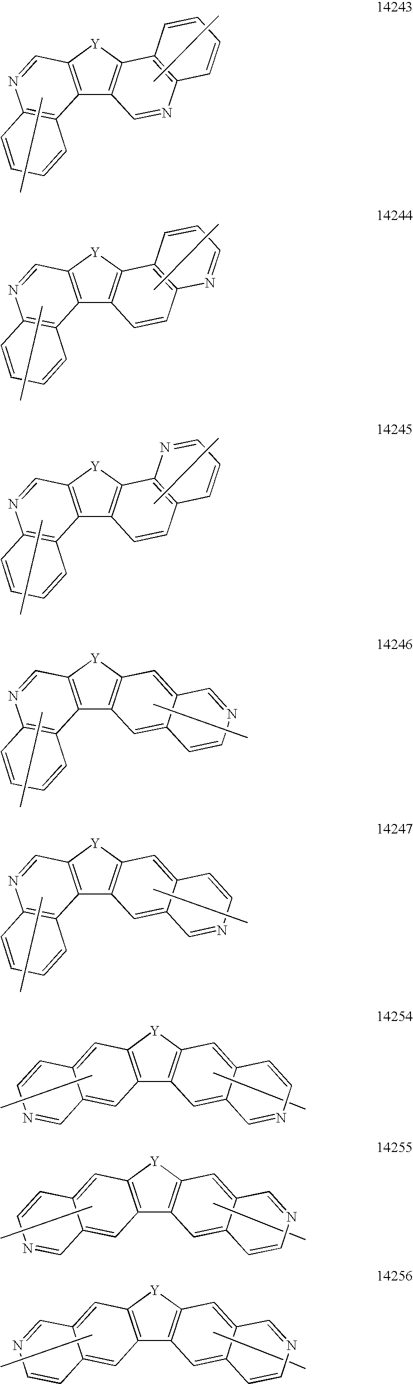

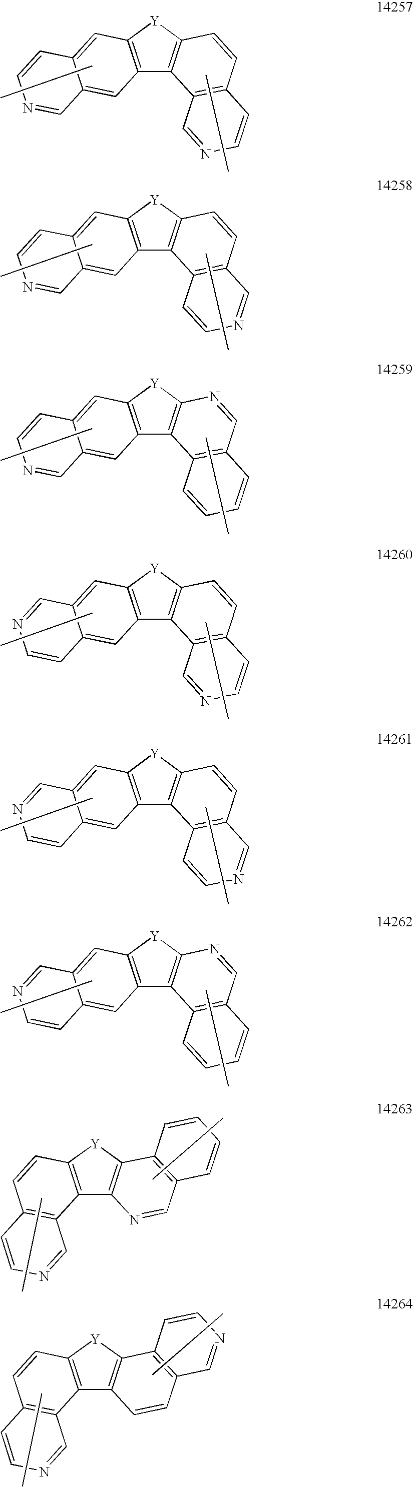

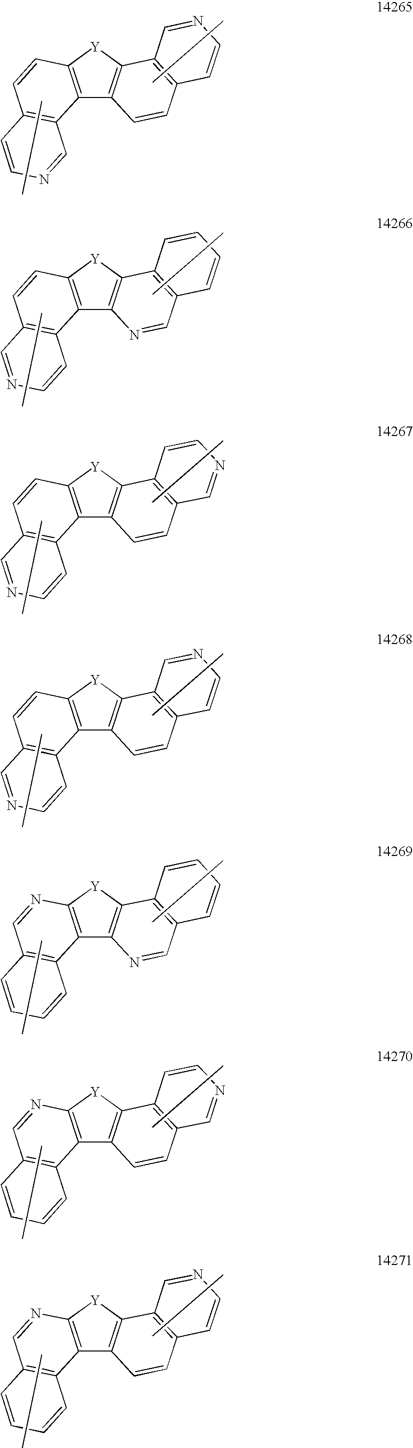

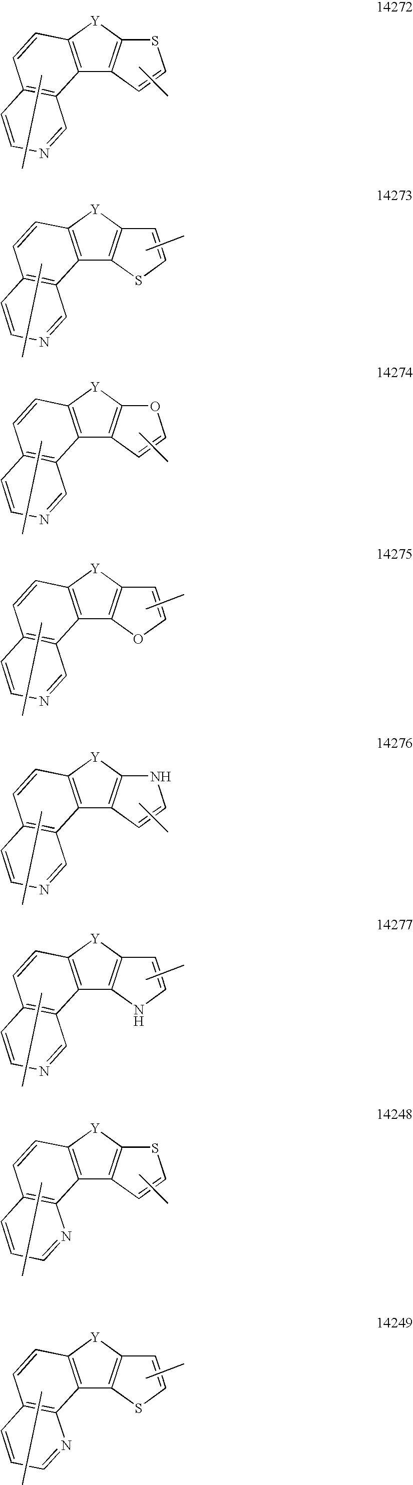

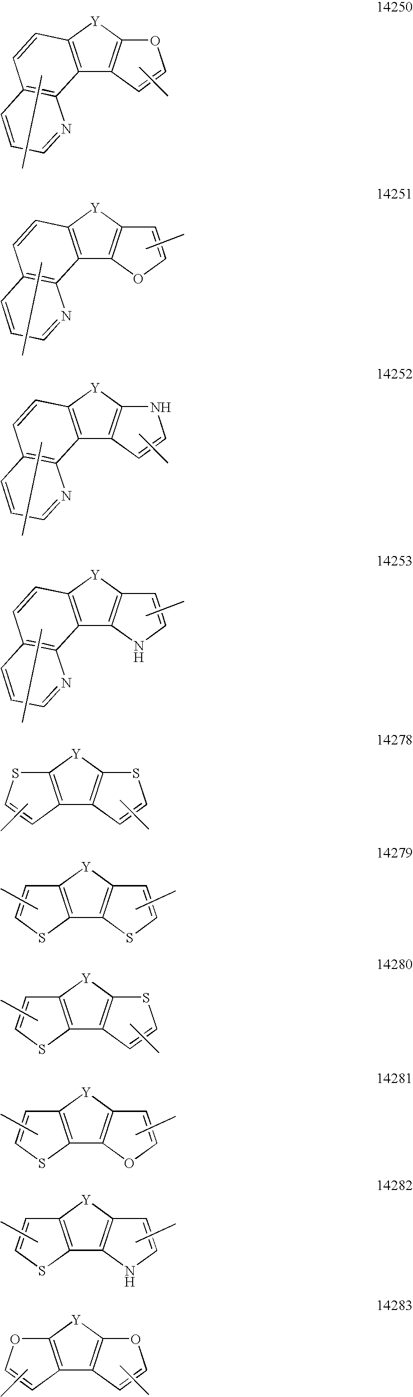

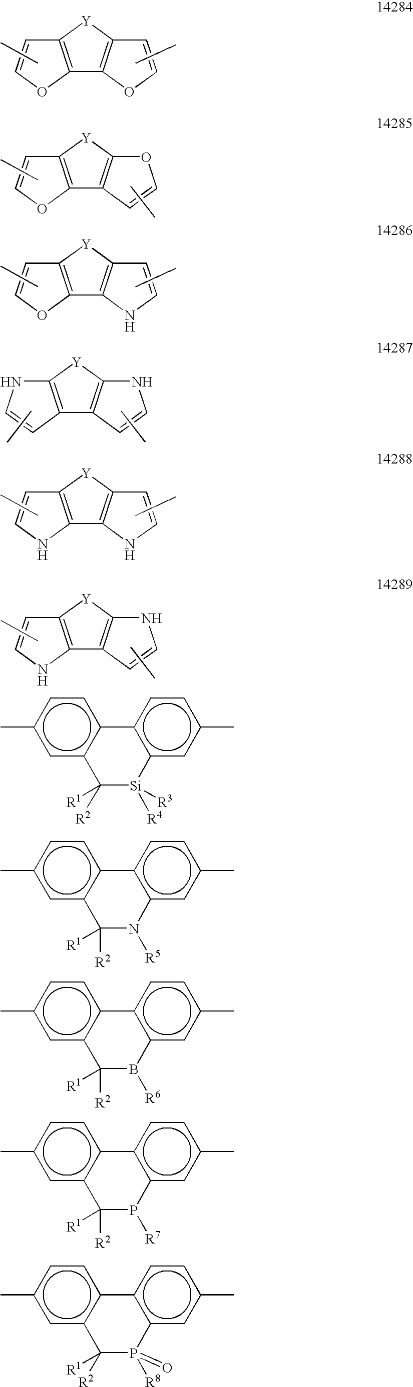

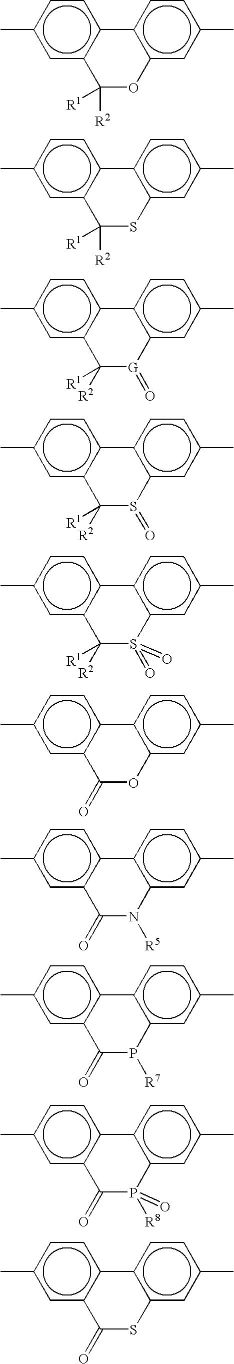

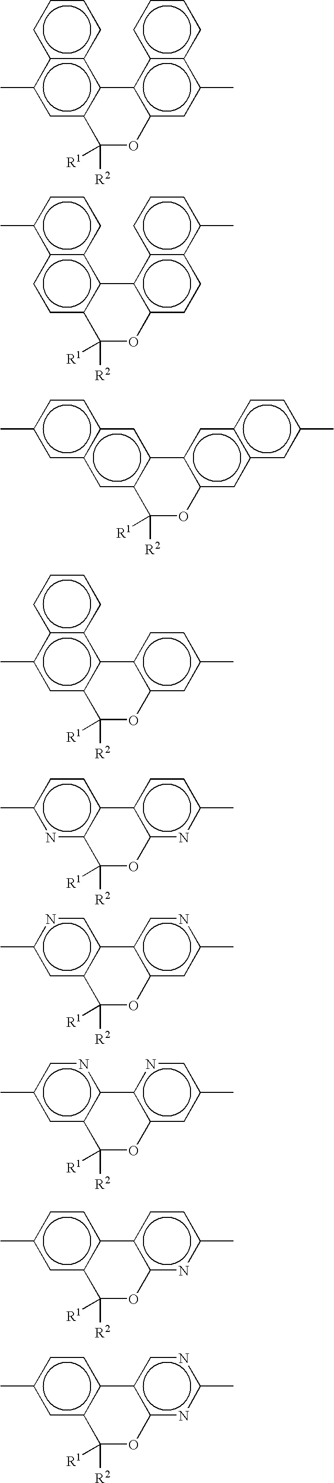

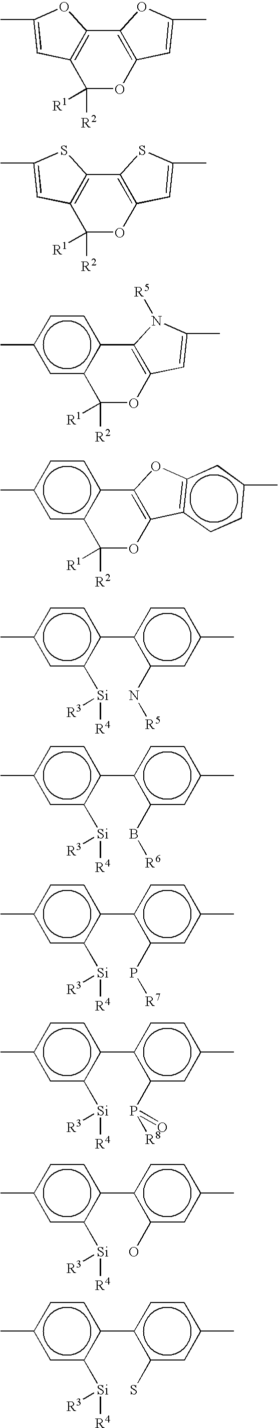

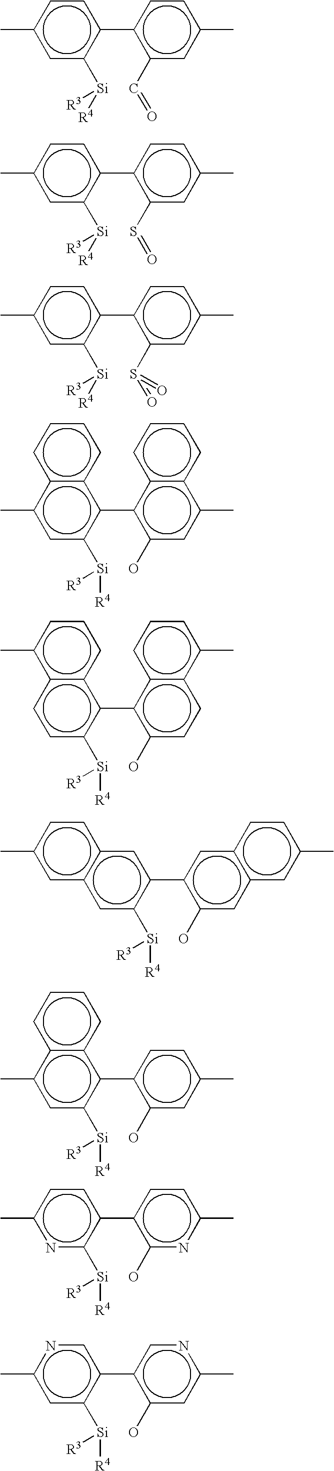

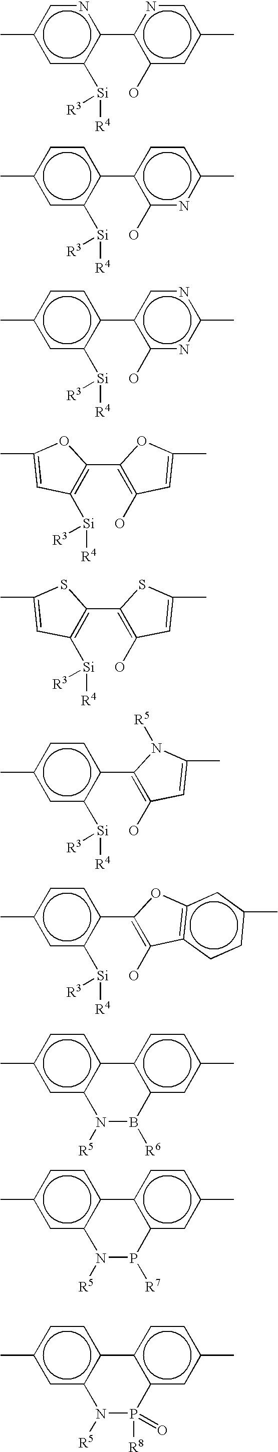

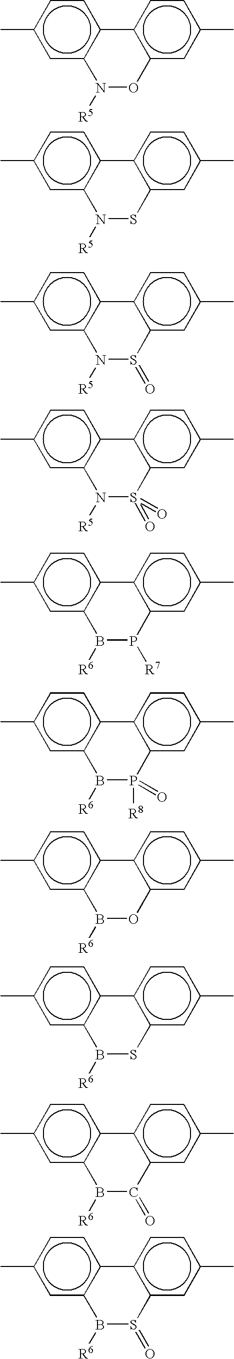

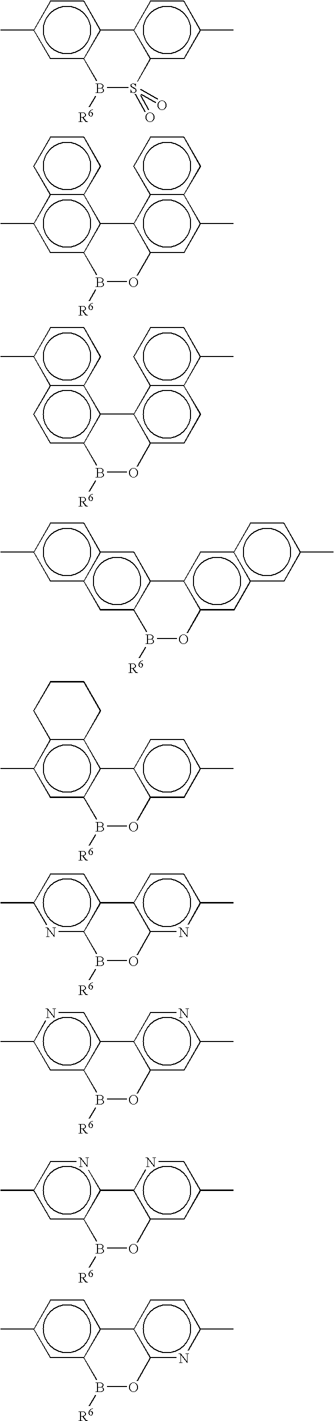

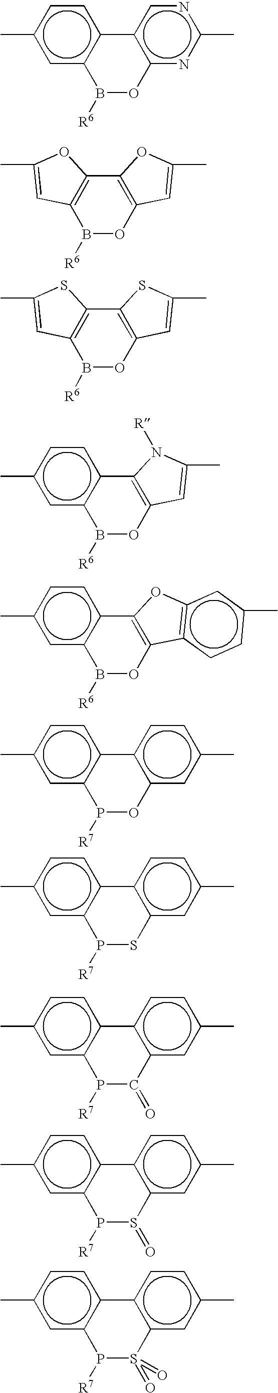

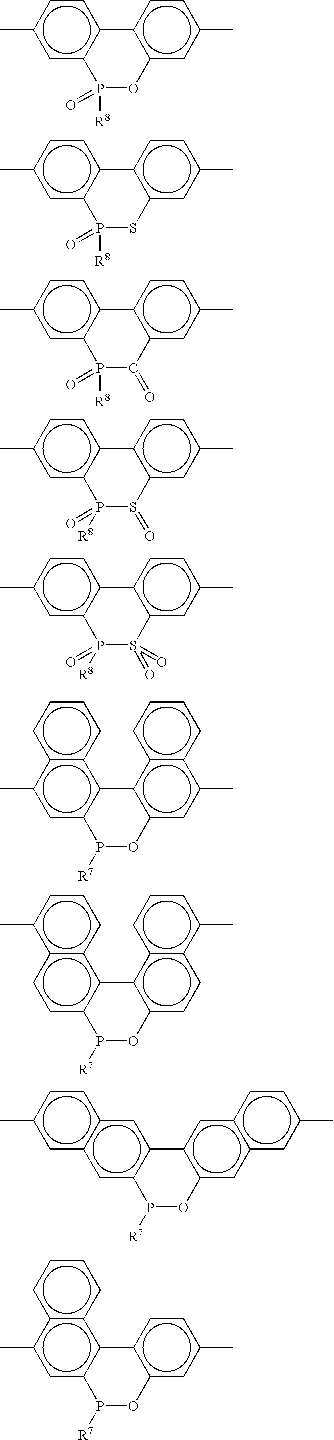

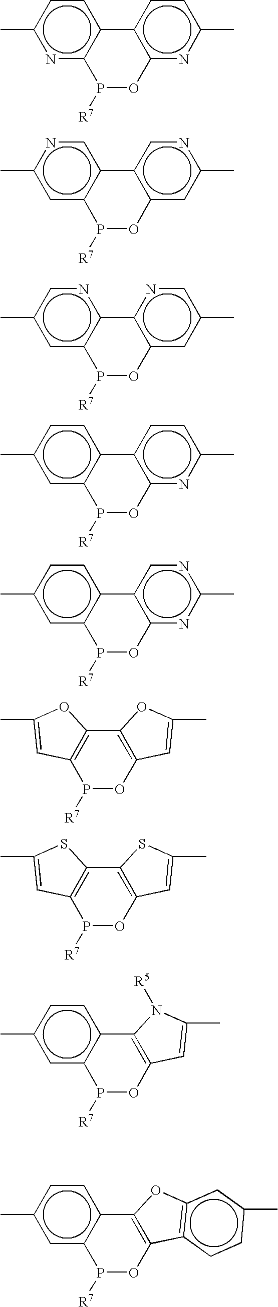

R^{1 to R}⁸ in the above-described formulae each independently represent a hydrogen atom, alkyl group, alkyloxy group, alkylthio group, aryl group, aryloxy group, arylthio group, arylalkyl group, arylalkoxy group, arylalkylthio group, acyl group, acyloxy group, amide group, acid imide group, imine residue, amino group, substituted amino group, substituted silyl group, substituted silyloxy group, substituted silylthio group, substituted silylamino group, monovalent heterocyclic group, heteroaryloxy group, heteroarylthio group, arylalkenyl group, arylethynyl group, carboxyl group or cyano group. R¹ and R², and R³ and R⁴ may each mutually be connected to form a ring.

Among specific examples of the formula (1-5), examples as described below are mentioned as those having no substituent.

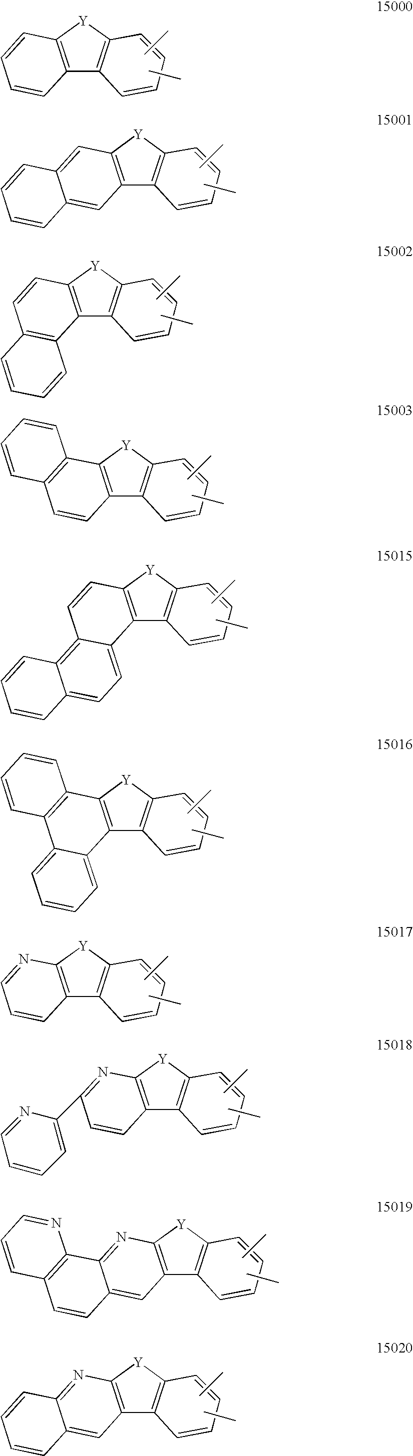

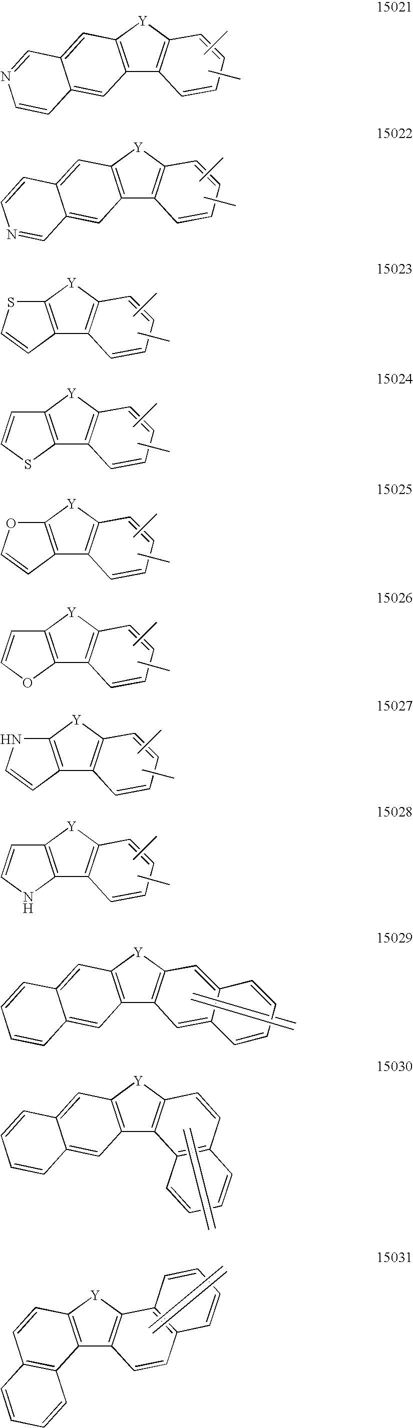

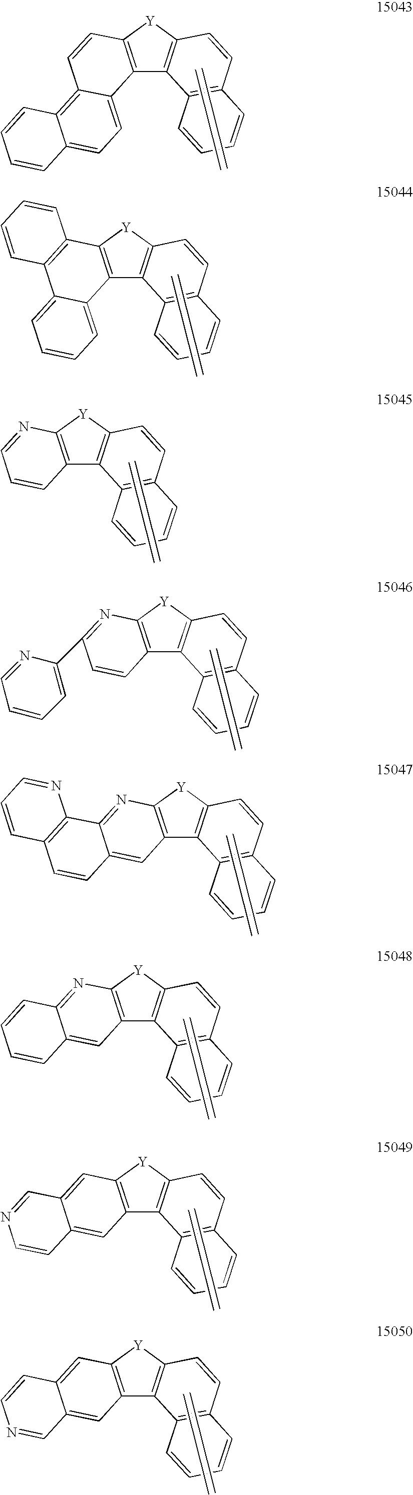

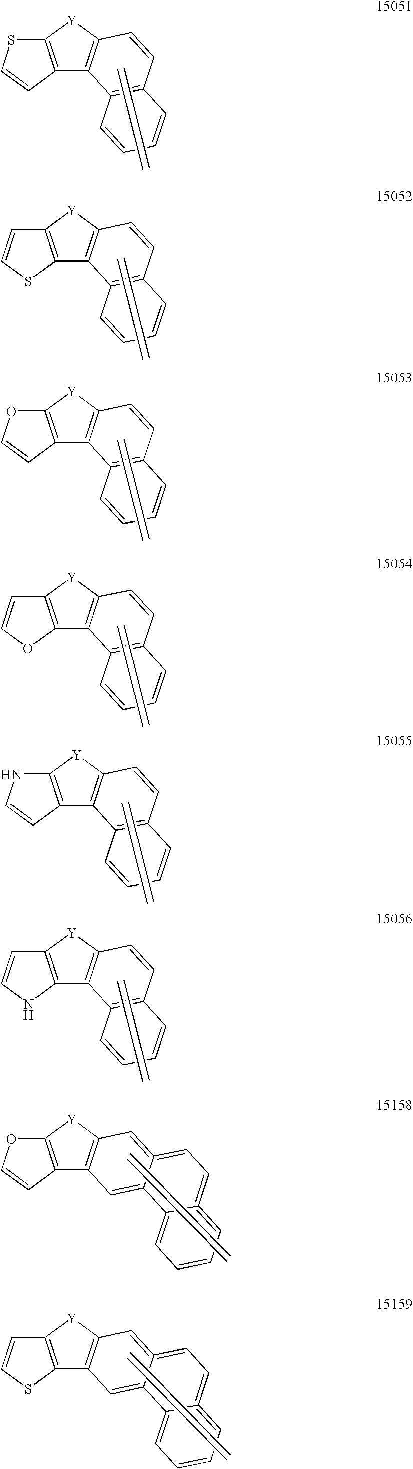

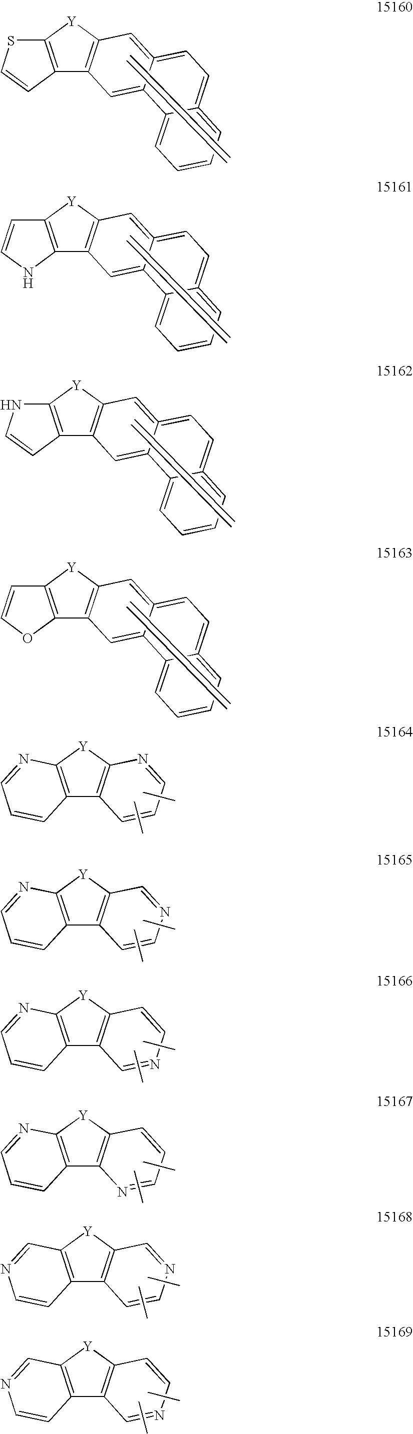

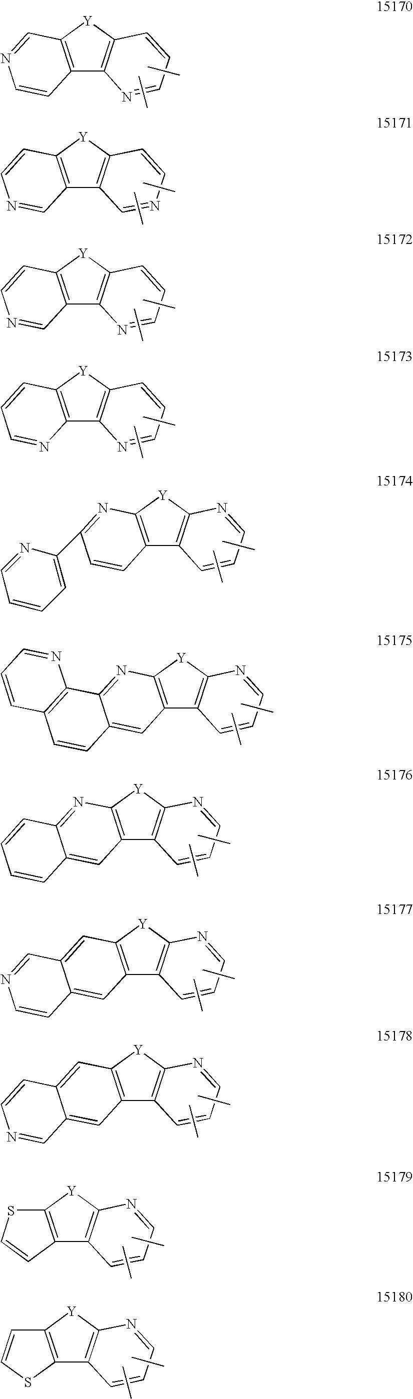

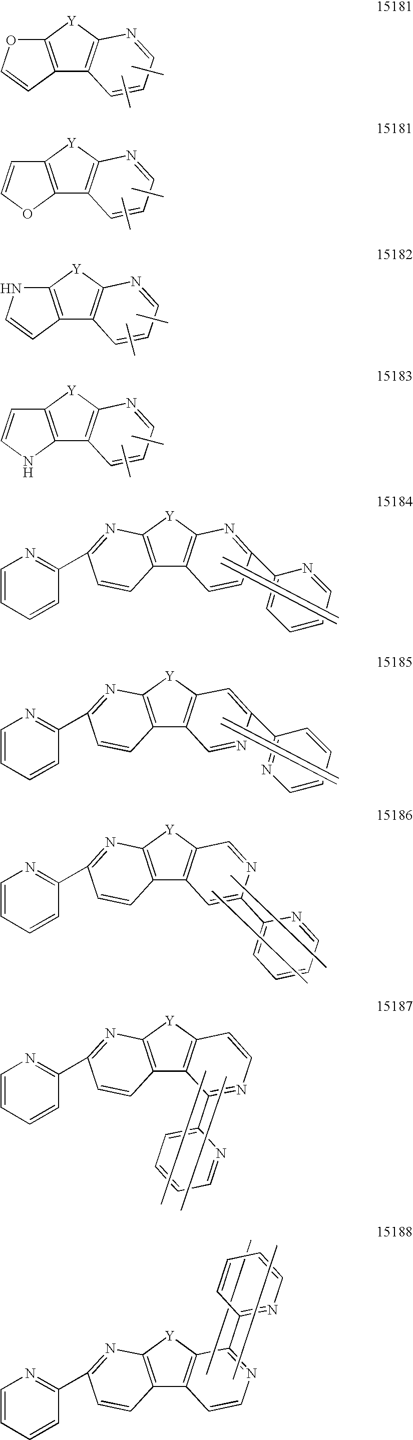

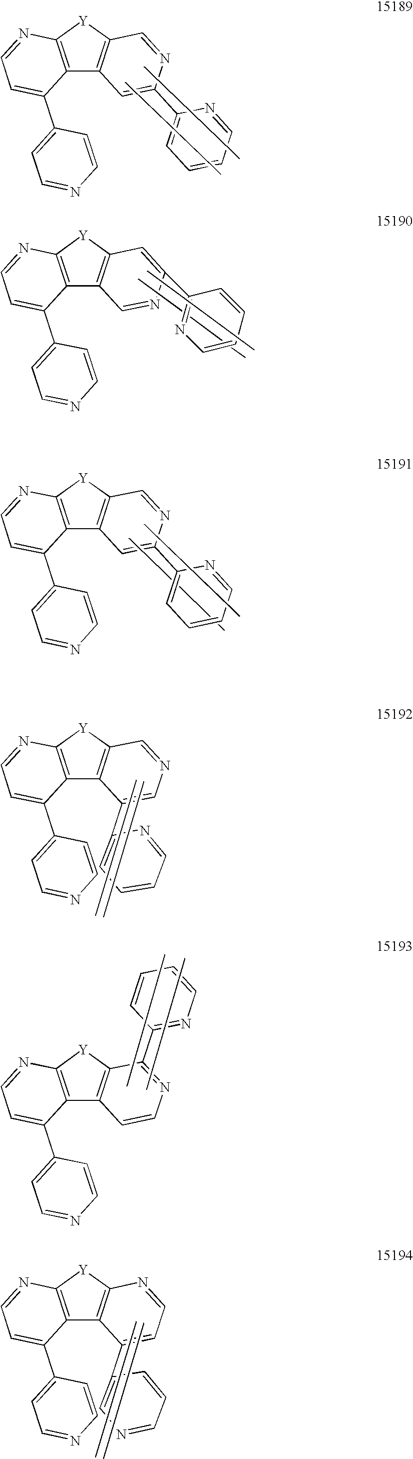

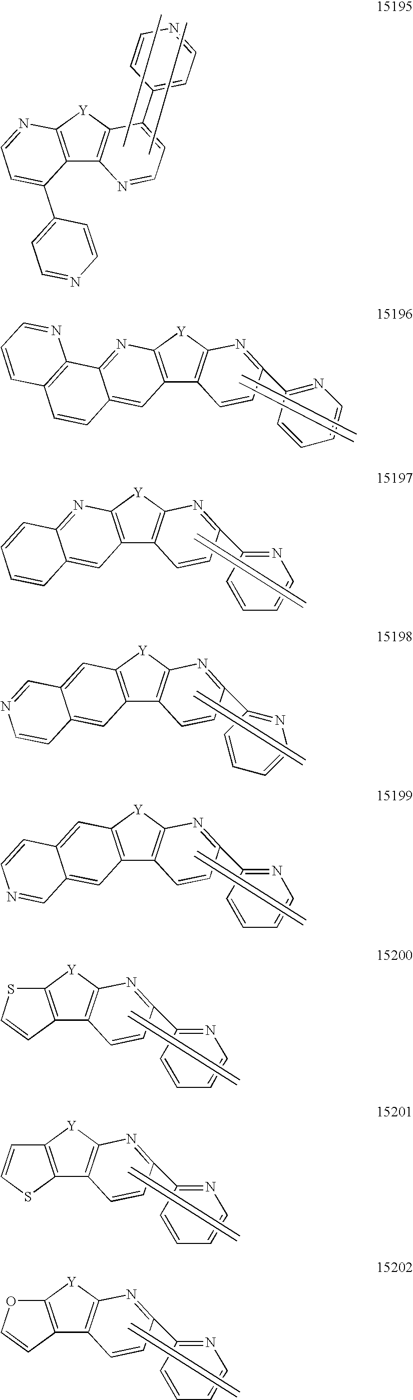

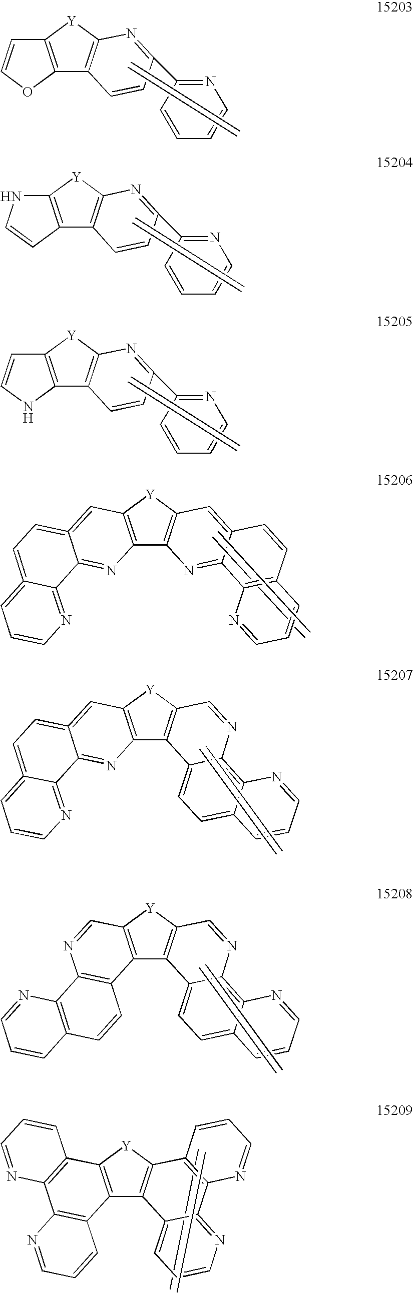

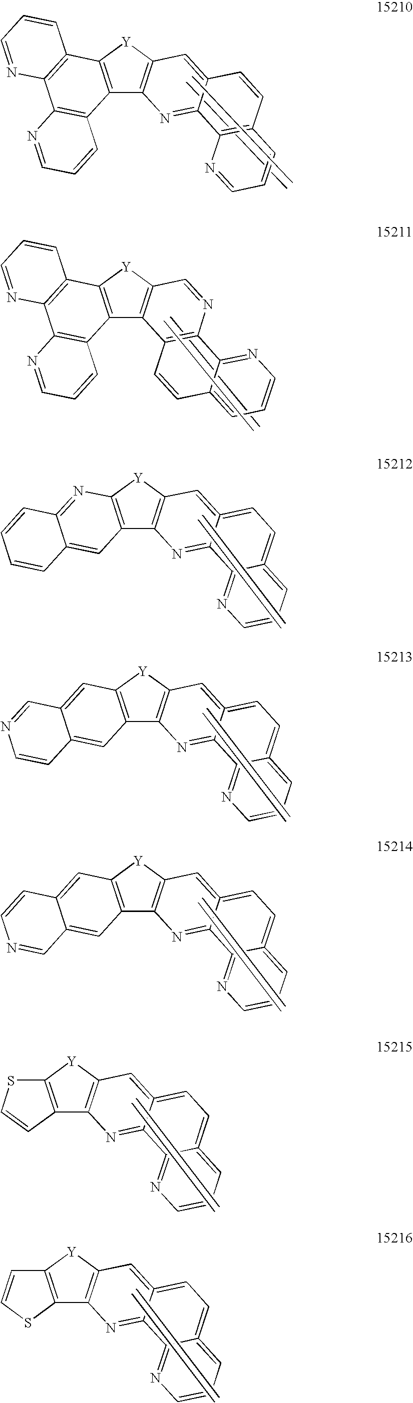

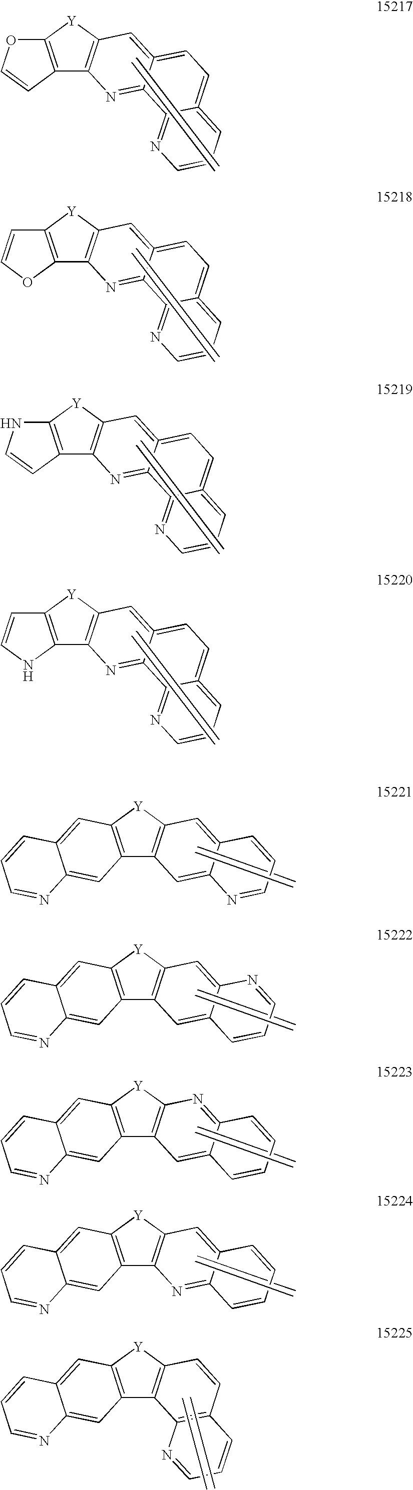

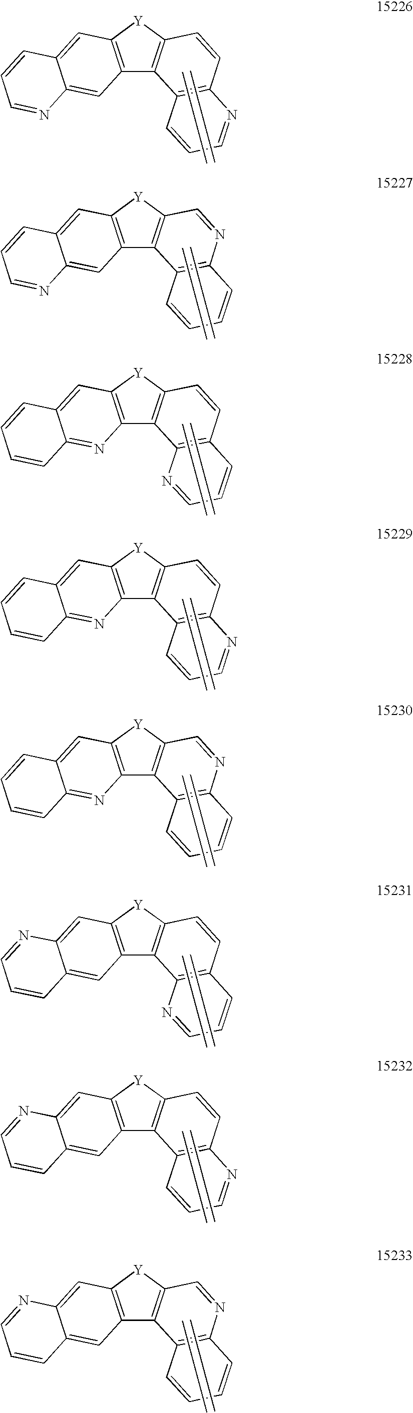

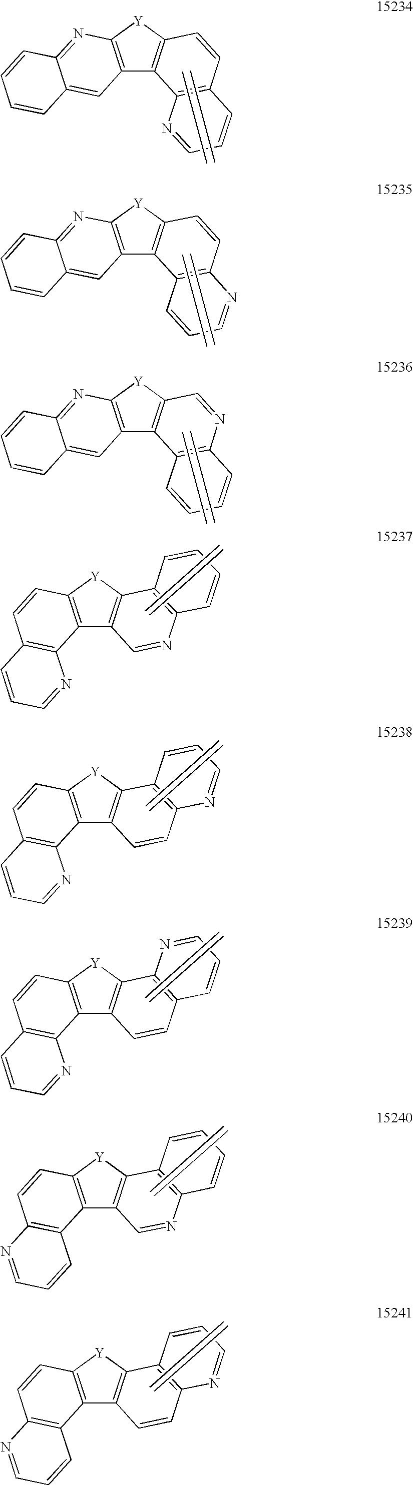

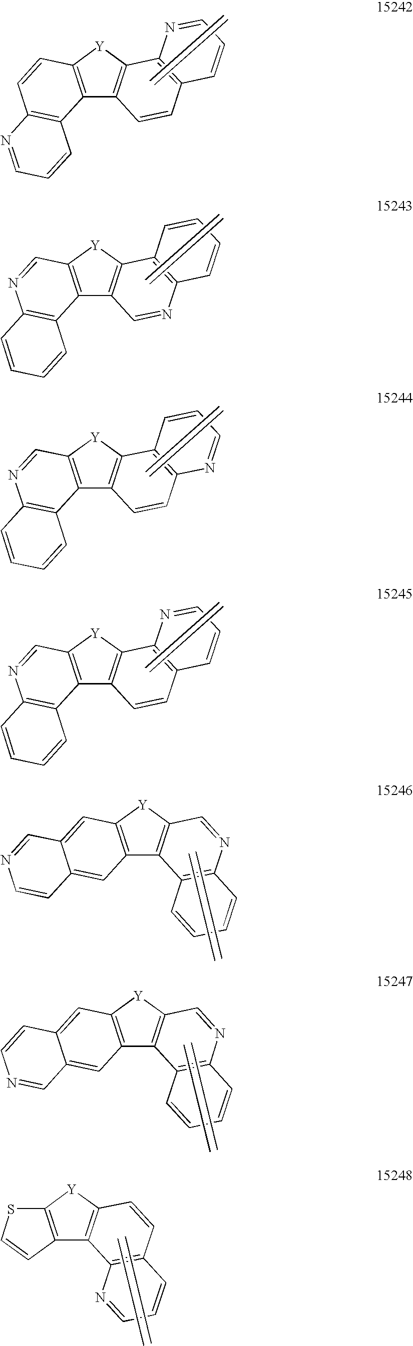

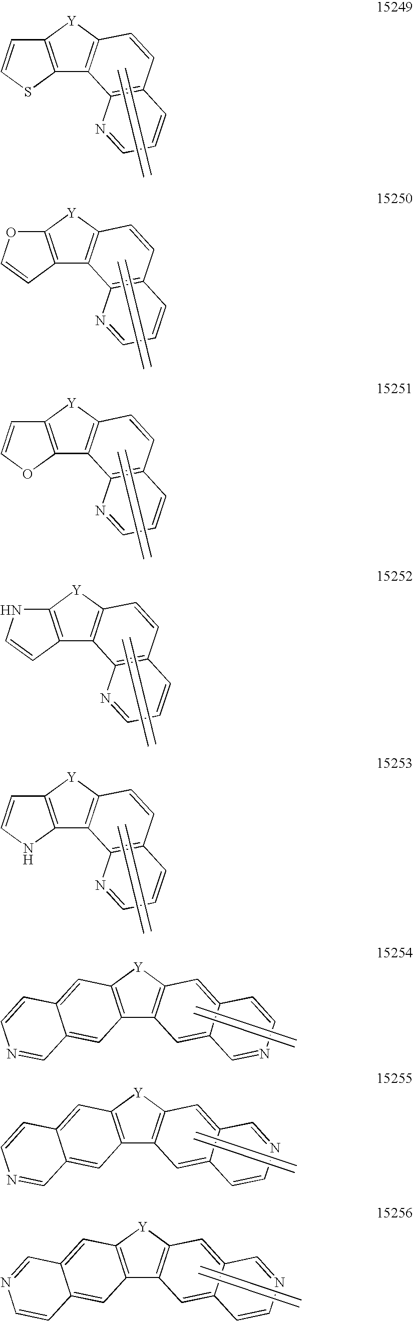

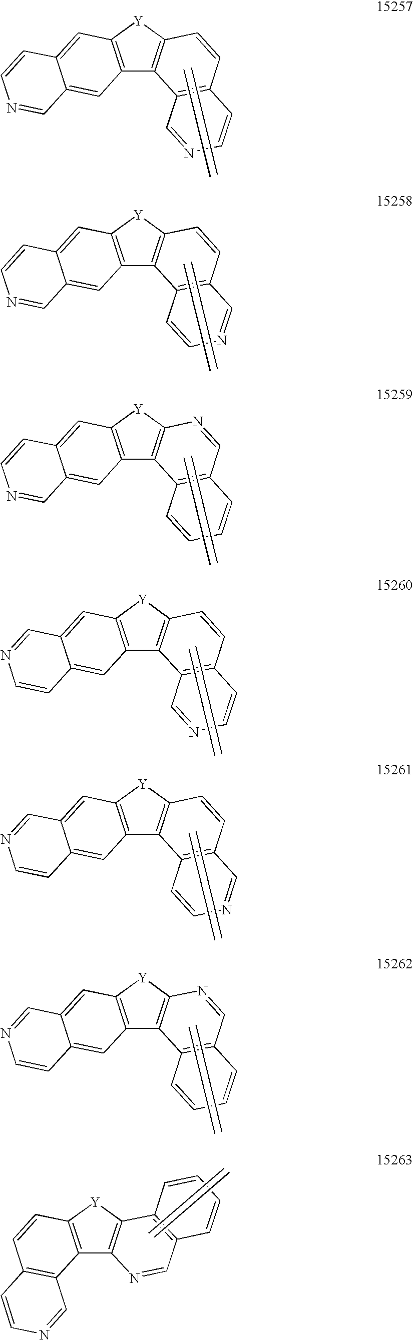

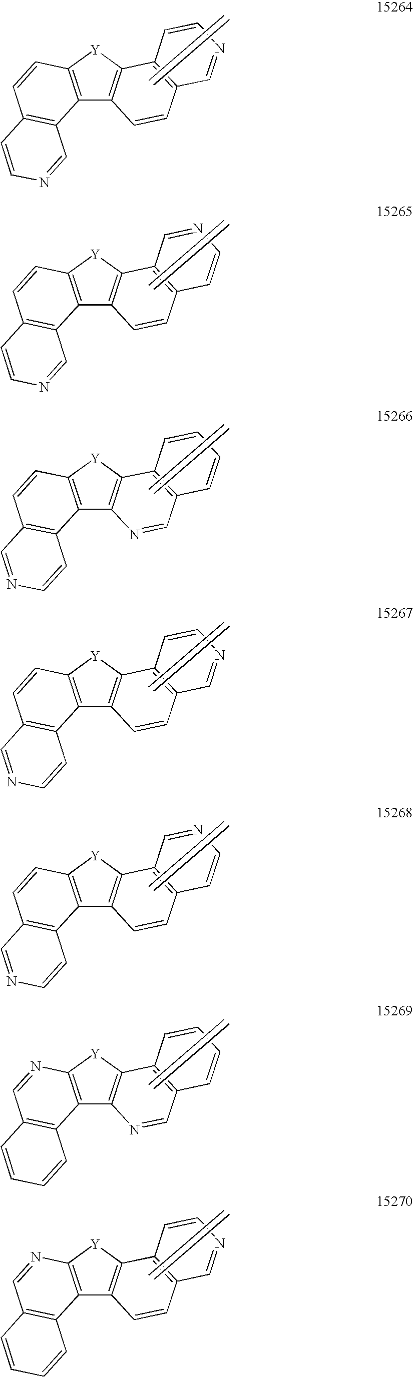

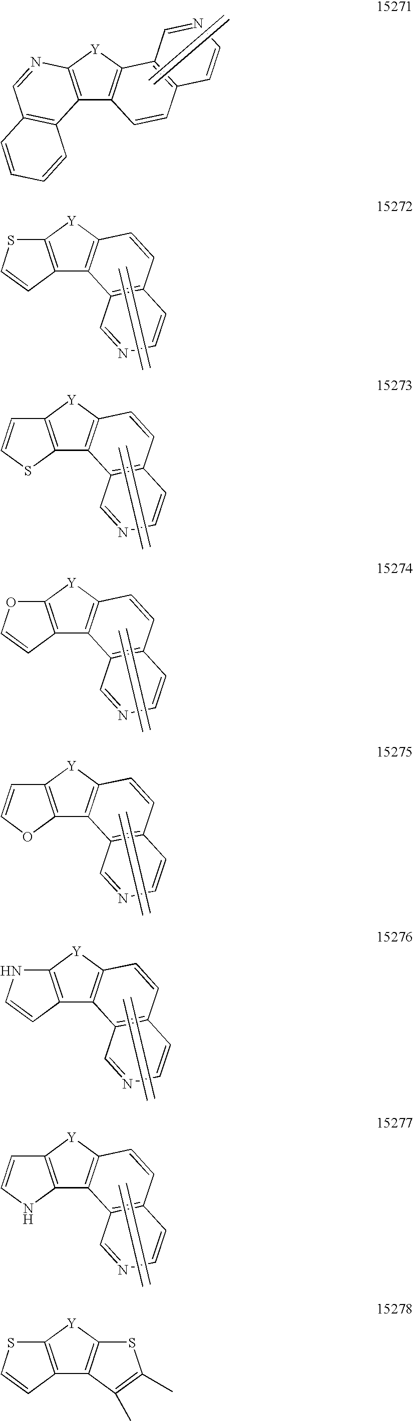

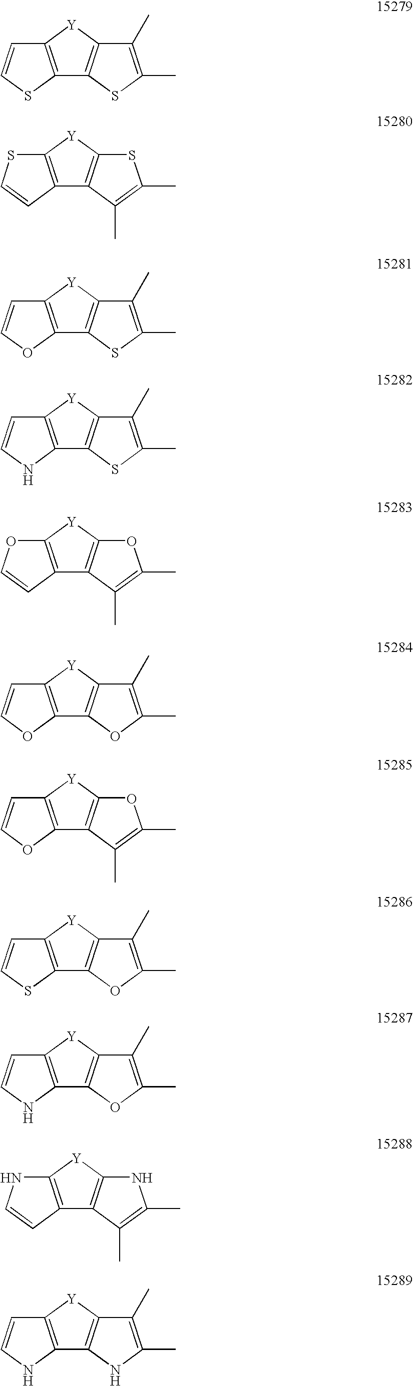

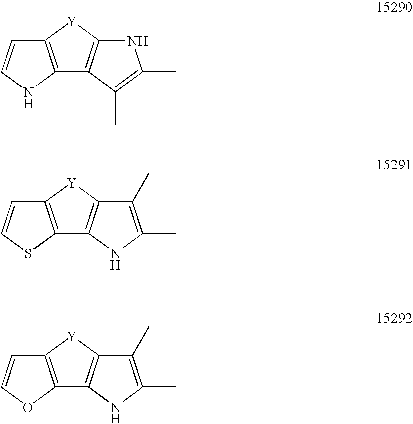

Among the above-mentioned specific examples, it is preferable that these aromatic hydrocarbon groups or heterocycles have further a substituent, from the standpoint of improvement in solubility. Exemplified as the substituent are halogen atoms, alkyl groups, alkyloxy groups, alkylthio groups, aryl groups, aryloxy groups, arylthio groups, arylalkyl groups, arylalkyloxy groups, arylalkylthio groups, acyl group, acyloxy group, amide group, acid imide group, imine residue, amino group, substituted amino groups, substituted silyl groups, substituted silyloxy groups, substituted silylthio groups, substituted silylamino groups, monovalent heterocyclic groups, heteroaryloxy groups, heteroarylthio groups, arylalkenyl groups, arylethynyl groups, carboxyl group and cyano group, and they may be mutually connected to form a ring.

Of the above-described formula (1), the formulae (1-4) and (1-5) are preferable, the formula (1-4) is more preferable, and structures of the following formula (1-6) are more preferable.

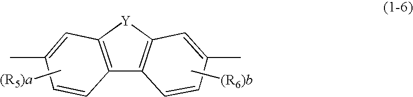

(wherein, R₅ and R₆ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, acyloxy group, imine residue, amide group, acid imide group, monovalent heterocyclic group, carboxyl group or substituted carboxyl group. a and b each independently represent an integer of 0 to 3. When R₅ and R₆ are present each in plural number, they may be the same or different. Y represents the same meaning as described above.).

In the formula (1-6), Y preferably represents —S—, —O— or —C(R₁)(R₂)—, and further preferably, Y represents —S— or —O—.

From the standpoint of solubility in a solvent, a+b is preferably 1 or more.

The P ring, Q ring, A ring, B ring, C ring, D ring, E ring, F ring and G ring in the above-described formulae (1), (1-1) to (1-8) preferably represent an aromatic hydrocarbon ring.

Regarding the above-mentioned Ar₁, Ar₂, Ar₃ and Ar₄, the arylene ring is an atomic group obtained by removing two hydrogen atoms from an aromatic hydrocarbon, and has usually about 6 to 60 carbon atoms, preferably 6 to 20 carbon atoms. Here, the aromatic hydrocarbon includes those having a condensed ring, and those obtained by connecting two or more independent benzene rings or condensed rings directly or via a group such as vinylene and the like.

Examples of the arylene group include phenylene group (for example, following formulas 1-3), naphthalenediyl group (following formulas 4-13), anthracenylene group (following formulas 14-19), biphenylene group (following formulas 20-25), terphenyl-diyl group (following formulas 26-28), condensed ring compound group (following formulas 29-35), fluorene-diyl group (following formulas 36-38), stilbene-diyl (following formulas A-D), distilbene-diyl (following formulas E, F), etc. Among them, phenylene group, biphenylene group, and stilbene-diyl group are preferable.

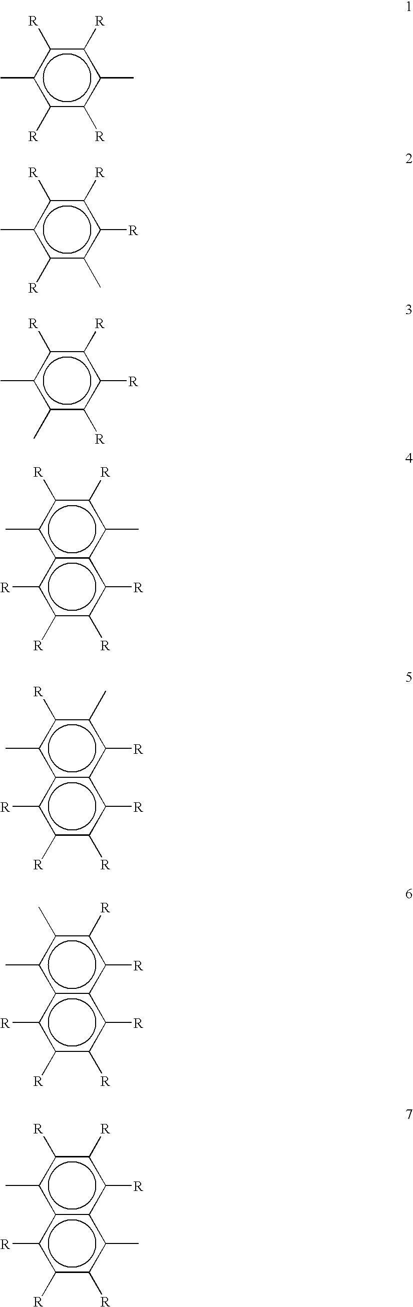

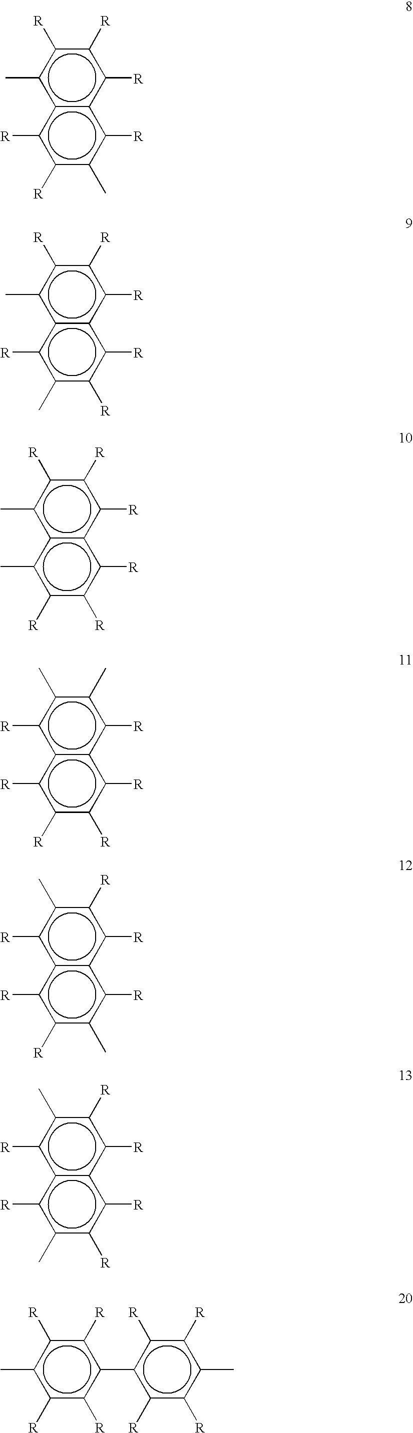

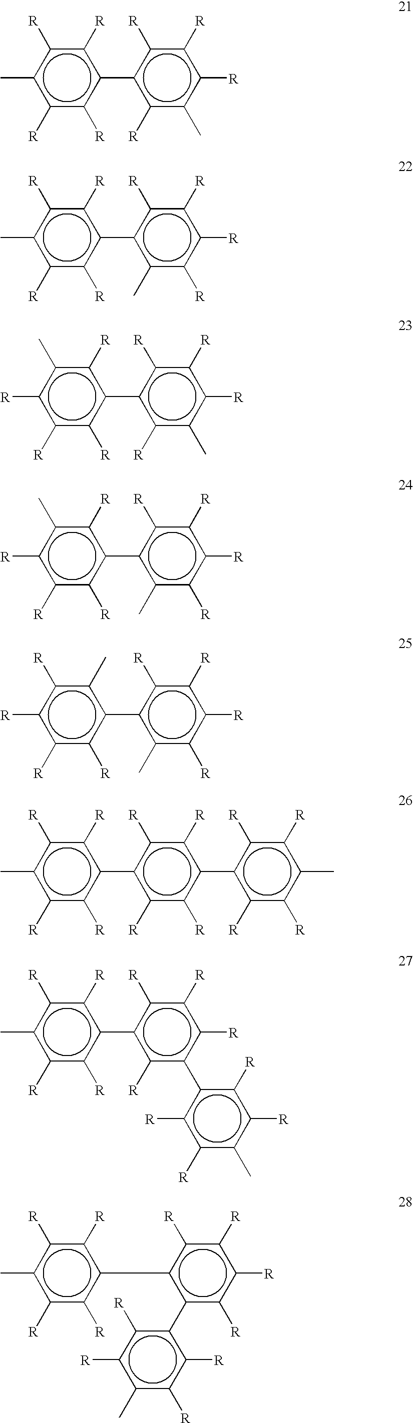

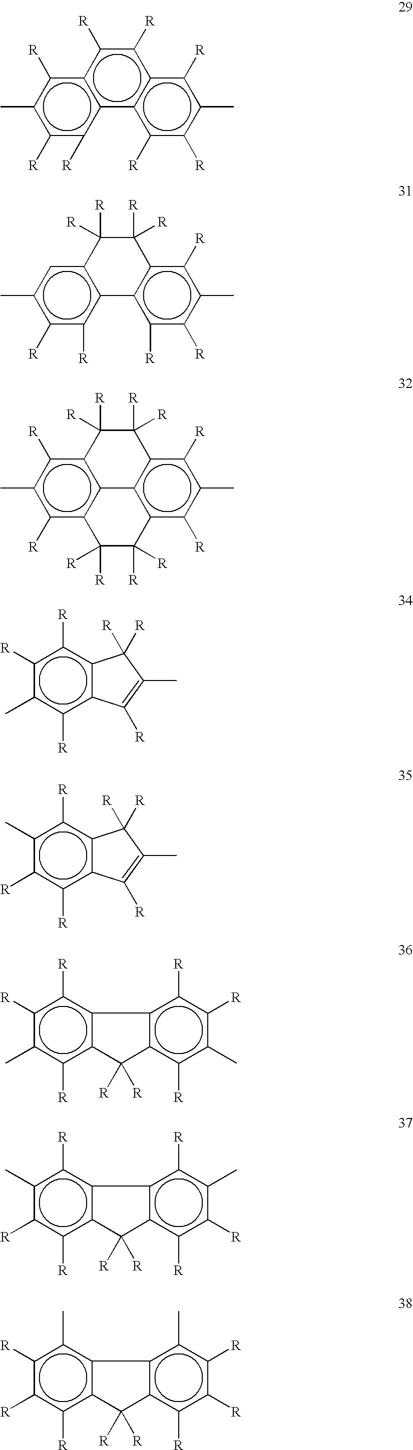

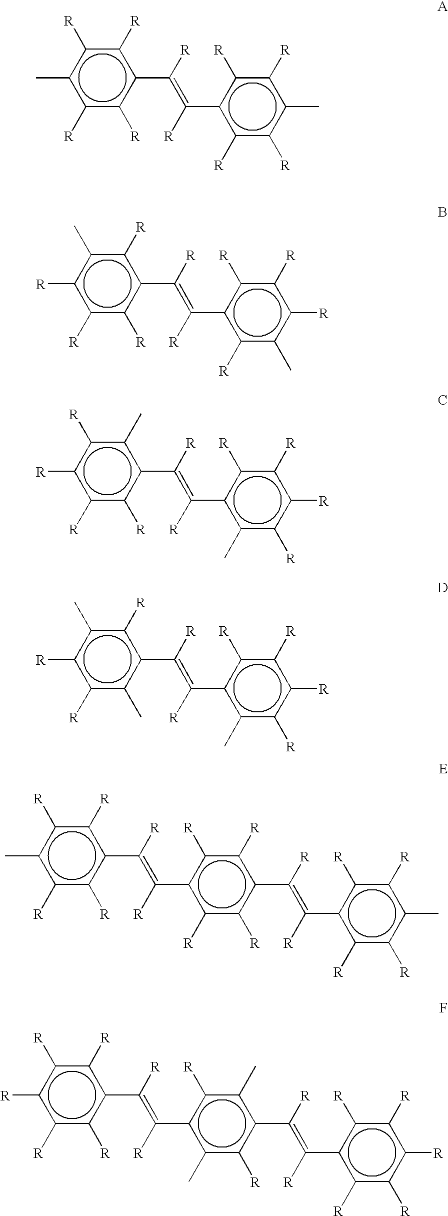

The divalent heterocyclic group means an atomic group in which two hydrogen atoms are removed from a heterocyclic compound, and the number of carbon atoms is usually about 3 to 60.

The heterocyclic compound means an organic compound having a cyclic structure in which at least one heteroatom such as oxygen, sulfur, nitrogen, phosphorus, boron, etc. is contained in the cyclic structure as the element other than carbon atoms.

Examples of the divalent heterocyclic groups include the followings.

Divalent heterocyclic groups containing nitrogen as a hetero atom; pyridine-diyl group (following formulas 39-44), diaza phenylene group (following formulas 45-48), quinolinediyl group (following formulas 49-63), quinoxalinediyl group (following formulas 64-68), acridinediyl group (following formulas 69-72), bipyridyldiyl group (following formulas 73-75), phenanthrolinediyl group (following formulas 76-78), etc.

Groups having a fluorene structure containing silicon, nitrogen, selenium, etc. as a hetero atom (following formulas 79-93).

5 membered heterocyclic groups containing silicon, nitrogen, sulfur, selenium, etc. as a hetero atom: (following formulas 94-98).

Condensed 5 membered heterocyclic groups containing silicon, nitrogen, selenium, etc. as a hetero atom: (following formulas 99-110),

5 membered heterocyclic groups containing silicon, nitrogen, sulfur, selenium, etc. as a hetero atom, which are connected at the a position of the hetero atom to form a dimer or an oligomer (following formulas 111-112);

5 membered ring heterocyclic groups containing silicon, nitrogen, sulfur, selenium, as a hetero atom is connected with a phenyl group at the a position of the hetero atom (following formulas 113-119); and

Groups of 5 membered ring heterocyclic groups containing nitrogen, oxygen, sulfur, as a hetero atom onto which a phenyl group, furyl group, or thienyl group is substituted (following formulas 120-125).

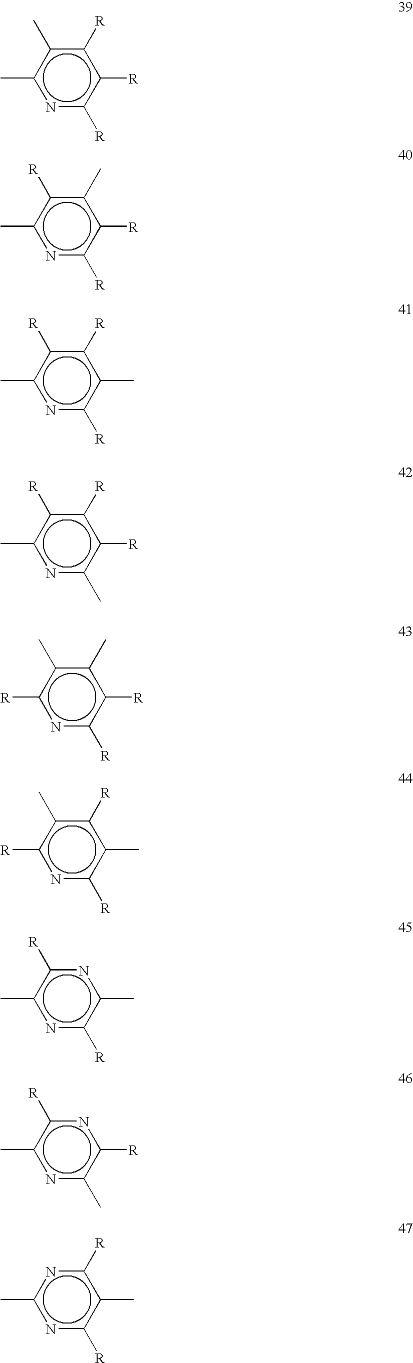

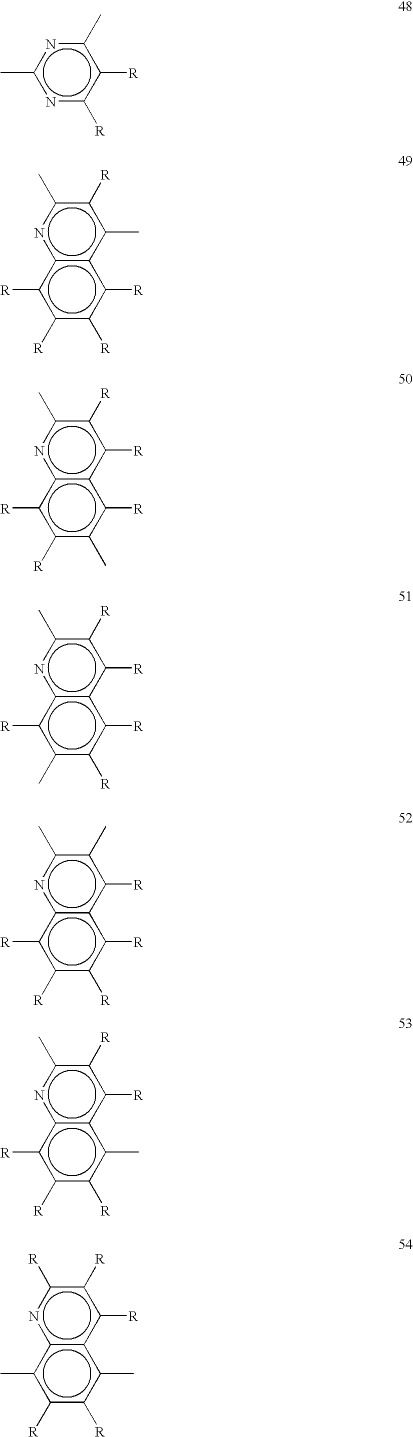

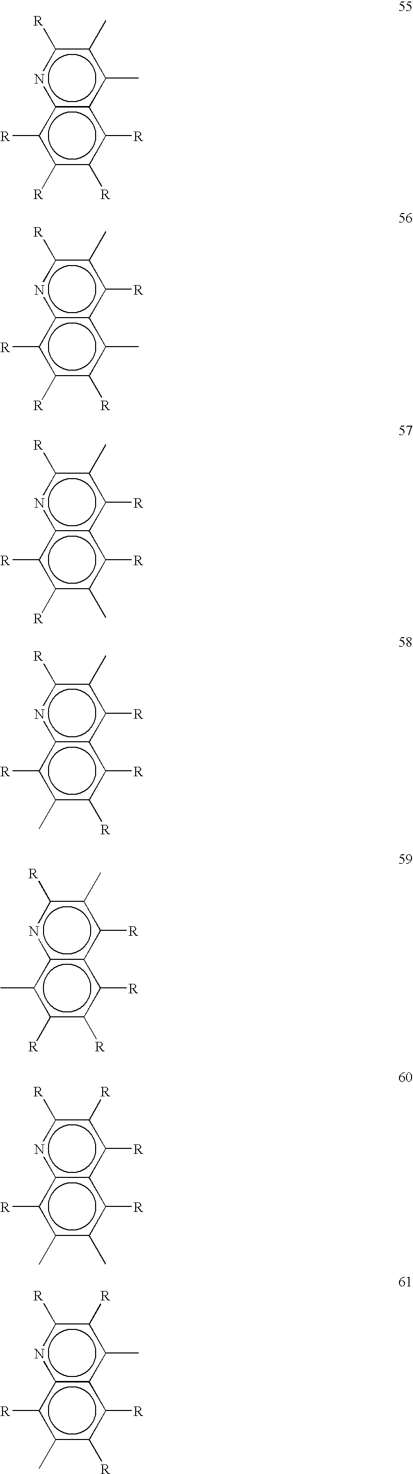

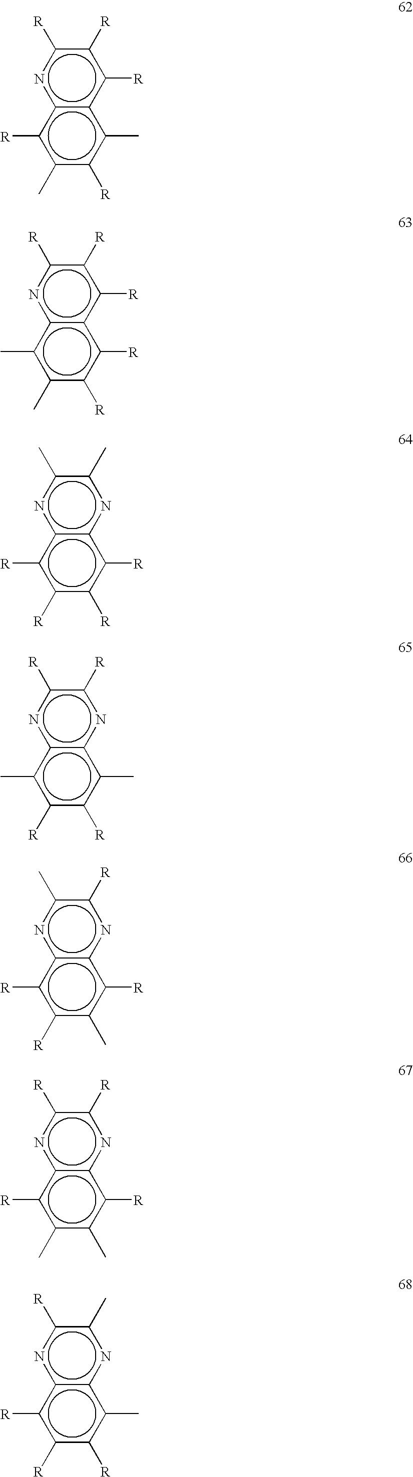

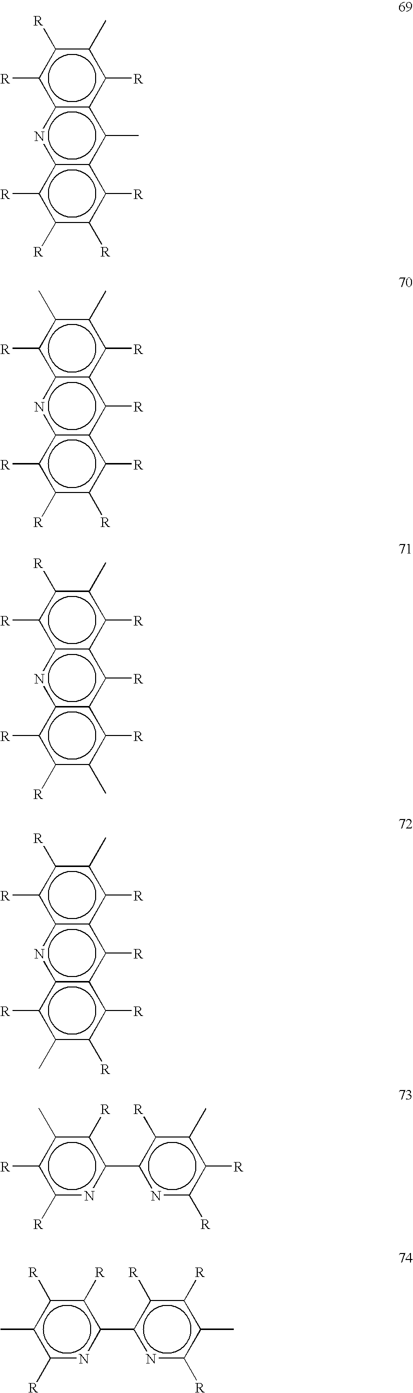

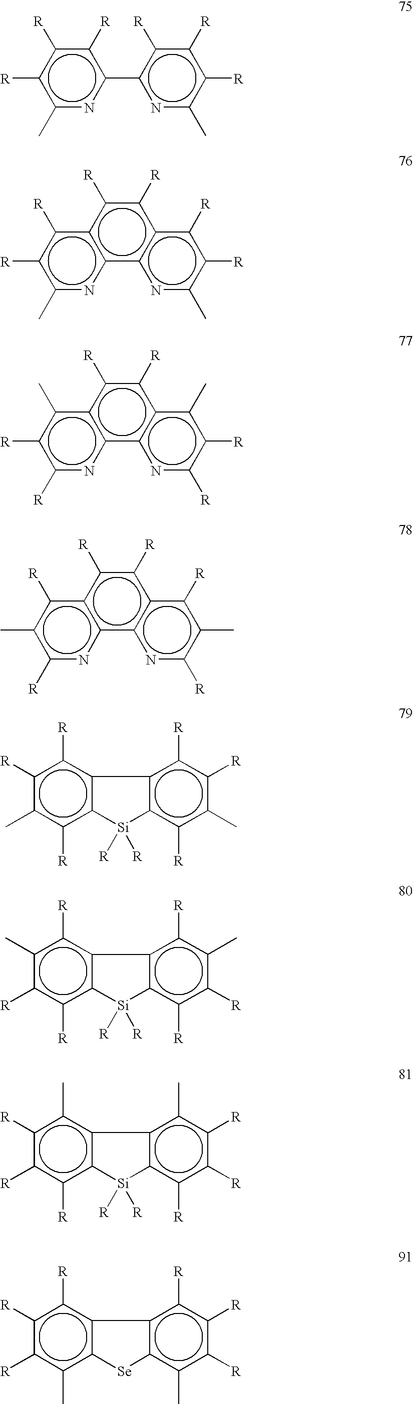

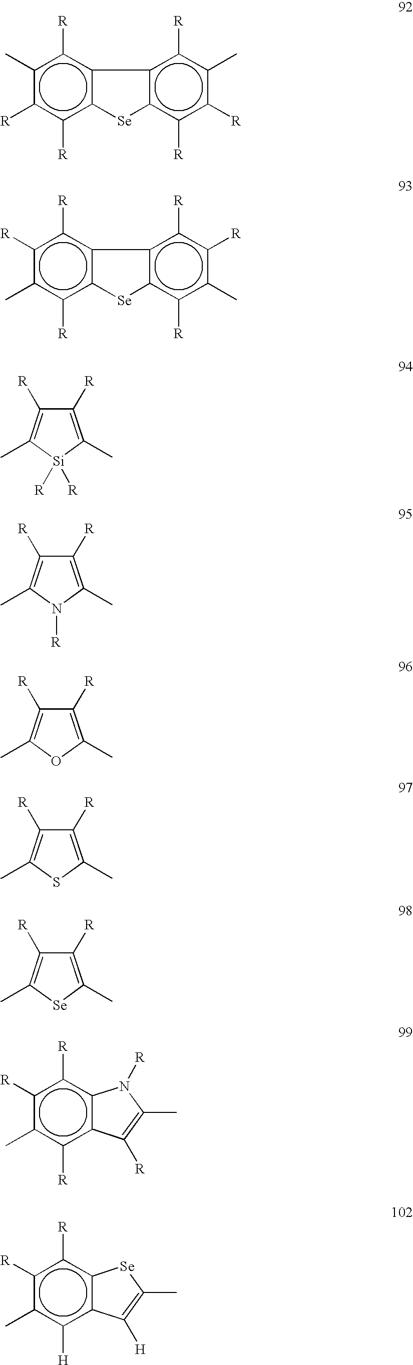

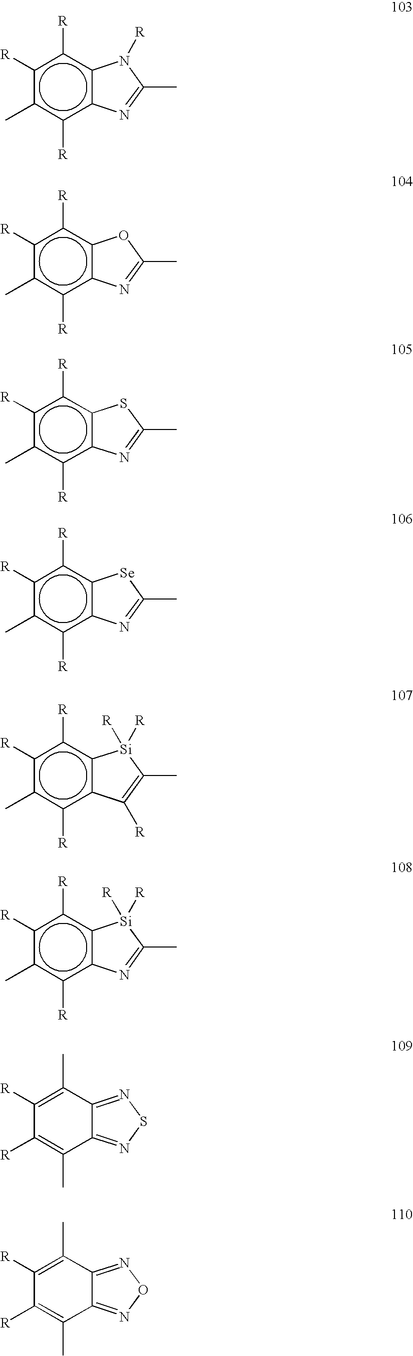

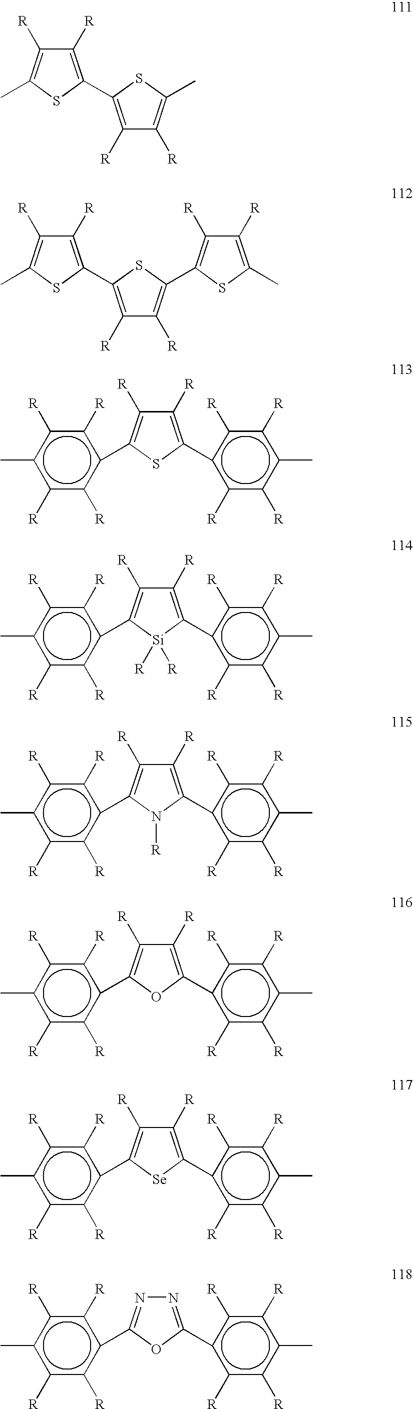

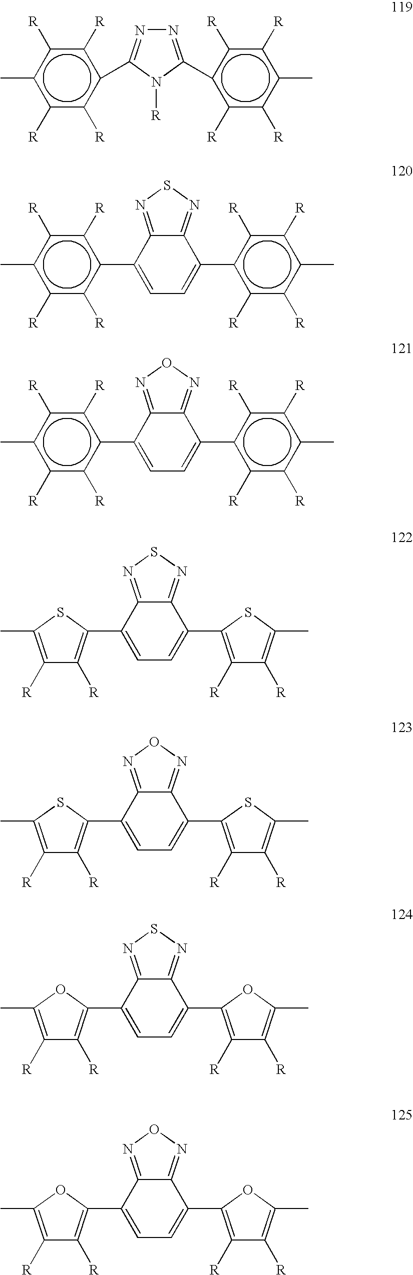

In the examples of the above formulae 1-125, Rs each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom (for example, chlorine, bromine, iodine), acyl group, acyloxy group, imine residue, amide group, acid imide group, monovalent heterocyclic group, carboxyl group, substituted carboxyl group, or cyano group. Carbon atom contained in the groups of formulas 1-125 may be substituted by a nitrogen atom, oxygen atom, or sulfur atom, and a hydrogen atom may be substituted by a fluorine atom.

The alkyl group, alkoxy group, alkylthio group, aryl group, aryloxy group, arylthio group, arylalkyl group, arylalkoxy group, arylalkylthio group, arylalkenyl group, arylalkynyl group, substituted amino group, substituted silyl group, halogen atom, acyl group, acyloxy group, imine residue, amide group, acidimide group, monovalent heterocyclic group, carboxyl group, and substituted carboxyl group in the above formulae (1) to (12), (1-1) to (1-10), and in the above examples, represent the same meaning as above.

The alkyl group may be any of linear, branched or cyclic. The number of carbon atoms is usually about 1 to 20, preferably 3 to 20, and specific examples thereof include methyl group, ethyl group, propyl group, i-propyl group, butyl group, i-butyl group, t-butyl group, pentyl group, hexyl group, cyclohexyl group, heptyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, perfluorooctyl group, etc.; and pentyl group, hexyl group, octyl group, 2-ethylhexyl group, decyl group, and 3,7-dimethyloctyl group are preferable.

The alkoxy group may be any of linear, branched or cyclic. The number of carbon atoms is usually about 1 to 20, preferably 3 to 20, and specific examples thereof include methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethyl hexyloxy group, nonyloxy group, decyloxy group, 3,7-dimethyl octyloxy group, lauroyloxy group, trifluoromethoxy group, pentafluoroethoxy group, perfluorobutoxy group, perfluorohexyloxy group, perfluorooctyloxy group, methoxymethyloxy group, 2-methoxyethyloxy group, etc.; and pentyloxy group, hexyloxy group, octyloxy group, 2-ethylhexyloxy group, decyloxy group, and 3,7-dimethyl octyloxy group are preferable.

The alkylthio group may be any of linear, branched or cyclic. The number of carbon atoms is usually about 1 to 20, preferably 3 to 20, and specific examples thereof include methylthio group, ethylthio group, propylthio group, i-propylthio group, butylthio group, i-butylthio group, t-butylthio group, pentylthio group, hexylthio group, cyclo hexylthio group, heptylthio group, octylthio group, 2-ethyl hexylthio group, nonylthio group, decylthio group, 3,7-dimethyloctylthio group, laurylthio group, trifluoromethylthio group, etc.; and pentylthio group, hexylthio group, octylthio group, 2-ethyl hexylthio group, decylthio group, and 3,7-dimethyloctylthio group are preferable.

The aryl group has usually about 6 to 60 carbon atoms, preferably 7 to 48, and specific examples thereof include phenyl group, C₁-C₁₂ alkoxyphenyl group (C₁-C₁₂ represents the number of carbon atoms 1-12. Hereafter the same), C₁-C₁₂ alkylphenyl group, 1-naphtyl group, 2-naphtyl group, 1-anthracenyl group, 2-anthracenyl group, 9-anthracenyl group, pentafluorophenyl group, etc., and C₁-C₁₂ alkoxyphenyl group and C₁-C₁₂ alkylphenyl group are preferable. The aryl group is an atomic group in which one hydrogen atom is removed from an aromatic hydrocarbon. The aromatic hydrocarbon includes those having a condensed ring, an independent benzene ring, or two or more condensed rings bonded through groups, such as a direct bond or a vinylene group.

Concrete examples of C₁-C₁₂ alkoxy include methoxy, ethoxy, propyloxy, i-propyloxy, butoxy, i-butoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, lauryloxyphenoxy, etc.

Concrete examples of C₁-C₁₂ alkylphenyl group include methylphenyl group, ethylphenyl group, dimethylphenyl group, propylphenyl group, mesityl group, methylethylphenyl group, i-propylphenyl group, butylphenyl group, i-butylphenyl group, t-butylphenyl group, pentylphenyl group, isoamylphenyl group, hexylphenyl group, heptylphenyl group, octylphenyl group, nonylphenyl group, decylphenyl group, dodecylphenyl group, etc.

The aryloxy group has the number of carbon atoms of usually about 6 to 60, preferably 7 to 48, and concrete examples thereof include phenoxy group, C₁-C₁₂ alkoxyphenoxy group, C₁-C₁₂ alkyl phenoxy group, 1-naphtyloxy group, 2-naphtyloxy group, pentafluorophenyloxy group, etc.; and C₁-C₁₂ alkoxyphenoxy group and C₁-C₁₂ alkylphenoxy group are preferable.

Concrete examples of C₁-C₁₂ alkoxy include methoxy, ethoxy, propyloxy, i-propyloxy, butoxy, i-butoxy, t-butoxy, pentyloxy, hexyloxy, cyclohexyloxy, heptyloxy, octyloxy, 2-ethylhexyloxy, nonyloxy, decyloxy, 3,7-dimethyloctyloxy, lauryloxyphenoxy, etc.

Concrete examples of C₁-C₁₂ alkylphenoxy group include methylphenoxy group, ethylphenoxy group, dimethylphenoxy group, propylphenoxy group, 1,3,5-trimethylphenoxy group, methylethylphenoxy group, i-propylphenoxy group, butyl phenoxy group, i-butylphenoxy group, t-butylphenoxy group, pentylphenoxy group, isoamylphenoxy group, hexylphenoxy group, heptylphenoxy group, octylphenoxy group, nonylphenoxy group, decylphenoxy group, dodecylphenoxy group, etc.

The arylthio group has the number of carbon atoms of usually about 6 to 60, preferably 7 to 48, and concrete examples thereof include phenylthio group, C₁-C₁₂ alkoxyphenylthio group, C₁-C₁₂ alkylphenylthio group, 1-naphthylthio group, 2-naphthylthio group, pentafluorophenylthio group, etc.; C₁-C₁₂ alkoxy phenylthio group and C₁-C₁₂ alkyl phenylthio group are preferable.

The arylalkyl group has the number of carbon atoms of usually about 7 to 60, preferably 7 to 48, and concrete examples thereof include phenyl-C₁-C₁₂alkyl group, C₁-C₁₂alkoxy phenyl-C₁-C₁₂ alkyl group, C₁-C₁₂ alkylphenyl-C₁-C₁₂ alkyl group, 1-naphtyl-C₁-C₁₂ alkyl group, 2-naphtyl-C₁-C₁₂ alkyl group etc.; and C₁-C₁₂ alkoxyphenyl-C₁-C₁₂ alkyl group and C₁-C₁₂ alkyl phenyl-C₁-C₁₂ alkyl group are preferable.

The arylalkoxy group has the number of carbon atoms of usually about 7 to 60, preferably 7 to 48, and concrete examples thereof include: phenyl-C₁-C₁₂alkoxy groups, such as phenylmethoxy group, phenylethoxy group, phenylbutoxy group, phenylpentyloxy group, phenylhexyloxy group, phenylheptyloxy group, and phenyloctyloxy group; C₁-C₁₂alkoxyphenyl-C₁-C₁₂ alkoxy group, C₁-C₁₂alkylphenyl-C₁-C₁₂alkoxy group, 1-naphtyl-C₁-C₁₂ alkoxy group, 2-naphtyl-C₁-C₁₂ alkoxy group etc.; and C₁-C₁₂ alkoxyphenyl-C₁-C₁₂ alkoxy group and C₁-C₁₂ alkylphenyl-C₁-C₁₂ alkoxy group are preferable.

The arylalkylthio group has the number of carbon atoms of usually about 7 to 60, preferably 7 to 48, and concrete examples thereof include: phenyl-C₁-C₁₂ alkylthio group, C₁-C₁₂ alkoxy phenyl-C₁-C₁₂ alkylthio group, C₁-C₁₂ alkylphenyl-C₁-C₁₂ alkylthio group, 1-naphtyl-C₁-C₁₂ alkylthio group, 2-naphtyl-C₁-C₁₂ alkylthio group, etc.; and C₁-C₁₂ alkoxy phenyl-C₁-C₁₂ alkylthio group and C₁-C₁₂ alkylphenyl-C₁-C₁₂ alkylthio group are preferable.

The arylalkenyl group has the number of carbon atoms of usually about 7 to 60, preferably 7 to 48, and concrete examples thereof include: phenyl-C₂-C₁₂ alkenyl group, C₁-C₁₂ alkoxy phenyl-C₂-C₁₂ alkenyl group, C₁-C₁₂ alkyl phenyl-C₂-C₁₂ alkenyl group, 1-naphtyl-C₂-C₁₂ alkenyl group, 2-naphtyl-C₂-C₁₂alkenyl group, etc.; and C₁-C₁₂ alkoxy phenyl-C₂-C₁₂alkenyl group, and C₂-C₁₂alkyl phenyl-C₁-C₁₂ alkenyl group are preferable.

The arylalkynyl group has the number of carbon atoms of usually about 7 to 60, preferably 7 to 48, and concrete examples thereof include: phenyl-C₂-C₁₂ alkynyl group, C₁-C₁₂ alkoxy phenyl-C₂-C₁₂ alkynyl group, C₁-C₁₂ alkylphenyl-C₂-C₁₂ alkynyl group, 1-naphtyl-C₂-C₁₂ alkynyl group, 2-naphtyl-C₂-C₁₂ alkynyl group, etc.; and C₁-C₁₂ alkoxyphenyl-C₂-C₁₂ alkynyl group, and C₁-C₁₂ alkylphenyl-C₂-C₁₂ alkynyl group are preferable.

The substituted amino group means a amino group substituted by 1 or 2 groups selected from an alkyl group, aryl group, arylalkyl group, or monovalent heterocyclic group, and said alkyl group, aryl group, arylalkyl group, or monovalent heterocyclic group may have substituent. The substituted amino groups has usually about 1 to 60, preferably 2 to 48 carbon atoms, without including the number of carbon atoms of said substituent.

Concrete examples thereof include methylamino group, dimethylamino group, ethylamino group, diethylamino group, propylamino group, dipropylamino group, i-propylamino group, diisopropylamino group, butylamino group, i-butyl amino group, t-butylamino group, pentylamino group, hexyl amino group, cyclohexylamino group, heptylamino group, octyl amino group, 2-ethylhexylamino group, nonylamino group, decyl amino group, 3,7-dimethyloctylamino group, laurylamino group, cyclopentylamino group, dicyclopentyl amino group, cyclohexyl amino group, dicyclohexylamino group, pyrrolidyl group, piperidyl group, ditrifluoromethylamino group, phenylamino group, diphenylamino group, C₁-C₁₂ alkoxyphenylamino group, di(C₁-C₁₂ alkoxyphenyl)amino group, di(C₁-C₁₂ alkylphenyl)amino group, 1-naphtylamino group, 2-naphtylamino group, pentafluorophenylamino group, pyridylamino group, pyridazinylamino group, pyrimidylamino group, pyrazylamino group, triazylamino group phenyl-C₁-C₁₂ alkylamino group, C₁-C₁₂ alkoxyphenyl-C₁-C₁₂alkylamino group, C₁-C₁₂ alkyl phenyl-C₁-C₁₂ alkylamino group, di(C₁-C₁₂ alkoxyphenyl-C₁-C₁₂ alkyl)amino group, di(C₁-C₁₂ alkylphenyl-C₁-C₁₂ alkyl)amino group, 1-naphtyl-C₁-C₁₂ alkylamino group, 2-naphtyl-C₁-C₁₂ alkylamino group, etc.

The substituted silyl group means a silyl group substituted by 1, 2 or 3 groups selected from an alkyl group, aryl group, arylalkyl group, or monovalent heterocyclic group. The substituted silyl group has usually about 1 to 60, preferably 3 to 48 carbon atoms. Said alkyl group, aryl group, arylalkyl group, or monovalent heterocyclic group may have substituent.

Concrete examples of the substituted silyl group include trimethylsilyl group, triethylsilyl group, tripropylsilyl group, tri-1-propylsilyl group, dimethyl-1-propylsilyl group, diethyl-1-propylsilyl group, t-butylsilyldimethylsilyl group, pentyldimethylsilyl group, hexyldimethylsilyl group, heptyl dimethylsilyl group, octyldimethylsilyl group, 2-ethyl hexyl-dimethylsilyl group, nonyldimethylsilyl group, decyl dimethylsilyl group, 3,7-dimethyloctyl-dimethylsilyl group, lauryldimethylsilyl group, phenyl-C₁-C₁₂ alkylsilyl group, C₁-C₁₂ alkoxyphenyl-C₁-C₁₂ alkylsilyl group, C₁-C₁₂ alkyl phenyl-C₁-C₁₂ alkylsilyl group, 1-naphtyl-C₁-C₁₂ alkylsilyl group, 2-naphtyl-C₁-C₁₂ alkylsilyl group, phenyl-C₁-C₁₂ alkyl dimethylsilyl group, triphenylsilyl group, tri-p-xylylsilyl group, tribenzylsilyl group, diphenylmethylsilyl group, t-butyldiphenylsilyl group, dimethylphenylsilyl group, etc.

As the halogen atom, a fluorine atom, a chlorine atom, a bromine atom, and an iodine atom are exemplified.

The acyl group has usually about 2 to 20 carbon atoms, preferably 2 to 18 carbon atoms, and concrete examples thereof include acetyl group, propionyl group, butyryl group, isobutyryl group, pivaloyl group, benzoyl group, trifluoro acetyl group, pentafluorobenzoyl group, etc.

The acyloxy group has usually about 2 to 20 carbon atoms, preferably 2 to 18 carbon atoms, and concrete examples thereof include acetoxy group, propionyloxy group, butyryloxy group, isobutyryloxy group, pivaloyloxy group, benzoyloxy group, trifluoroacetyloxy group, pentafluorobenzoyl oxy group, etc.

Imine residue is a residue in which a hydrogen atom is removed from an imine compound (an organic compound having —N═C— is in the molecule. Examples thereof include aldimine, ketimine, and compounds whose hydrogen atom on N is substituted with an alkyl group etc.), and usually has about 2 to 20 carbon atoms, preferably 2 to 18 carbon atoms. As the concrete examples, groups represented by below structural formulas are exemplified.

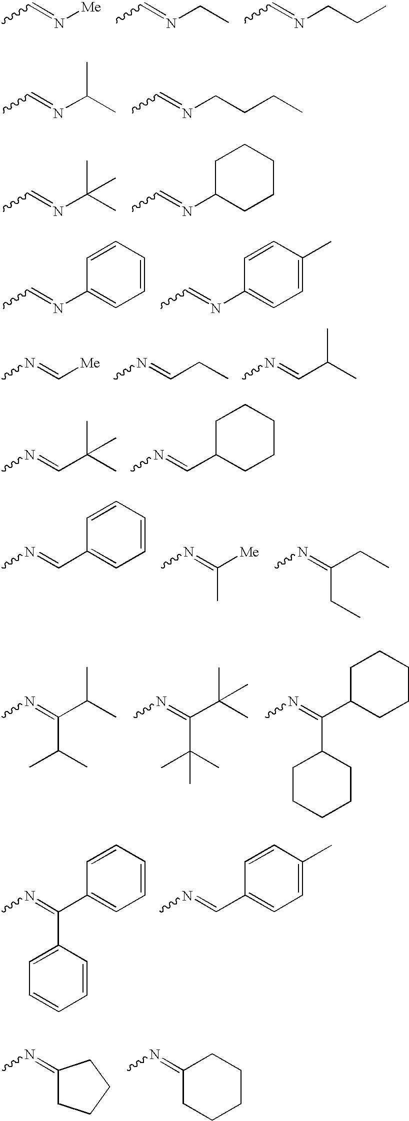

The amide group has usually about 2 to 20 carbon atoms, preferably 2 to 18 carbon atoms, and specific examples thereof include formamide group, acetamide group, propioamide group, butyroamide group, benzamide group, trifluoroacetamide group, pentafluoro benzamide group, diformamide group, diacetoamide group, dipropioamide group, dibutyroamide group, dibenzamide group, ditrifluoro acetamide group, dipentafluorobenzamide group, etc.

Examples of the acid imide group include residual groups in which a hydrogen atom connected with nitrogen atom is removed, and have usually about 2 to 60 carbon atoms, preferably 2 to 48 carbon atoms. As the concrete examples of acid imide group, the following groups are exemplified.

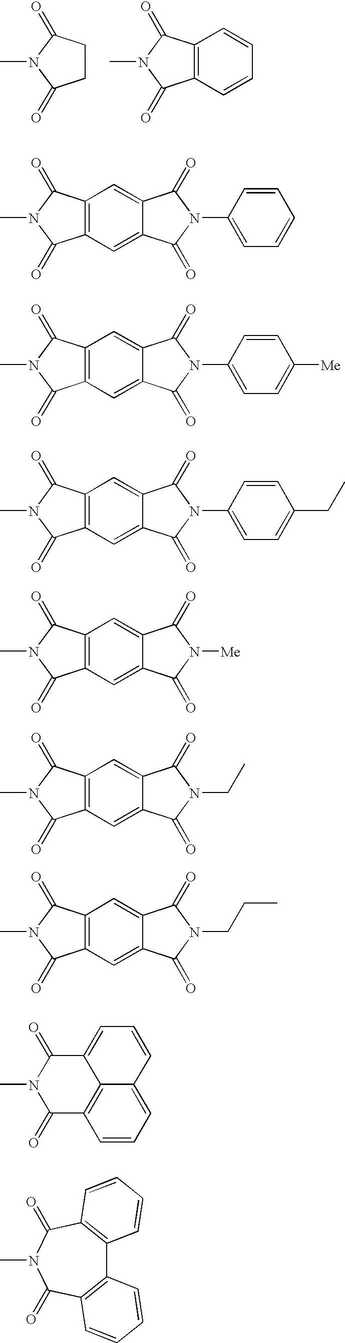

The monovalent heterocyclic group means an atomic group in which a hydrogen atom is removed from a heterocyclic compound, and the number of carbon atoms is usually about 4 to 60, preferably 4 to 20. The number of carbon atoms of the substituent is not contained in the number of carbon atoms of a heterocyclic group. The heterocyclic compound means an organic compound having a cyclic structure in which at least one heteroatom such as oxygen, sulfur, nitrogen, phosphorus, boron, etc. is contained in the cyclic structure as the element other than carbon atoms. Concrete examples thereof include thienyl group, C₁-C₁₂ alkylthienyl group, pyroryl group, furyl group, pyridyl group, C₁-C₁₂ alkylpyridyl group, piperidyl group, quinolyl group, isoquinolyl group, etc.; and thienyl group, C₁-C₁₂ alkylthienyl group, pyridyl group, and C₁-C₁₂ alkylpyridyl group are preferable.

The substituted carboxyl group means a carboxyl group substituted by alkyl group, aryl group, arylalkyl group, or monovalent heterocyclic group, and has usually about 2 to 60, preferably 2 to 48 carbon atoms. Concrete examples thereof include methoxy carbonyl group, ethoxycarbonyl group, propoxycarbonyl group, i-propoxycarbonyl group, butoxycarbonyl group, i-butoxy carbonyl group, t-butoxycarbonyl group, pentyloxycarbonyl group, hexyloxycarbonyl group, cyclohexyloxycarbonyl group, heptyloxycarbonyl group, octyloxycarbonyl group, 2-ethylhexyloxycarbonyl group, nonyloxycarbonyl group, decyloxycarbonyl group, 3,7-dimethyloctyloxycarbonyl group, dodecyloxycarbonyl group, trifluoromethoxycarbonyl group, pentafluoroethoxycarbonyl group, perfluorobutoxycarbonyl group, perfluorohexyloxycarbonyl group, perfluorooctyloxy carbonyl group, phenoxycarbonyl group, naphtoxycarbonyl group, pyridyloxycarbonyl group, etc. Said alkyl group, aryl group, arylalkyl group, or monovalent heterocyclic group may have substituent. The number of carbon atoms of said substituent is not contained in the number of carbon atoms of the substituted carboxyl group.

Among the above, in the groups containing an alkyl, they may be any of linear, branched or cyclic, or may be the combination thereof. In case of not linear, isoamyl group, 2-ethylhexyl group, 3,7-dimethyloctyl group, cyclohexyl group, 4-C₁-C₁₂ alkylcyclohexyl group, etc., are exemplified. Moreover, the tips of two alkyl chains may be connected to form a ring. Furthermore, a part of methyl groups and methylene groups of alkyl, may be replaced by a group containing hetero atom, or a methyl or methylene group substituted by one or more fluorine. As the hetero atoms, an oxygen atom, a sulfur atom, a nitrogen atom, etc., are exemplified.

Furthermore, in the examples of the substituents, when an aryl group or a heterocyclic group is included in the part thereof, they may have one or more substituents.

In order to improve the solubility in a solvent, it is preferable that Ar₁, Ar₂, Ar₃ and Ar₄ have substituent, and one or more of them include an alkyl group or alkoxy group having cyclic or long chain. Examples thereof include cyclopentyl group, cyclohexyl group, pentyl group, isoamyl group, hexyl group, octyl group, 2-ethylhexyl group, decyl group, 3,7-dimethyloctyl group, pentyloxy group, isoamyloxy group, hexyloxy group, octyloxy group, 2-ethylhexyloxy group, decyloxy group, and 3,7-dimethyloctyloxy group.

Two substituents may be connected to form a ring. Further, partial carbon atoms in an alkyl chain may be substituted by a group containing a hetero atom, and as the hetero atom, exemplified are an oxygen atom, sulfur atom, nitrogen atom and the like.

As the repeating unit of the formula (3), mentioned are repeating units of the following formula (7), (9), (10), (11), (12), (13) or (14).

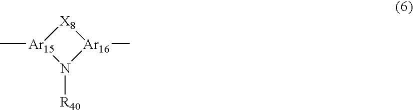

(wherein, Ar₁₅ and Ar₁₆ each independently represent a trivalent aromatic hydrocarbon group or trivalent heterocyclic group, R₄₀ represents an alkyl group, alkoxy group, alkylthio group, alkylsilyl group, alkylamino group, aryl group optionally having a substituent or monovalent heterocyclic group, and X represents a single bond or any of the following groups:

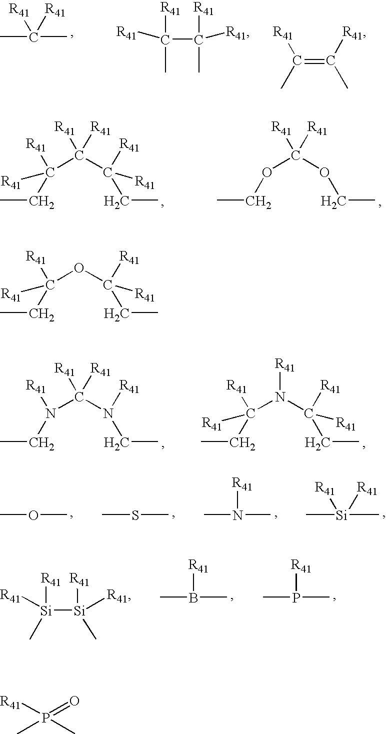

(wherein, R₄₁s each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group or cyano group. When a plurality of R₄₁s are present, they may be the same or different.)].

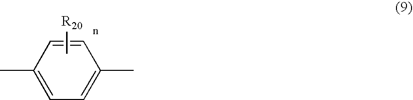

(wherein, R₂₀ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. n represents an integer of 0 to 4. When a plurality of R₂₀s are present, they may be the same or different.)

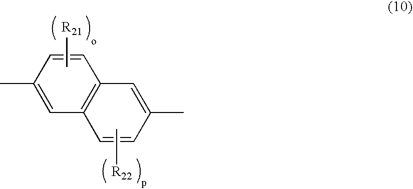

(wherein, R₂₁ and R₂₂ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. o and p each independently represent an integer of 0 to 3. When R₂₁ and R₂₂ are present each in plural number, they may be the same or different.)

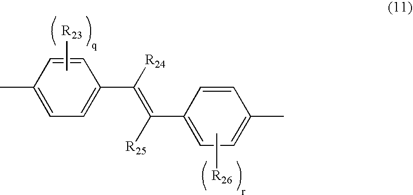

(wherein, R₂₃ and R₂₆ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. q and r each independently represent an integer of 0 to 4. R₂₄ and R₂₅ each independently represent a hydrogen atom, alkyl group, aryl group, monovalent heterocyclic group, carboxyl group, substituted carboxyl group or cyano group. When R₂₃ and R₂₆ are present in plural number, they may be the same or different.)

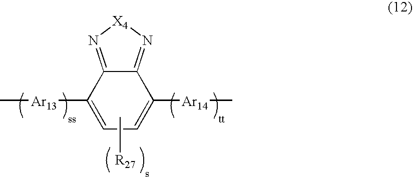

(wherein, R₂₇ represents an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. s represents an integer of 0 to 2. Ar₁₃ and Ar₁₄ each independently represent an arylene group, divalent heterocyclic group or divalent group having a metal complex structure. ss and tt each independently represent 0 or 1. X₄ represents O, S, SO, SO₂, Se or Te. When a plurality of R₂₇s are present, they may be the same or different.)

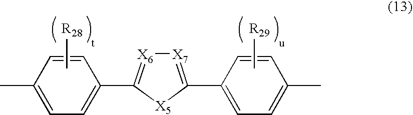

(wherein, R₂₈ and R₂₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. t and u each independently represent an integer of 0 to 4. X₅ represents O, S, SO₂, Se, Te, N—R₃₀ or SiR₃₁R₃₂. X₆ and X₇ each independently represent N or C—R₃₃. R₃₀, R₃₁, R₃₂ and R₃₃ each independently represent a hydrogen atom, alkyl group, aryl group, arylalkyl group or monovalent heterocyclic group. When R₂₈, R₂₉ and R₃₃ are present in plural number, they may be the same or different.)

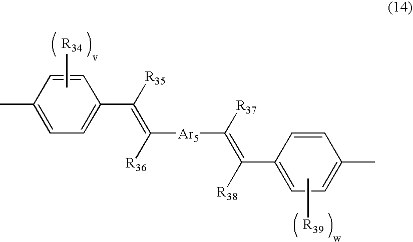

(wherein, R₃₄ and R₃₉ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group or cyano group. v and w each independently represent an integer of 0 to 4. R₃₅, R₃₆, R₃₇ and R₃₈ each independently represent a hydrogen atom, alkyl group, aryl group, monovalent heterocyclic group, carboxyl group, substituted carboxyl group or cyano group. Ar₅ represents an arylene group, divalent heterocyclic group or divalent group having a metal complex structure. When R₃₄ and R₃₉ are present in plural number, they may be the same or different).

Examples of the repeating unit represented by the above formula (4) include a repeating unit of the following formula (7).

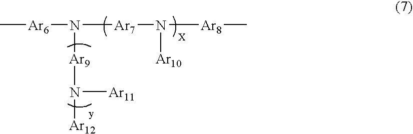

(wherein, Ar₆, Ar₇, Ar₈ and Ar₉ each independently represent an arylene group or divalent heterocyclic group. Ar₁₀, Ar₁₁ and Ar₁₂ each independently represent an aryl group or monovalent heterocyclic group. Ar₆, Ar₇, Ar₈, Ar₉ and Ar₁₀ may have a substituent. x and y each independently represent 0 or 1, and 0=x+y=1).

Among the structures represented by the above formula (7), structures represented by the below formula (15) are preferable.

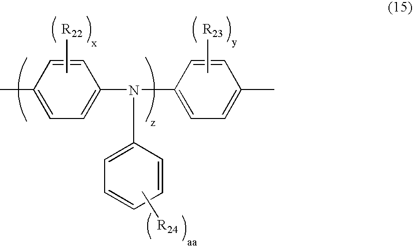

(wherein, R₂₂, R₂₃ and R₂₄ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group, or cyano group. x and y each independently represent an integer of 0-4. z represents an integer of 1-2. aa represents an integer of 0-5.)

As R₂₄ in the above formula (15), an alkyl group, alkoxy group, aryl group, aryloxy group, arylalkyl group, arylalkoxy group, substituted amino group are preferable. As the substituted amino group, diaryl amino group is preferable, and diphenyl amino group is more preferable.

In the above, although preferable combination thereof differs according to a dendrimer combined with the polymer, combinations of the above formula (I-6) with the above formula (7), (8) or (9) are preferable, and combinations of formula (I-6) with formula (8) or (9) are more preferable.

In the structure represented by the above formula (1-6), it is preferable that Y is —O—, —S—, or —C(R₁)(R₂). [R₁ and R₂ represent the same meaning as the above.]

Furthermore, the end group of conjugated polymer used for the present invention may also be protected with a stable group, since light emitting property and life time when made into a device may be deteriorated if a polymerizable group remains intact. Those having a conjugated bond continuing to a conjugated structure of the main chain are preferable, and there are exemplified structures connected to an aryl group or heterocyclic group via a carbon-carbon bond. Specifically, substituents described as Chemical Formula 10 in JP-A-9-45478 are exemplified.

The conjugated polymer used for the present invention may also be a random, block or graft copolymer, or a polymer having an intermediate structure thereof, for example, a random copolymer having block property. From the viewpoint for obtaining a polymer having high quantum yield, random copolymers having block property and block or graft copolymers are preferable than complete random copolymers. Further, a polymer having a branched main chain and more than three terminals, and a dendrimer may also be included.

It is preferable that the conjugated polymer used for the present invention has a polystyrene reduced number average molecular weights of 10³-10⁸, and more preferably 10⁴-10⁷.

As the manufacture method of the conjugated polymer used for the polymer material of the present invention, a monomer having a plurality of polymerizable groups is dissolved in an organic solvent according to necessity, and can be reacted using alkali or appropriate catalyst, at a temperature between the boiling point and the melting point of the organic solvent.

For example, known methods which can be used are described in: Organic Reactions, volume 14, page 270-490, John Wiley a Sons, Inc., 1965; Organic Syntheses, Collective Volume VI, page 407-411, John Wiley & Sons, Inc., 1988; Chemical Review (Chem. Rev.), Volume 95, page 2457 (1995); Journal of Organometallic Chemistry (J. Organomet. Chem.), Volume 576, page 147 (1999); and Macromolecular Chemistry, Macromolecular Symposium (Makromol. Chem., Macromol. Symp.), Volume 12th, page 229 (1987).

In the manufacture method of the polymer compound used for the polymer material of the present invention, known condensation reactions can be used as the method of carrying out condensation polymerization. As the method of condensation polymerization, in case of producing double bond, for example, a method described in JP-A-5-202355 is exemplified.

That is, exemplified are: polymerization by Wittig reaction of a compound having formyl group and a compound having phosphonium-methyl group, or a compound having formyl group and phosphonium-methyl group; polymerization by Heck reaction of a compound having vinyl group and a compound having halogen atom; polycondensation by dehydrohalogenation method of a compound having two or more monohalogenated-methyl groups; polycondensation by sulfonium-salt decomposition method of a compound having two or more sulfonium-methyl groups; polymerization by Knoevenagel reaction of a compound having formyl group and a compound having cyano group; and polymerization by McMurry reaction of a compound having two or more formyl groups.

When a polymer of the present invention has a triple bond in the main chain by condensation polymerization, for example, Heck reaction can be used.

In case of producing neither a double bond nor a triple bond, exemplified are: a method of polymerization by Suzuki coupling reaction from corresponding monomer; a method of polymerization by Grignard reaction; a method of polymerization by Ni(0) complex; a method of polymerization by oxidizing agent, such as FeCl₃; a method of electrochemical oxidative polymerization; and a method by decomposition of an intermediate polymer having a suitable leaving group.

Among these, a polymerization by Wittig reaction, a polymerization by Heck reaction, a polymerization by Knoevenagel reaction, a method of polymerization by Suzuki coupling reaction, a method of polymerization by Grignard reaction, and a method of polymerization by nickel zero-valent complex are preferable, since it is easy to control the structure.

When the reactive substituent in the raw monomer for the polymer used for the present invention is a halogen atom, alkylsulfonate group, arylsulfonate group, or arylalkylsulfonate group, a manufacture method by condensation polymerization in the existence of nickel-zerovalent-complex is preferable.

As the raw material compound, a dihalogenated compound, bis (alkylsulfonate) compound, bis(arylsulfonate) compound, bis (arylalkylsulfonate) compound, or halogen-alkylsulfonate compound, halogen-arylsulfonate compound, halogen-arylalkylsulfonate compound, alkylsulfonate-arylsulfonate compound, alkylsulfonate-arylalkylsulfonate compound are exemplified.

Moreover, When the reactive substituent in the raw monomer for the polymer compound used for the present invention is a halogen atom, alkylsulfonate group, arylsulfonate group, arylalkylsulfonate group, boric-acid group, or boric acid ester group, it is preferable that the ratio of the total mol of a halogen atom, alkylsulfonate group, arylsulfonate group, and arylalkylsulfonate group, with the total of boric-acid group and boric acid ester group is substantially 1 (usually in the range of 0.7 to 1.2), and the manufacture method is a condensation polymerization using a nickel catalyst or a palladium catalyst.

Concrete examples of the combination of raw material compounds include combinations of a dihalogenated compound, bis (alkylsulfonate) compound, bis(arylsulfonate) compound or bis(arylalkylsulfonate) compound, with a diboric acid compound, or diboric acid ester compound.

Moreover, halogen-boric acid compound, halogen-boric acid ester compound, alkylsulfonate-boric acid compound, alkylsulfonate-boric acid ester compound, arylsulfonate-boric acid compound, arylsulfonate-boric acid ester compound, arylalkylsulfonate-boric acid compound, and arylalkylsulfonate-boric acid ester compound are exemplified.

It is preferable that the organic solvent used is subjected to a deoxygenation treatment sufficiently and the reaction is progressed under an inert atmosphere, generally for suppressing a side reaction, though the treatment differs depending on compounds and reactions used. Further, it is preferable to conduct a dehydration treatment likewise. However, this is not applicable in the case of a reaction in a two-phase system with water, such as a Suzuki coupling reaction.

For the reaction, alkali or a suitable catalyst is added. It can be selected according to the reaction to be used. It is preferable that the alkali or the catalyst can be dissolved in a solvent used for a reaction. Example of the method for mixing the alkali or the catalyst, include a method of adding a solution of alkali or a catalyst slowly, to the reaction solution with stirring under an inert atmosphere of argon, nitrogen, etc. or conversely, a method of adding the reaction solution to the solution of alkali or a catalyst slowly.

When the polymer materials of the present invention are used for a polymer LED, the purity thereof exerts an influence on light emitting property, therefore, it is preferable that a monomer is purified by a method such as distillation, sublimation purification, re-crystallization and the like before being polymerized. Further, it is preferable to conduct a purification treatment such as re-precipitation purification, chromatographic separation and the like after the polymerization.

Next, the dendrimer (B) used in the polymer material of the present invention will be explained.

The dendrimer represents a super-branched polymer of dendritic morphology, which, for example, is introduced in the literature (Kobunshi Vol. 47, Nov. 812, page 1998) and WO02/066575, and designed and synthesized in order to have various functions. As an example of the dendrimer, the following is mentioned:

CORE-[D¹]_{Z1}[D²]_{Z2}

(wherein, CORE represents a (Z1+Z2)-valent atom or atomic group, and Z1 and Z2 represent an integer of 1 or more. D¹ and D² each independently represent a dendron having a dendritic structure, and when D¹ and D² are present each in a plural number, they may be the same or different, and at least one of D¹ and D² is a conjugated system containing an aromatic ring optionally having a hetero atom.).

CORE represents a (Z1+Z2)-valent atom or atomic group which is exemplified with those described in IEEE2002, p 195 (Conference Process), WO02/066575 and WO02/066575.

Furthermore, the dendritic structure mentioned above is disclosed, for example, in Kobunshi Vol. 52, Aug., p 578 (2003) and M&BE, Vol. 14, No. 3, p 169 (2003), and occasionally represented as a branched structure.

The aromatic ring optionally having a hetero atom is exemplified with a benzene ring, pyridine ring, pyrimidine ring, naphthalene ring or a ring represented by the above-mentioned general formula (1).

The dendrimer is further schematically represented as follows:

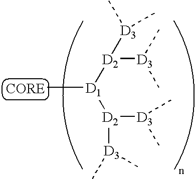

In the above figure, CORE represents a luminescent structural unit, for example, having a metal complex structure. D₁, D₂, and D₃ represent a dendron and are a unit of branching. Although the above figure shows branching units ranging to D3, the branching unit may repeat subsequently beyond D₃. Furthermore, the branching units may have a same or different structure. n is an integer of 1 or more, when n is 2 or more, the branching units belonging in the respective groups may be the same or different. The branching unit has, for example, structures such as trivalent aromatic ring, condensed ring and heterocycle and the like. Furthermore, the end of terminating the branching may have a surface group. The surface group is an atom other than a hydrogen atom, an alkyl group, an alkoxy group and the like.

In view of enhancing solubility, it is preferable that at least one of the surface groups on the dendrimer is the one other than a hydrogen atom. A luminescent dendrimer of the dendrimers consists of a dendric multi-branched structure of which center includes a luminescent structural unit (CORE of the above-mentioned figure). As the luminescent structural unit, mentioned is a structure containing at least one of stilbene, an aromatic condensed ring, a heterocycle, a condensed ring having a heterocycle, and a metal complex structure.

Among the dendrimers, the luminescent dendrimer is preferable, and the dendrimer exhibiting luminescence from an excited triplet state is more preferable.

Herein, the dendrimer exhibiting luminescence from an excited triplet state includes, for example, compounds in which phosphorescence is observed, as well as compounds in which luminescence is observed besides phosphorescence

Specific examples of the dendrimer are disclosed, for example, in WO02/066552. Furthermore, the luminescent portion of the dendrimers is exemplified with metal complex structures disclosed, for example, in Nature, (1998), 395, 151, Appl. Phys. Lett. (1999), 75(1), 4, Proc. SPIE-Int. Soc. Opt. Eng. (2001), 4105 (Organic Light-Emitting Materials and Devices IV), 119, J. Am. Chem. Soc., (2001), 123, 4304, Appl. Phys. Lett., (1997), 71(18), 2596, Syn. Met., (1998), 94(1), 103, Syn. Met., (1999), 99(2), 1361 Adv. Mater., (1999), 11(10), 852, etc.

As the dendrimer, preferable is the one having a metal complex structure as the partial structure thereof. A central metal to be contained in the core of the dendrimer is the metal which usually consists of an atom having atomic number of 50 or more, has a spin-orbit interaction with the complex, and is able to cause an intersystem crossing between singlet state and triplet state, such metal is exemplified with rhenium, iridium, osmium, scandium, yttrium, platinum, gold and lanthanoids such as europium, terbium, thulium, dysprosium, samarium, praseodymium, gadolinium, and the like, and preferable are rhenium, iridium, platinum, gold, europium, and terbium.

As a ligand of the core portion of the dendrimer, mentioned are, for example, 8-quinolinol and its derivatives, benzoquinolinol and its derivatives, 2-phenyl-pyridine and its derivatives, 2-phenyl-benzothiazole and its derivatives, 2-phenyl-benzooxazole and its derivatives, porphyrin and its derivatives, and the like.

An amount of the dendrimer (B) in the material of the present invention is not particularly limited because the amount differs depending on the kind of the conjugated polymer (A) to be combined or on properties to be optimized; being usually 0.01 to 80 parts by weight, and preferably 0.1 to 60 parts by weight, when the amount of the polymer (A) is defined as 100 parts by weight.

Furthermore, the polymer material of the invention may be a polymer material in which the molecule of the conjugated polymer (A) contains the dendrimer (B) as a partial structure thereof. (The embodiment mentioned in the above (ii))

Such polymer material is exemplified with the one that includes the repeated unit represented by the formula (1), has a polystyrene-reduced number-average molecular weight of 10³ to 10⁸ and has the dendrimer (B) in the side chain, main chain and/or at the end thereof. In the case of having the dendrimer (B) in the main chain, not only the one integrating the dendrimer (B) in the main chain consisting of a linear polymer but also the one having 3 or more polymer chains linking from the dendrimer (B) are included.

A polymer structure having in the side chain of the conjugated polymer (A) the dendrimer (B) structure which exhibits a luminescence from an excited triplet state is, for example, represented by the following formula:

—Ar¹⁸—

[wherein Ar¹⁸ represents a divalent aromatic group or divalent heterocyclic group having one or more atom(s) selected from the group consisting of an oxygen atom, silicon atom, germanium atom, tin atom, phosphorus atom, boron atom, sulfur atom, selenium atom, and a tellurium atom, and the Ar¹⁸ has one or more and four or less group(s) represented by -L-X, wherein X represents a monovalent group containing a dendrimer which exhibits luminescence from an excited triplet state, and L represents a single bond, —O—, —S—, —CO—, —CO₂—, —SO—, —SO₂—, —SiR⁶⁸R⁶⁹—, NR⁷⁰—, —BR⁷¹—, —PR⁷²—, —P(═O)(R⁷³)—, optionally substituted alkylene group, optionally substituted alkenylene group, optionally substituted alkynylene group, optionally substituted arylene group, or optionally substituted divalent heterocyclic group, when the alkylene group, alkenylene group and alkynylene group contain a —CH₂— group, one or more —CH₂— group(s) contained in the alkylene group, one or more —CH₂— group(s) contained in the alkenylene group and one or more —CH₂— group(s) contained in the alkynylene group, may be replaced respectively with a group selected from the group consisting of —O—, —S—, —CO—, —CO₂—, —SO—, —SO₂—, —SiR⁷⁴R⁷⁵—, NR⁷⁶—, —BR⁷⁷—, —PR⁷⁸— and —P(═O)(R⁷⁹)—. R⁶⁸, R⁶⁹, R⁷⁰, R⁷¹, R⁷², R⁷³, R⁷⁴, R⁷⁵, R⁷⁶, R⁷⁷, R⁷⁸ and R⁷⁹ are each independently represents a group selected from the group consisting of a hydrogen atom, alkyl group, aryl group, monovalent heterocyclic group and cyano group. Ar¹⁸ may, besides the group represented by -L-X, further has a group selected from the group consisting of an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imine residue, amide group, acid imide group, monovalent heterocyclic group, carboxyl group, substituted carboxyl group and cyano group. When Ar¹⁸ has a plurality of substituents, they may be the same or different each other.]

Herein, the divalent aromatic group is exemplified with a phenylene, pyridinylene, pyrimidylene, naphtylene or the ring represented by the above-mentioned general formula (1).

A polymer structure having in the main chain of the conjugated polymer (A) the dendrimer (B) structure which exhibits a luminescence from an excited triplet state is, for example, represented by the following formula:

-L₁-

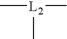

[wherein L₁ and L₂ represent the dendrimer structure which exhibits a luminescence from an excited triplet state, and di- or trivalent bonding group in the formula is contained in the dendron at the end of the dendrimer structure and/or the ligand of the core portion and links with a repeating unit forming the main chain of the polymer chain.]

A polymer structure having at the end of the conjugated polymer (A) the dendrimer (B) structure which exhibits a luminescence from an excited triplet state is, for example, represented by the following formula:

—X-L₃

[wherein L₃ represents the monovalent group containing the dendrimer structure which exhibits a luminescence from an excited triplet state, and the monovalent bonding group is contained in the dendron at the end of the dendrimer structure and/or the ligand of the core portion and links with X. X represents a single bond, optionally substituted alkenylene group, optionally substituted alkynylene group, optionally substituted arylene group, or optionally substituted divalent heterocyclic group.]

The polymer having the dendrimer structure at the side chain, main chain or at the end thereof can be produced, for example, with using a monomer having a dendrimer structure as one of raw ingredients with the above-mentioned method.

The present invention relates to a polymer light-emitting material containing the above-mentioned polymer material.

In this case, it is preferable that the dendrimer is a luminescent dendrimer.

Next, a device of the present invention is explained.

The device of the present invention is characterized by having a layer containing the polymer material of the present invention between electrodes which are composed of an anode and cathode.

As the device of the present invention, polymer light-emitting devices, photoelectric devices and the like are mentioned.

When the device of the present invention is a polymer light-emitting device, it is preferable that the layer containing the polymer material of the present invention is a light-emitting layer.

Moreover, the polymer LED of the present invention include: a polymer LED having an electron transporting layer between a cathode and a light emitting layer; a polymer LED having an hole transporting layer between an anode and a light emitting layer; and a polymer LED having an electron transporting layer between an cathode and a light emitting layer, and a hole transporting layer between an anode and a light emitting layer.

Furthermore, exemplified are: a polymer-LED in which a layer containing a conductive polymer is disposed between at least one of the above electrodes and a light emitting layer adjacently to the electrode; and a polymer LED in which a buffer layer having a mean film thickness of 2 nm or less is disposed between at least one of the above electrodes and a light emitting layer adjacently to the electrode.

Specifically, the following structures a)-d) are exemplified.

a) anode/light emitting layer/cathode
b) anode/hole transporting layer/light emitting layer/cathode
c) anode/light emitting layer/electron transporting layer/cathode
d) anode/hole transporting layer/light emitting layer/electron transporting layer/cathode
(wherein, “/” indicates adjacent lamination of layers. Hereinafter, the same).

Herein, the light emitting layer is a layer having function to emit a light, the hole transporting layer is a layer having function to transport a hole, and the electron transporting layer is a layer having function to transport an electron. Herein, the electron transporting layer and the hole transporting layer are generically called a charge transporting layer.

The light emitting layer, hole transporting layer and electron transporting layer also may be used each independently in two or more layers.

Charge transporting layers disposed adjacent to an electrode, that having function to improve charge injecting efficiency from the electrode and having effect to decrease driving voltage of an device are particularly called sometimes a charge injecting layer (hole injecting layer, electron injecting layer) in general.

For enhancing adherence with an electrode and improving charge injection from an electrode, the above-described charge injecting layer or insulation layer having a thickness of 2 nm or less may also be provided adjacent to an electrode, and further, for enhancing adherence of the interface, preventing mixing and the like, a thin buffer layer may also be inserted into the interface of a charge transporting layer and light emitting layer.

The order and number of layers laminated and the thickness of each layer can be appropriately applied while considering light emitting efficiency and life of the device.

In the present invention, as the polymer LED having a charge injecting layer (electron injecting layer, hole injecting layer) provided, there are listed a polymer LED having a charge injecting layer provided adjacent to a cathode and a polymer LED having a charge injecting layer provided adjacent to an anode.

For example, the following structures e) to p) are specifically exemplified.

e) anode/charge injecting layer/light emitting layer/cathode
f) anode/light emitting layer/charge injecting layer/cathode
g) anode/charge injecting layer/light emitting layer/charge injecting layer/cathode
h) anode/charge injecting layer/hole transporting layer/light emitting layer/cathode
i) anode/hole transporting layer/light emitting layer/charge injecting layer/cathode
j) anode/charge injecting layer/hole transporting layer/light emitting layer/charge injecting layer/cathode
k) anode/charge injecting layer/light emitting layer/electron transporting layer/cathode
l) anode/light emitting layer/electron transporting layer/charge injecting layer/cathode
m) anode/charge injecting layer/light emitting layer/electron transporting layer/charge injecting layer/cathode
n) anode/charge injecting layer/hole transporting layer/light emitting layer/electron transporting layer/cathode
o) anode/hole transporting layer/light emitting layer/electron transporting layer/charge injecting layer/cathode
p) anode/charge injecting layer/hole transporting layer/light emitting layer/electron transporting layer/charge injecting layer/cathode

As the specific examples of the charge injecting layer, there are exemplified layers containing an conducting polymer, layers which are disposed between an anode and a hole transporting layer and contain a material having an ionization potential between the ionization potential of an anode material and the ionization potential of a hole transporting material contained in the hole transporting layer, layers which are disposed between a cathode and an electron transporting layer and contain a material having an electron affinity between the electron affinity of a cathode material and the electron affinity of an electron transporting material contained in the electron transporting layer, and the like.

When the above-described charge injecting layer is a layer containing an conducting polymer, the electric conductivity of the conducting polymer is preferably 10⁻⁵ S/cm or more and 10³ S/cm or less, and for decreasing the leak current between light emitting pixels, more preferably 10⁻⁵ S/cm or more and 10² S/cm or less, further preferably 10⁻⁵ S/cm or more and 10¹ S/cm or less.

Usually, to provide an electric conductivity of the conducting polymer of 10⁻⁵ S/cm or more and 10³ S/cm or less, a suitable amount of ions are doped into the conducting polymer.

Regarding the kind of an ion doped, an anion is used in a hole injecting layer and a cation is used in an electron injecting layer. As examples of the anion, a polystyrene sulfonate ion, alkylbenzene sulfonate ion, camphor sulfonate ion and the like are exemplified, and as examples of the cation, a lithium ion, sodium ion, potassium ion, tetrabutyl ammonium ion and the like are exemplified.

The thickness of the charge injecting layer is for example, from 1 nm to 100 nm, preferably from 2 nm to 50 nm.

Materials used in the charge injecting layer may properly be selected in view of relation with the materials of electrode and adjacent layers, and there are exemplified conducting polymers such as polyaniline and derivatives thereof, polythiophene and derivatives thereof, polypyrrole and derivatives thereof, poly(phenylene vinylene) and derivatives thereof, poly(thienylene vinylene) and derivatives thereof, polyquinoline and derivatives thereof, polyquinoxaline and derivatives thereof, polymers containing aromatic amine structures in the main chain or the side chain, and the like, and metal phthalocyanine (copper phthalocyanine and the like), carbon and the like.

The insulation layer having a thickness of 2 nm or less has function to make charge injection easy. As the material of the above-described insulation layer, metal fluoride, metal oxide, organic insulation materials and the like are listed. As the polymer LED having an insulation layer having a thickness of 2 nm or less, there are listed polymer LEDs having an insulation layer having a thickness of 2 nm or less provided adjacent to a cathode, and polymer LEDs having an insulation layer having a thickness of 2 nm or less provided adjacent to an anode.

Specifically, there are listed the following structures q) to ab) for example.

q) anode/insulation layer having a thickness of 2 nm or less/light emitting layer/cathode
r) anode/light emitting layer/insulation layer having a thickness of 2 nm or less/cathode
s) anode/insulation layer having a thickness of 2 nm or less/light emitting layer/insulation layer having a thickness of 2 nm or less/cathode
t) anode/insulation layer having a thickness of 2 nm or less/hole transporting layer/light emitting layer/cathode
u) anode/hole transporting layer/light emitting layer/insulation layer having a thickness of 2 nm or less/cathode
v) anode/insulation layer having a thickness of 2 nm or less/hole transporting layer/light emitting layer/insulation layer having a thickness of 2 nm or less/cathode
w) anode/insulation layer having a thickness of 2 nm or less/light emitting layer/electron transporting layer/cathode
x) anode/light emitting layer/electron transporting layer/insulation layer having a thickness of 2 nm or less/cathode
y) anode/insulation layer having a thickness of 2 nm or less/light emitting layer/electron transporting layer/insulation layer having a thickness of 2 nm or less/cathode
z) anode/insulation layer having a thickness of 2 nm or less/hole transporting layer/light emitting layer/electron transporting layer/cathode
aa) anode/hole transporting layer/light emitting layer/electron transporting layer/insulation layer having a thickness of 2 nm or less/cathode
ab) anode/insulation layer having a thickness of 2 nm or less/hole transporting layer/light emitting layer/electron transporting layer/insulation layer having a thickness of 2 nm or less/cathode

A hole preventing layer is a layer having a function of transporting electrons and confining the holes transported from anode, and the layer is prepared at the interface on the side cathode of the light emitting layer, and consists of a material having larger ionization potential than that of the light emitting layer, for example, a metal complex of bathocuproine, 8-hydroxy quinoline, or derivatives thereof.

The film thickness of the hole preventing layer, for example, is 1 nm to 100 nm, and preferably 2 nm to 50 nm.

Specifically, there are listed the following structures ac) to an) for example.

ac) anode/charge injection layer/light emitting layer/hole preventing layer/cathode
ad) anode/light emitting layer/hole preventing layer/charge injection layer/cathode
ae) anode/charge injection layer/light emitting layer/hole preventing layer/charge injection layer/cathode
af) anode/charge injection layer/hole transporting layer/light emitting layer/hole preventing layer/cathode
ag) anode/hole transporting layer/light emitting layer/hole preventing layer/charge injection layer/cathode
ah) anode/charge injection layer/hole transporting layer/light emitting layer/hole preventing layer/charge injection layer/cathode
ai) anode/charge injection layer/light emitting layer/hole preventing layer/charge transporting layer/cathode
aj) anode/light emitting layer/hole preventing layer/electron transporting layer/charge injection layer/cathode
ak) anode/charge injection layer/light emitting layer/hole preventing layer/electron transporting layer/charge injection layer/cathode
al) anode/charge injection layer/hole transporting layer/light emitting layer/hole preventing layer/charge transporting layer/cathode
am) anode/hole transporting layer/light emitting layer/hole preventing layer/electron transporting layer/charge injection layer/cathode
an) anode/charge injection layer/hole transporting layer/light emitting layer/hole preventing layer/electron transporting layer/charge injection layer/cathode

In producing a polymer LED, when a film is formed from a solution by using such polymer materials of the present invention, only required is removal of the solvent by drying after coating of this solution, and even in case of mixing of a charge transporting material and a light emitting material, the same method can be applied, causing an extreme advantage in production. As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

As an ink composition (for example, being used in a form of solution for printing methods and the like), the composition contains at least one kind of the polymer materials of the present invention.

The ink composition, besides the polymer materials of the present invention, usually contains a solvent and may contain a hole transporting material, electron transporting material, light-emitting material, stabilizer, additive to control viscosity and/or surface tension and additives such as antioxidant and the like.

The ratio of the polymer material of the present invention in the ink composition is usually 20 wt % to 100 wt % based on the total weight of the ink composition excluding a solvent, and preferably 40 wt % to 100 wt %.

Furthermore, the ratio of the solvent in the ink composition is 1 wt % to 99.9 wt % based on the total weight of the ink composition, preferably 60 wt % to 99.9 wt %, and more preferably 90 wt % to 99.5 wt %.

A viscosity of the ink composition varies depending on printing methods; when the ink composition passes through a discharging device in methods such as ink-jet printing and the like, it is preferable that, to prevent clogging or flight deflection during discharging, the viscosity is in the range of 1 to 20 mPa·s at 25° C.

As the solvent used for the ink composition, preferable is the one capable of dissolving or uniformly dispersing the polymer material of the present invention. As the solvent, exemplified are chlorine solvents such as chloroform, methylene chloride, 1,2-dichloroethane, 1,1,2-trichloroethane, chlorobenzene, o-dichlorobenzene and the like, ether solvents such as tetrahydrofuran, dioxane and the like, aromatic hydrocarbon solvents such as toluene, xylene and the like, aliphatic hydrocarbon solvents such as cyclohexane, methylcyclohexane, n-pentane, n-hexane, n-heptane, n-octane, n-nonane, n-decan and the like, ketone solvents such as acetone, methyl ethyl ketone, cyclohexanone and the like, ester solvents such as ethyl acetate, butyl acetate, ethyl cellosolve acetate and the like, polyhydric alcohols such as ethylene glycol, ethylene glycol monobutyl ether, ethylene glycol monoethyl ether, ethylene glycol monomethyl ether, dimethoxy ethane, propylene glycol, diethoxy methane, triethylene glycol monoethyl ether, glycerol, 1,2-hexanediol and the like, and the derivative thereof, alcohol solvents such as methanol, ethanol, propanol, isopropanol, cyclohexanol and the like, sulfoxide solvents such as dimethyl sulfoxide and the like, and amide solvents such as N-methyl-2-pyrrolidone, N,N-dimethyl formamide and the like. Furthermore, these solvents may be used alone or as a combination of a plural kinds thereof. Among the solvents mentioned above, preferable is a solvent containing one or more kinds of organic solvents which have a structure including at least one or more benzene ring(s), a melting point of 0° C. or less, and a boiling point of 100° C. or more.

As a kind of solvents, in view of a solubility of the polymer material of the present invention to an organic solvent, a homogeneity at the time of forming a film, viscosity characteristics and the like, preferable are an aromatic hydrocarbon solvent, aliphatic hydrocarbon solvent, an ester solvent and a ketone solvent, preferable are toluene, xylene, ethylbenzene, diethylbenzene, trimethylbenzene, n-propylbenzene, i-propylbenzene, n-butylbenzene, i-butylbenzene, s-butylbenzene, anisole, ethoxybenzene, 1-methylnaphthalene, cyclohexane, cyclohexanone, cyclohexylbenzene, bicyclohexyl, cyclohexenylcyclohexanone, n-heptylcyclohexane, n-hexylcyclohexane, 2-propylcyclohexanone, 2-heptanone, 3-heptanone, 4-heptanone, 2-octanone, 2-nonanone, 2-decanone, and dicyclohexylketone, and more preferable is the one containing at least one kind selected from xylene, anisole, cyclohexylbenzene and bicyclohexyl.

The kinds of the solvents of the ink composition, in view of a film forming ability, device's characteristics and the like, include preferably 2 or more kinds, more preferably 2 to 3 kinds, and more preferably 2 kinds.

When 2 kinds of solvents are contained in the ink composition, one kind of the solvents may be a solid state at 25° C. In view of the film forming ability, it is preferable that one kind of the solvents is the solvent having a boiling point of 180° C. or more and the other one kind of the solvents is the solvent having a boiling point of 180° C. or less, and more preferable that one kind of the solvents is the solvent having a boiling point of 200° C. or more and the other one kind of the solvents is the solvent having a boiling point of 180° C. or less. Moreover, in view of the viscosity, it is preferable that both of the 2 kinds of solvents dissolves 1 wt % or more of the polymer material of the present invention at 60° C., and preferable that one kind solvent of the two kinds of the solvents dissolves 1 wt % or more of the polymer material of the present invention at 25° C.

When 3 kinds of solvents are contained in the ink composition, 1 to 2 kinds of the solvents may be a solid state at 25° C. In view of the film forming ability, it is preferable that at least one kind solvent of the 3 kinds of the solvents is the solvent having a boiling point of 180° C. or more and at least another one kind solvent is the solvent having a boiling point of 180° C. or less, and more preferable that at least one kind solvent of the 3 kinds of the solvents is the solvent having a boiling point of 200° C. or more and 300° C. or less and at least another one kind solvent is the solvent having a boiling point of 180° C. or less. Moreover, in view of the viscosity, it is preferable that 2 kind solvents of the 3 kind of the solvents dissolves 1 wt % or more of the polymer material of the present invention at 60° C., and preferable that one kind solvent of the 3 kinds of the solvents dissolves 1 wt % or more of the polymer material of the present invention at 25° C.

When 2 or more kinds of solvents are contained in the ink composition, in view of the viscosity and film forming ability, the solvent having the highest boiling point occupy 40 to 90 wt % of the total weight of the solvents of the ink composition, preferably 50 to 90 wt %, and more preferably 65 to 85 wt %.

As the ink composition of the present invention, in view of the viscosity and film forming ability, preferable is the composition including anisole and bicyclohexyl, composition including anisole and cyclohexylbenzene, composition including xylene and bicyclohexyl, and composition including xylene and cyclohexylbenzene,

Among the additives capable of being contained in the ink composition of the present invention,

as the hole transporting materials, mentioned are polyvinylcarbazole or its derivatives, polysilane or its derivatives, polysiloxane derivatives having an aromatic amine at a side chain or main chain thereof, pyrazoline derivatives, arylamine derivatives, stilbene derivatives, triphenyldiamine derivatives, polyaniline or its derivatives, polythiophene or its derivatives, polypyrrole or its derivatives, poly(p-phenylenevinylene) or its derivatives, and poly (2,5-thienylenevinylene) or its derivative.

As the electron transporting materials, mentioned are oxadiazole derivatives, anthraquinodimethane or its derivatives, benzoquinone or its derivatives, naphthoquinone or its derivatives, anthraquinone or its derivatives, a tetra-cyanoanthraquinodimethane or its derivatives, fluorenone derivatives, diphenyldicyanoethylene or its derivatives, diphenoquinone derivatives, or 8-hydroxyquinoline or its derivatives' metal complexes, poly quinoline or its derivatives, polyquinoxaline or its derivatives, polyfluorene or its derivatives.

As the light-emitting materials, mentioned are naphthalene derivatives, anthracene or its derivatives, perylene or its derivatives, coloring matters such as a polymethine, xanthene, coumarin and cyanine, 8-hydroxyquinoline or its derivatives' metal complexes, aromatic amines, tetra-phenylcyclopentadiene or its derivatives, and tetra-phenylbutadiene or its derivatives.

As the stabilizers, mentioned are phenolic antioxidants, phosphorus antioxidants and the like.

As the additives to adjust the viscosity and/or surface tension, high-molecular-weight polymer compounds (thickeners) or poor solvents for increasing a viscosity, low-molecular-weight polymer compounds for decreasing a viscosity and surfactants for decreasing a surface tension may be used with appropriately combining each other.

The above-mentioned high-molecular-weight polymer compounds may be the one which can be dissolved in the same solvent to be used for the polymer material of the present invention and never inhibits the light emission and electron transportation. For example, high-molecular-weight polystyrene or polymethylmethacrylate, or the polymer material of the present invention having a high molecular weight may be used. The weight-average molecular weight is preferably 500000 or more, and more preferably 1000000 or more. The poor solvent can be used as a thickener. That is, adding a small amount of the solvent which is poor to the solid component in the solution may increase the viscosity. When adding a poor solvent for such purpose, the kind of the solvent and the amount thereof to be added may be selected within the range of not causing a precipitation of the solid contained in the solution. With consideration of stability during preservation, the amount of the poor solvent is preferably 50 wt % or less with respect to the total solution, and more preferably 30 wt % or less.

As the antioxidant, may be the one which can be dissolve to the same solvent to be used for the polymer material of the present invention and never inhibit the light emission and electron transportation, being exemplified with phenolic antioxidants, phosphorus antioxidants and the like. The use of the antioxidant can improve the preservation stability of the polymer material of the present invention and solvent.

In view of the solubility of the polymer material of the present invention in a solvent, a difference of the solubility parameter of the solvent and that of the polymer material is preferably 10 or less, and more preferably 7 or less. The solubility parameter of the solvent and that of the polymer material of the present invention can be determined with the method described in “YOUZAI (Solvent) Handbook (published by Kodansha Ltd., 1976)”.

The polymer materials of the present invention contained in the ink composition may be one kind or 2 or more kinds thereof, and may contain a polymer compound other than the polymer material of the present invention within a range of not injuring a device characteristics.

Regarding the thickness of the light emitting layer, the optimum value differs depending on material used, and may properly be selected so that the driving voltage and the light emitting efficiency become optimum values, and for example, it is from 1 nm to 1 μm, preferably from 2 nm to 500 nm, further preferably from 5 nm to 200 nm.

In the polymer LED of the present invention, light emitting materials other than the light emitting material of the present invention or light emitting material polymer complex compound can also be mixed in a light emitting layer. Further, in the polymer LED of the present invention, the light emitting layer containing light emitting materials other than the above light emitting material may also be laminated with a light emitting layer containing the above light emitting material of the present invention.

As the light emitting material, known materials can be used. In a compound having lower molecular weight, there can be used, for example, naphthalene derivatives, anthracene or derivatives thereof, perylene or derivatives thereof; dyes such as polymethine dyes, xanthene dyes, coumarine dyes, cyanine dyes; metal complexes of 8-hydroxyquinoline or derivatives thereof, aromatic amine, tetraphenylcyclopentane or derivatives thereof, or tetraphenylbutadiene or derivatives thereof, and the like.

Specifically, there can be used known compounds such as those described in JP-A Nos. 57-51781, 59-194393 and the like, for example.

When the polymer LED of the present invention has a hole transporting layer, as the hole transporting materials used, there are exemplified polyvinylcarbazole or derivatives thereof, polysilane or derivatives thereof, polysiloxane derivatives having an aromatic amine in the side chain or the main chain, pyrazoline derivatives, arylamine derivatives, stilbene derivatives, triphenyldiamine derivatives, polyaniline or derivatives thereof, polythiophene or derivatives thereof, polypyrrole or derivatives thereof, poly(p-phenylenevinylene) or derivatives thereof, poly(2,5-thienylenevinylene) or derivatives thereof, or the like.

Specific examples of the hole transporting material include those described in JP-A Nos. 63-70257, 63-175860, 2-135359, 2-135361, 2-209988, 3-37992 and 3-152184.

Among them, as the hole transporting materials used in the hole transporting layer, preferable are polymer hole transporting materials such as polyvinylcarbazole or derivatives thereof, polysilane or derivatives thereof, polysiloxane derivatives having an aromatic amine compound group in the side chain or the main chain, polyaniline or derivatives thereof, polythiophene or derivatives thereof, poly(p-phenylenevinylene) or derivatives thereof, poly(2,5-thienylenevinylene) or derivatives thereof, or the like, and further preferable are polyvinylcarbazole or derivatives thereof, polysilane or derivatives thereof and polysiloxane derivatives having an aromatic amine compound group in the side chain or the main chain. In the case of a hole transporting material having lower molecular weight, it is preferably dispersed in a polymer binder for use.

Polyvinylcarbazole or derivatives thereof are obtained, for example, by cation polymerization or radical polymerization from a vinyl monomer.

As the polysilane or derivatives thereof, there are exemplified compounds described in Chem. Rev., 89, 1359 (1989) and GB 2300196 published specification, and the like. For synthesis, methods described in them can be used, and a Kipping method can be suitably used particularly.

As the polysiloxane or derivatives thereof, those having the structure of the above-described hole transporting material having lower molecular weight in the side chain or main chain, since the siloxane skeleton structure has poor hole transporting property. Particularly, there are exemplified those having an aromatic amine having hole transporting property in the side chain or main chain.

The method for forming a hole transporting layer is not restricted, and in the case of a hole transporting layer having lower molecular weight, a method in which the layer is formed from a mixed solution with a polymer binder is exemplified. In the case of a polymer hole transporting material, a method in which the layer is formed from a solution is exemplified.

The solvent used for the film forming from a solution is not particularly restricted providing it can dissolve a hole transporting material. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like, from a solution.

The polymer binder mixed is preferably that does not disturb charge transport extremely, and that does not have strong absorption of a visible light is suitably used. As such polymer binder, polycarbonate, polyacrylate, poly(methyl acrylate), poly(methyl methacrylate), polystyrene, poly(vinyl chloride), polysiloxane and the like are exemplified.

Regarding the thickness of the hole transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the hole transporting layer is, for example, from 1 nm to 1 μm, preferably from 2 nm to 500 nm, further preferably from 5 nm to 200 nm.

When the polymer LED of the present invention has an electron transporting layer, known compounds are used as the electron transporting materials, and there are exemplified oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinoline derivatives, or metal complexes of 8-hydroxyquinoline or derivatives thereof, polyquinoline and derivatives thereof, polyquinoxaline and derivatives thereof, polyfluorene or derivatives thereof, and the like.

Specifically, there are exemplified those described in JP-A Nos. 63-70257, 63-175860, 2-135359, 2-135361, 2-209988, 3-37992 and 3-152184.

Among them, oxadiazole derivatives, benzoquinone or derivatives thereof, anthraquinone or derivatives thereof, or metal complexes of 8-hydroxyquinoline or derivatives thereof, polyquinoline and derivatives thereof, polyquinoxaline and derivatives thereof, polyfluorene or derivatives thereof are preferable, and 2-(4-biphenyl)-5-(4-t-butylphenyl)-1,3,4-oxadiazole, benzoquinone, anthraquinone, tris(8-quinolinol)aluminum and polyquinoline are further preferable.

The method for forming the electron transporting layer is not particularly restricted, and in the case of an electron transporting material having lower molecular weight, a vapor deposition method from a powder, or a method of film-forming from a solution or melted state is exemplified, and in the case of a polymer electron transporting material, a method of film-forming from a solution or melted state is exemplified, respectively. In case of the film-forming from a solution or molten state, a polymer binder may be used together.

The solvent used in the film-forming from a solution is not particularly restricted provided it can dissolve electron transporting materials and/or polymer binders. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film-forming method from a solution or melted state, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

The polymer binder to be mixed is preferably that which does not extremely disturb a charge transport property, and that does not have strong absorption of a visible light is suitably used. As such polymer binder, poly(N-vinylcarbazole), polyaniline or derivatives thereof, polythiophene or derivatives thereof, poly(p-phenylene vinylene) or derivatives thereof, poly(2,5-thienylene vinylene) or derivatives thereof, polycarbonate, polyacrylate, poly(methyl acrylate), poly(methyl methacrylate), polystyrene, poly(vinyl chloride), polysiloxane and the like are exemplified.

Regarding the thickness of the electron transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the electron transporting layer is, for example, from 1 nm to 1 μm, preferably from 2 nm to 500 nm, further preferably from 5 nm to 200 nm.

The substrate forming the polymer LED of the present invention may preferably be that does not change in forming an electrode and layers of organic materials, and there are exemplified glass, plastics, polymer film, silicon substrates and the like. In the case of a opaque substrate, it is preferable that the opposite electrode is transparent or semitransparent.

Usually, at least one of the electrodes consisting of an anode and a cathode, is transparent or semitransparent. It is preferable that the anode is transparent or semitransparent.

As the material of this anode, electron conductive metal oxide films, semitransparent metal thin films and the like are used. Specifically, there are used indium oxide, zinc oxide, tin oxide, and composition thereof, i.e. indium/tin/oxide (ITO), and films (NESA and the like) fabricated by using an electron conductive glass composed of indium/zinc/oxide, and the like, and gold, platinum, silver, copper and the like. Among them, ITO, indium/zinc/oxide, tin oxide are preferable. As the fabricating method, a vacuum vapor deposition method, sputtering method, ion plating method, plating method and the like are used. As the anode, there may also be used organic transparent conducting films such as polyaniline or derivatives thereof, polythiophene or derivatives thereof and the like.

The thickness of the anode can be appropriately selected while considering transmission of a light and electric conductivity, and for example, from 10 nm to 10 μm, preferably from 20 nm to 1 μm, further preferably from 50 nm to 500 nm.

Further, for easy charge injection, there may be provided on the anode a layer comprising a phthalocyanine derivative conducting polymers, carbon and the like, or a layer having an average film thickness of 2 nm or less comprising a metal oxide, metal fluoride, organic insulating material and the like.

As the material of a cathode used in the polymer LED of the present invention, that having lower work function is preferable. For example, there are used metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, or alloys comprising two of more of them, or alloys comprising one or more of them with one or more of gold, silver, platinum, copper, manganese, titanium, cobalt, nickel, tungsten and tin, graphite or graphite intercalation compounds and the like. Examples of alloys include a magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The cathode may be formed into a laminated structure of two or more layers.

The thickness of the cathode can be appropriately selected while considering transmission of a light and electric conductivity, and for example, from 10 nm to 10 μm, preferably from 20 nm to 1 μm, further preferably from 50 nm to 500 nm.

As the method for fabricating a cathode, there are used a vacuum vapor deposition method, sputtering method, lamination method in which a metal thin film is adhered under heat and pressure, and the like. Further, there may also be provided, between a cathode and an organic layer, a layer comprising an conducting polymer, or a layer having an average film thickness of 2 nm or less comprising a metal oxide, metal fluoride, organic insulation material and the like, and after fabrication of the cathode, a protective layer may also be provided which protects the polymer LED. For stable use of the polymer LED for a long period of time, it is preferable to provide a protective layer and/or protective cover for protection of the device in order to prevent it from outside damage.

As the protective layer, there can be used a polymeric compound, metal oxide, metal fluoride, metal borate and the like. As the protective cover, there can be used a glass plate, a plastic plate the surface of which has been subjected to lower-water-permeation treatment, and the like, and there is suitably used a method in which the cover is pasted with an device substrate by a thermosetting resin or light-curing resin for sealing. If space is maintained using a spacer, it is easy to prevent an device from being injured. If an inner gas such as nitrogen and argon is sealed in this space, it is possible to prevent oxidation of a cathode, and further, by placing a desiccant such as barium oxide and the like in the above-described space, it is easy to suppress the damage of an device by moisture adhered in the production process. Among them, any one means or more are preferably adopted.

The polymer LED of the present invention can be used for a flat light source, a segment display, a dot matrix display, and a liquid crystal display as a back light, etc.

For obtaining light emission in plane form using the polymer LED of the present invention, an anode and a cathode in the plane form may properly be placed so that they are laminated each other. Further, for obtaining light emission in pattern form, there is a method in which a mask with a window in pattern form is placed on the above-described plane light emitting device, a method in which an organic layer in non-light emission part is formed to obtain extremely large thickness providing substantial non-light emission, and a method in which any one of an anode or a cathode, or both of them are formed in the pattern. By forming a pattern by any of these methods and by placing some electrodes so that independent on/off is possible, there is obtained a display device of segment type which can display digits, letters, simple marks and the like. Further, for forming a dot matrix device, it may be advantageous that anodes and cathodes are made in the form of stripes and placed so that they cross at right angles. By a method in which a plurality of kinds of polymeric compounds emitting different colors of lights are placed separately or a method in which a color filter or luminescence converting filter is used, area color displays and multi color displays are obtained. A dot matrix display can be driven by passive driving, or by active driving combined with TFT and the like. These display devices can be used as a display of a computer, television, portable terminal, portable telephone, car navigation, view finder of a video camera, and the like.

Further, the above-described light emitting device in plane form is a thin self-light-emitting one, and can be suitably used as a flat light source for back-light of a liquid crystal display, or as a flat light source for illumination. Further, if a flexible plate is used, it can also be used as a curved light source or a display.

The polymer material of the present invention can be applied to a semiconductor material; with the same method as producing the above-mentioned light-emitting material device, being formed to a film for making a device, and it is preferable that an electron mobility or hole mobility of the semiconductor thin film, whichever is greater, has a value of 10⁻⁵ cm²/V/sec.

Next, as another embodiment of the present invention, a photoelectric device is explained.

The photoelectric device, for example, includes photoelectric conversion devices which are exemplified with a device interposing a layer of the polymer material of the present invention between two pairs of electrodes at least one of which is transparent or translucent or a device having a comb-shape electrode produced on a layer of the polymer material formed on a substrate. To enhance the characteristics thereof, a fullerene, a carbon nanotube and the like may be mixed.

As the method of producing the photoelectric conversion device, exemplified is a method disclosed in U.S. Pat. No. 3,146,296. Specifically, exemplified are the method of forming a polymer thin film on a substrate having a first electrode and forming a second electrode thereon, and the method of forming a polymer thin film on a pair of comb-shape electrode produced on a substrate. Any one of the first or second electrodes is transparent or translucent. The method of forming the polymer thin film and mixing the fullerene or carbon nanotube is not particularly limited; the method exemplified in the light-emitting device can be suitably applied.

In the followings, Examples are illustrated to explain the present invention in more detail, however, the present invention is not limited thereto.

Herein, polystyrene-reduced number-average molecular weight was determined with using tetrahydrofuran as a solvent with gel permeation chromatography (GPC: HLC-8220GPC manufactured by Tosoh Corporation, or SCL-10A manufactured by Shimadzu Corporation).

### EXAMPLE 1

Prepared was 1.8 wt % toluene solution of the mixture in which the following Polymer Compound I-1 was added with the following Dendrimer (D-1) in an amount of 40 wt %.

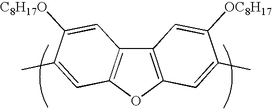

On a glass substrate having ITO film of 150 nm thick formed with a sputtering method, a film was formed in a thickness of 50 nm with a spin coating with using a poly(ethylenedioxythiophene)/polystyrene sulfonic acid solution (Bayer A.G. BaytronP), and then dried on a hot plate at 200° C. for 10 minutes. Thereafter, with using the above-prepared chloroform solution, a film was formed with a spin coating at a rotation speed of 1000 rpm. The resulting film thickness was 100 nm. Furthermore, this film, after being dried under a reduced pressure at 80° C. for 1 hour, was vapor-deposited with LiF with about 4 nm thick as a cathode buffer layer, calcium with about 5 nm thick as a cathode, and subsequently aluminum with about 80 nm thick to produce an EL device. Herein, the metal vapor-deposition was commenced after the vacuum degree had reached to 1×10⁻⁴ Pa or lower. With applying a voltage to the device obtained, an EL light emission having a peak at 520 nm was obtained. The device exhibited a light emission of 100 cd/m² at about 5 V and had a maximum brightness of 30000 cd/m² or more. In addition, the maximum light emission efficiency was 36 cd/A.

Furthermore, lowest excited triplet energies of Polymer Compound 1-1 and Dendrimer (D-1) calculated with computational chemical means were 2.82 eV and 2.71 eV, respectively.

In the calculation, the chemical structures applied to the calculation were defined as the following (1-1M) for Polymer Compound (1-1), and as the following D-1M for Dendrimer (D-1).

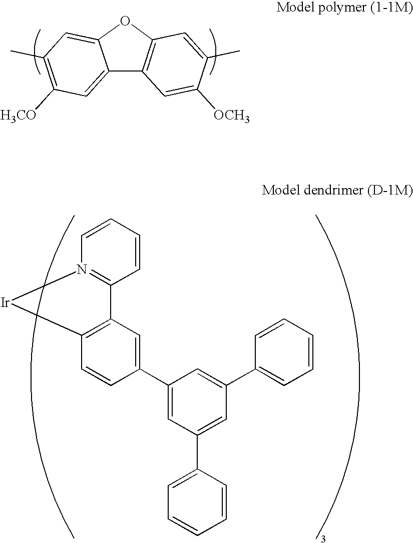

were defined, and the calculation was carried out with the method described in the detail explanation of the invention.

Specifically, Model dendrimer (D-1M) and Model polymer 1-1M were firstly subjected to a structural optimization with a Hatree-Fock (HF) method. In this optimization, as basis functions, lan12dz was applied to the iridium atom contained in Model dendrimer (D-1M), and 6-31 g* was applied to the other atoms in Model dendrimer (D-1M) and to Polymer Compound 1-1. Furthermore, for the optimized structure, with using the same bases as in the structural optimization, with a Time Dependent Density Functional Theory (TDDFT) at b3p86 level, a lowest excited singlet energy, lowest excited triplet energy, HOMO value and LUMO value were determined. The validity of simplifying the chemical structures applied to the calculation as above was confirmed in advance as follows.

After, in place of the side chain OC₈H₁₇ of Polymer Compound I-1, assuming OCH₃, OC₃H₇, OC₅H₁₁, and OC₈H₁₇ as the side chain, a HOMO value at the ground state, LUMO value at the ground state, lowest excited singlet energy and lowest excited triplet energy were calculated with the HF method with applying the above-mentioned basis function 6-31 g*, the calculation results were as follows.

TABLE 1

| | OC1H3 | OC3H7 | OC5H11 | OC8H17 |
|---|---|---|---|---|
| HOMO (eV) | −6.15 | −6.10 | −6.10 | −6.07 |
| LUMO (eV) | −1.44 | −1.39 | −1.38 | −1.37 |
| Lowest Excited | 4.17 | 4.16 | 4.16 | 4.16 |
| Singlet Energy | | | | |
| (eV) | | | | |
| Lowest Excited | 3.20 | 3.19 | 3.19 | 3.19 |
| Triplet Energy | | | | |
| (eV) | | | | |

According to the results, in the calculation carried out with the above calculation method, it is understood that the side chain length dependency of the HOMO value, LUMO value, lowest excited singlet energy and lowest excited triplet energy is small. Therefore, for Polymer Compound 1-1, the calculation was carried out after simplifying the side chain of the chemical structure to be calculated to OCH₃. Furthermore, regarding to the dendrimer, when a lowest excited triplet energy of the following complex (Complex 1) was calculated, the result was 2.76 eV, which was as almost same as the value of (D-1M) bonding with the dendron, therefore, it was confirmed that the dendron seldom affected to the lowest excited triplet energy.

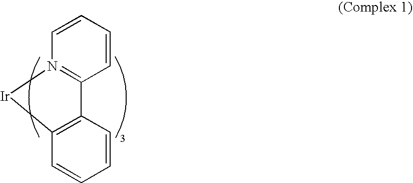

Polymer Compound (1-1) was synthesized according to a method disclosed in EP1344788 (polystyrene-reduced number-average molecular weight was Mn=1.1×10⁵, the weight-average molecular weight was Mw=2.7×10⁵). Dendrimer (D-1) was synthesized according to a method disclosed in WO02/066552.

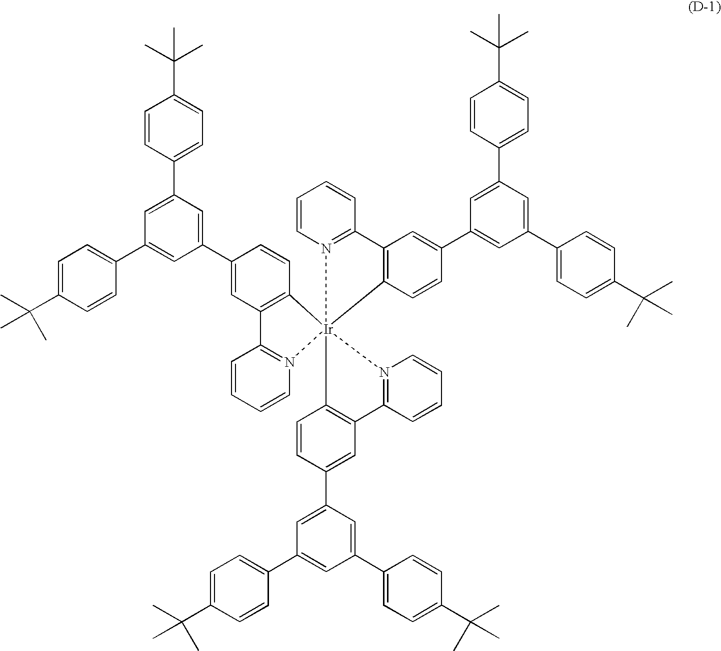

### EXAMPLE 2

After preparing 1.5 wt % toluene solution of the mixture in which the above-mentioned Polymer Compound 1-1 was added with the following Dendrimer (D-2) in an amount of 2 wt %, a device was produced in the same manner as in Example 1. A rotation number of a spin coater at the time of forming a film was 2000 rpm, and a film thickness was about 95 nm. With applying a voltage to the device obtained, an EL light emission having a peak at 625 nm was obtained. The device exhibited a light emission of 100 cd/m₂ at about 10 V. In addition, the maximum light emission efficiency was 4.9 cd/A.

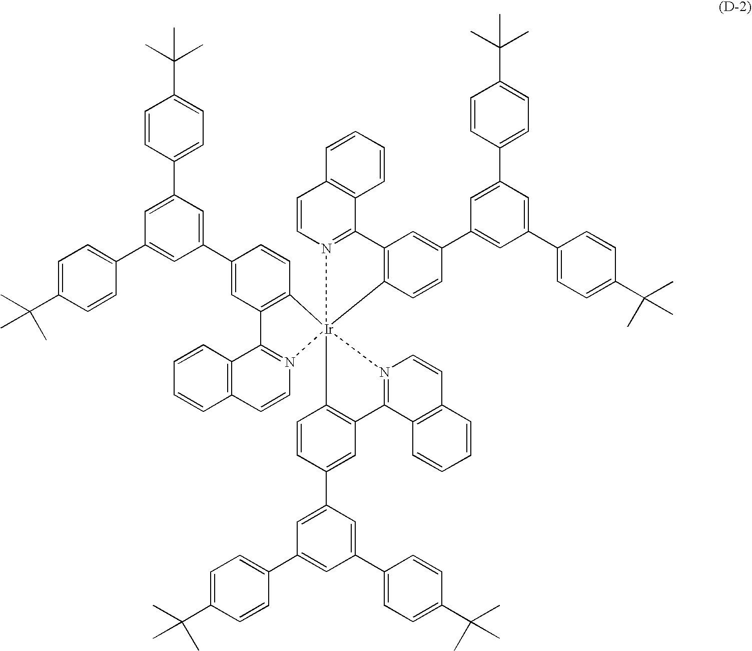

A lowest excited triplet energy of Dendrimer (D-2) obtained in the same manner as in Example 1 was 2.3 eV. For the calculation, the following molecule (D-2M) was used as a model. Model dendrimer (D-2M)

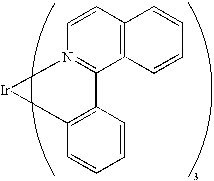

Dendrimer (D-2) was synthesized according to the method disclosed in WO02/066552.

### EXAMPLE 3

After preparing 1.0 wt % toluene solution of the mixture in which the following Polymer Compounds (1-2) and (3-1) and Dendrimer (D-2) described in Example 2 were mixed in a ratio (weight ratio) of 76:19:5, a device was produced in the same manner as in Example 1. A rotation number of a spin coater at the time of forming a film was 2200 rpm, and a film thickness was about 90 nm.

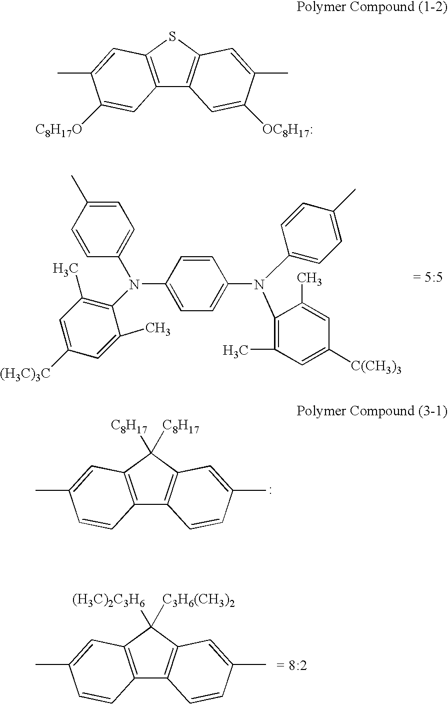

With applying a voltage to the device obtained, an EL light emission having a peak at 625 nm was obtained. The device exhibited a light emission of 100 cd/m² at about 5 V. In addition, the maximum light emission efficiency was 4.7 cd/A.

Polymer Compound (1-2) was synthesized according to a method disclosed in Kokai (Japan unexamined patent publication) No. 2004-143419. The polystyrene-reduced number-average molecular weight of this Polymer Compound (1-2) was Mn=1.2×10⁴, and the weight-average molecular weight was Mw=7.7×10⁴. Polymer Compound (3-1) was synthesized according to a method disclosed in Kokai No. 2004-002654, the polystyrene-reduced number-average molecular weight thereof was Mn=3.5×10⁵, and the weight-average molecular weight was Mw=1.1×10⁶.

### EXAMPLE 4

The following Polymer Compound (1-3) having a dendrimer at the end thereof was synthesized. After preparing 2.0 wt % toluene solution of Polymer Compound (1-3), a device was produced in the same manner as in Example 1. A rotation number of a spin coater at the time of forming a film was 1000 rpm, and a film thickness was about 100 nm.

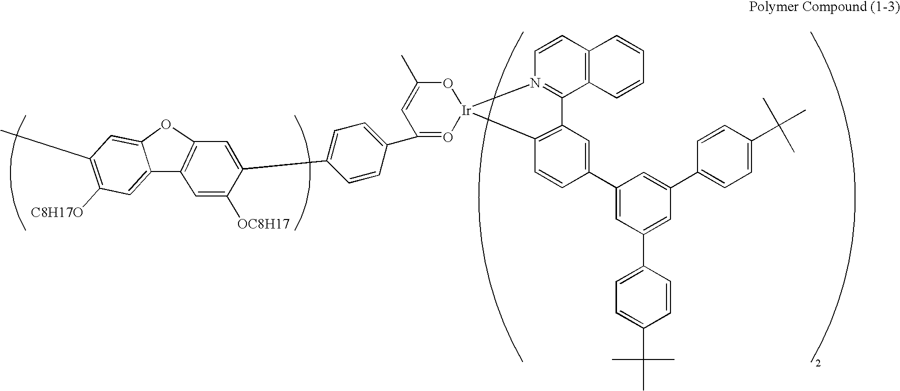

With applying a voltage to the device obtained, an EL light emission having a peak at 630 nm was obtained. Polymer Compound (1-3) was synthesized as follows.

After charging 57 mg (0.038 mmol) of the following Compound A, 852 mg (1.463 mmol) of 2,7-dibromo-3,6-octyloxydibenzofuran and 562 mg of 2,2′-bipyridyl in a reactor, the inside of the reaction system was replaced with nitrogen gas. To this mixture, added was 45 ml of tetrahydrofuran (dehydrating solvent) which was deaerated in advance with bubbling with argon gas. Thereafter, this mixed solution was added with 990 mg of bis(1,5-cyclooctadiene)nickel(0) (Ni(COD)₂), and agitated at a room temperature for 30 minutes, followed by reaction at 60° C. for 3.3 hours. The reaction was carried out under a nitrogen gas atmosphere. After the reaction, this solution was cooled down, and then poured into a mixed solution consisting of 45 ml of methanol/45 ml of ion-exchanged water/5.4 ml of 25% aqueous ammonium, followed by agitation for about 2 hours. Thereafter, the precipitate generated was collected with a filtration. After drying this precipitate under a reduced pressure, the precipitate was dissolved in toluene. After filtrating this solution to remove the insoluble, this solution was purified with passing through a column packed with alumina. Thereafter, this solution was washed with 1 normal hydrochloric acid, 2.5% aqueous ammonium, and ion-exchanged water, and then poured into methanol to reprecipitate, and then the precipitate generated was collected. This precipitate was dried under a reduced pressure to obtain a 230 mg of Polymer Compound (1-2).

The polystyrene-reduced number-average molecular weight of this Polymer Compound (1-2) was Mn=3.6×10⁴, and the weight-average molecular weight was Mw=7.8×10⁴.

### A Method of Synthesizing Compound A

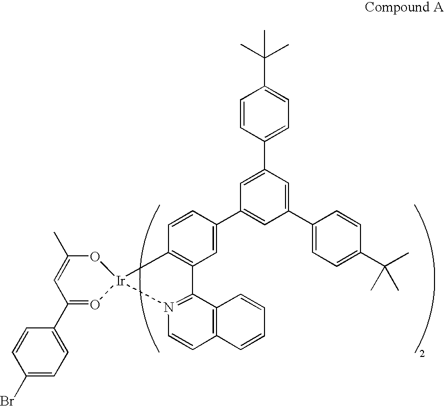

Compound A was synthesized as follows.

Under an argon atmosphere, 1.05 g (0.4 mmol) of Compound A-3, 0.29 g (1.2 mmol) of Compound A-1, 0.25 g of sodium carbonate and 20 ml of 2-ethoxyethanol were charged, and deaerated with argon, followed by reaction at a room temperature for 7 hours. The reactant, after distilling off the solvent therefrom, was added with chloroform/hexane=1/1 to pass through a silica gel column. The filtrate obtained was condensed. After dissolving the purplish red color powder obtained in toluene, the solution was passed through a silica gel column, and the filtrate obtained was condensed to obtain 0.45 g (yield: 37%) of a purplish red color powder.

¹H-NMR (300 MHz/CDCl₃):

δ 9.08 (d, 2H), 8.54 (m, 4H), 7.92 (bd, 2H), 7.40-7.80 (m, 30H), 7.34 (d, 2H), 7.06 (m, 2H), 6.60 (d, 2H), 5.87 (s, 1H), 1.94 (s, 3H), 1.36 (s, 36H)

MS (APCI(+)): (M+H)⁺ 1521

### Compound A-1

Under an argon atmosphere, 1.73 g (7.2 mmol) of NaH was charged, and then cooled in an ice bath; and then being dropped with 60 ml of ethyl acetate solution of 7.96 g (40 mmol) 4-bromoacetophenone over 1 hour on the ice bath. Heating under refluxing was carried out to react for 4.5 hours. The reactant was cooled to a room temperature, and washed with 1N hydrochloric acid, and ion-exchanged water, followed by phase separation. The organic phase was dried with anhydrous salt cake, and condensed to obtain 7.35 g of a light orange color crude product. The crude was recrystallized with ethanol to obtain 3.37 g (yield: 35%) of white needlelike crystal.

¹H-NMR (300 MHz/CDCl₃):

δ2.20 (s, 3H), 6.14 (s, 1H), 7.60 (d, 2H), 7.74 (d, 2H), 16.1 (bs, 1H)

MS (APCI(+)): (M+H)⁺ 241

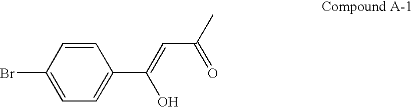

Compound A-2

The following compound was obtained according to the synthesis method disclosed in WO02/066552. Yield in amount 3.0 g (yield in rate 100%).

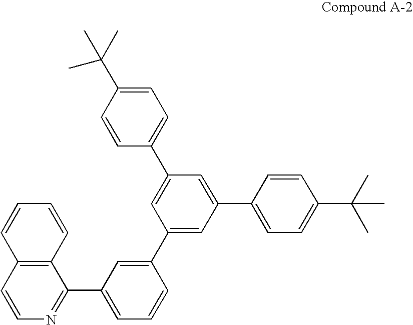

¹H-NMR (300 MHz/CDCl₃):

δ 8.71 (d, 1H), 8.24 (d, 1H), 8.10 (bs, 1H), 7.97 (d, 1H), 7.86-7.94 (m, 3H), 7.68-7.82 (m, 7H), 7.54 to 7.66 (m, 4H), 7.22-7.36 (m, 2H), 1.44 (s, 18H)

Compound A-3

Under an argon atmosphere, 1.92 g (3.5 mmol) of Compound A-2, 0.56 g (16 mmol) of IrCl₃.3H₂O, 15 ml of 2-EtOEtOH and 5 ml of ion-exchanged water were charged and refluxed for 7 hours. After charging an appropriate amount of ion-exchanged water, a solid precipitated was subjected to a vacuum filtration. The solid obtained was washed with ethanol, and ion-exchanged water, followed by drying to obtain 1.77 g (yield: 84%) of a red-brown color powder.

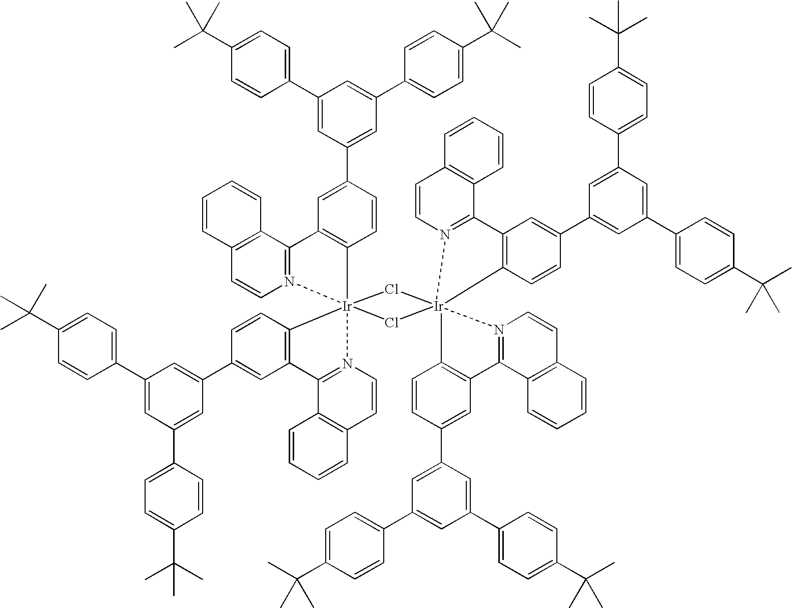

### EXAMPLE 5

The following Polymer Compound (1-4) having a dendrimer at the end thereof was synthesized. After preparing 2.0 wt % toluene solution of Polymer Compound (1-4), a device was produced in the same manner as in Example 1. A rotation number of a spin coater at the time of forming a film was 1100 rpm, and a film thickness was about 80 nm.

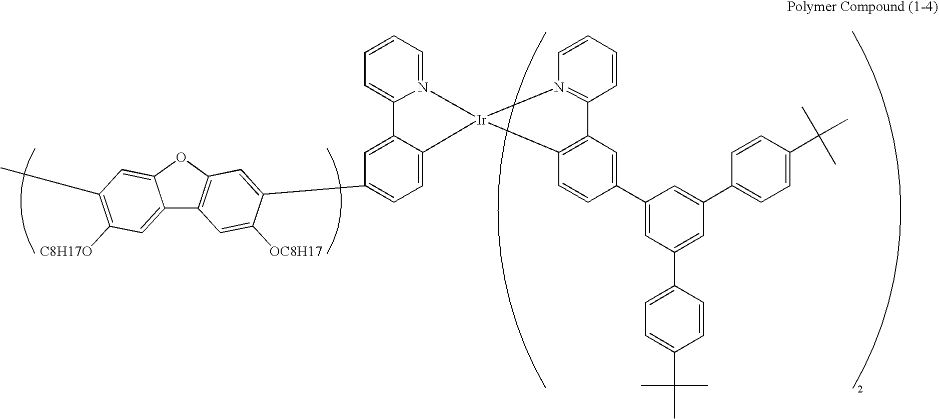

With applying a voltage to the device obtained, an EL light emission having a peak at 520 nm was obtained. The device exhibited a light emission of 100 cd/m² at about 9 V and had a maximum brightness of 6000 cd/m² or more. Polymer Compound (1-4) was synthesized as follows.

After charging 57 mg (0.040 mmol) of the following Compound B, 1.142 g (1.960 mmol) of 2,7-dibromo-3,6-octyloxydibenzofuran and 750 mg of 2,2′-bipyridyl in a reactor, the inside of the reaction system was replaced with nitrogen gas. To this mixture, added was 42 ml of tetrahydrofuran (dehydrating solvent) which was deaerated in advance with bubbling with argon gas. Thereafter, this mixed solution was added with 1.320 g of bis(1,5-cyclooctadiene)nickel(0) {Ni(COD)₂}, and agitated at a room temperature for 30 minutes, followed by reaction at 60° C. for 3.3 hours. The reaction was carried out under a nitrogen gas atmosphere. After the reaction, this solution was cooled down, and then poured into a mixed solution consisting of 42 ml of methanol/42 ml of ion-exchanged water/7.2 ml of 25% aqueous ammonium, followed by agitation for about 2 hours. Thereafter, the precipitate generated was collected with a filtration. After drying this precipitate under a reduced pressure, the precipitate was dissolved in toluene. After filtrating this solution to remove the insoluble, this solution was purified with passing through a column packed with alumina. Thereafter, this solution was washed with 1 normal hydrochloric acid, 2.5% aqueous ammonium, and ion-exchanged water, and then poured into methanol to reprecipitate, and then the precipitate generated was collected. This precipitate was dried under a reduced pressure to obtain a 760 mg of Polymer Compound (1-3).

The polystyrene-reduced number-average molecular weight of this Polymer Compound (1-3) was Mn=4.0×10⁴, and the weight-average molecular weight was Mw=8.6×10⁴.

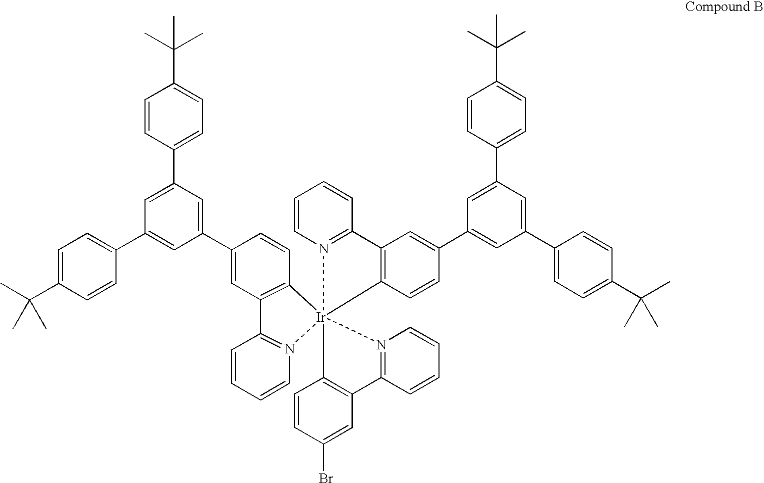

### Compound B was obtained according to the synthesis method disclosed in WO02/066552.

MALDI TOF MASS m/z=1414

### EXAMPLE 6

The following Polymer Compound (1-5) having a dendrimer at the end thereof was synthesized. After preparing 1.5 wt % toluene solution of Polymer Compound (1-5), a device was produced in the same manner as in Example 1. A rotation number of a spin coater at the time of forming a film was 2500 rpm, and a film thickness was about 75 nm.

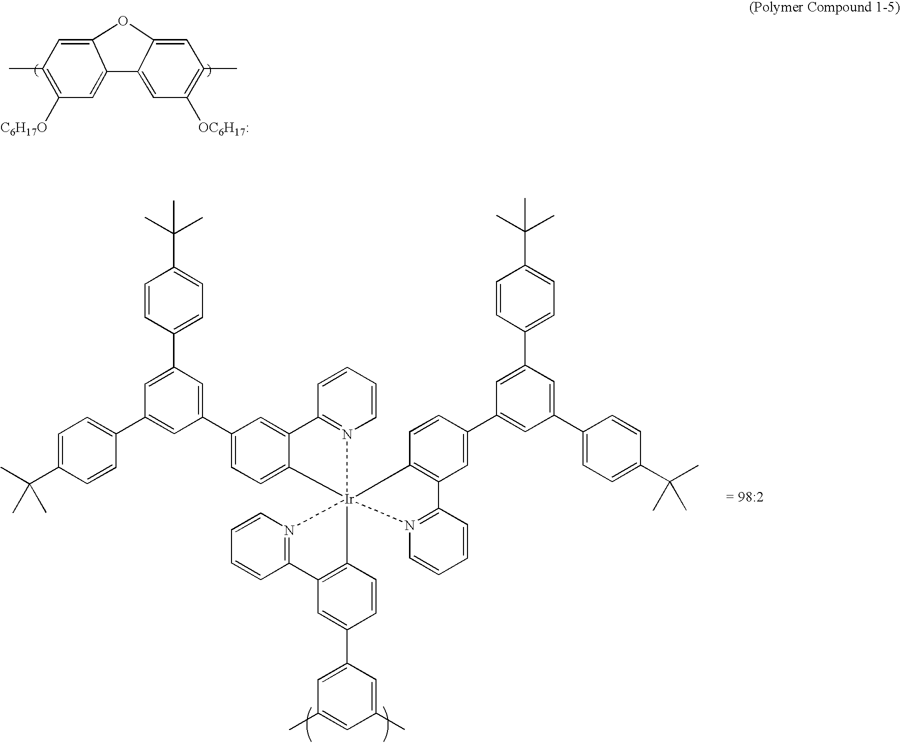

With applying a voltage to the device obtained, an EL light emission having a peak at 520 nm was obtained. The device exhibited a light emission of 100 cd/m² at about 8 V. In addition, the maximum light emission efficiency was 11 cd/A. Polymer Compound (1-5) was synthesized as follows.

After charging 25 mg (0.017 mmol) of the following Compound (C), 475 mg (0.82 mmol) of 2,7-dibromo-3,6-octyloxydibenzofuran and 351 mg of 2,2′-bipyridyl in a reactor, the inside of the reaction system was replaced with nitrogen gas. To this mixture, added was 35 ml of tetrahydrofuran (dehydrating solvent) which was deaerated in advance with bubbling with argon gas. Thereafter, this mixed solution was added with 618 mg of bis(1,5-cyclooctadiene)nickel(0) {Ni(COD)₂}, and agitated at a room temperature for 30 minutes, followed by reaction at 60° C. for 3.3 hours. The reaction was carried out under a nitrogen gas atmosphere. After the reaction, this solution was cooled down, and then poured into a mixed solution consisting of 15 ml of methanol/15 ml of ion-exchanged water/2.5 ml of 25% aqueous ammonium, followed by agitation for about 2 hours. Thereafter, the precipitate generated was collected with a filtration. After drying this precipitate under a reduced pressure, the precipitate was dissolved in toluene. After filtrating this solution to remove the insoluble, this solution was purified with passing through a column packed with alumina. Thereafter, this solution was washed with 1 normal hydrochloric acid, 2.5% aqueous ammonium, and ion-exchanged water, and then poured into methanol to reprecipitate, and then the precipitate generated was collected. This precipitate was dried under a reduced pressure to obtain a 140 mg of Polymer Compound (1-5).

The polystyrene-reduced number-average molecular weight of this polymer was 8.5×10⁴, and the polystyrene-reduced weight-average molecular weight was 6.7×10⁵.

Furthermore, 2,7-dibromo-3,6-octyloxydibenzofuran was synthesized according to the method disclosed in EP1344788.

Moreover, Compound C was synthesized as follows. In a four-necked flask, 0.1 g (0.5 mmol) of 3,5-dichlorophenylboric acid and 0.71 g (0.5 mmol) of the above-mentioned Compound B were charged, and subjected to an argon replacement. A solution of dissolving 30 ml of toluene, 10 ml of ethanol and 0.1 g (0.8 mmol) of potassium carbonate in 10 ml of ion-exchanged water was charged, and then subjected to an argon bubbling for 15 minutes. 0.01 g (0.01 mmol) of Pd(PPh₃)₄ was charged, and then further subjected to an argon bubbling for 5 minutes. Heating under refluxing was carried out for 7 hours.

A silica gel column purification (elution solution: chloroform/hexane=1/2) was carried out to obtain 580 mg of a yellow powder (yield 78%).

¹H-NMR (300 MHz/CDCl₃):

δ 1.38 (s, 36H), 6.95 to 7.00 (m, 3H), and 7.04 (s, 1H), 7.07 (s, 2H), 7.24-7.25 (m, 3H), 7.40-7.41 (m, 3H), 7.48 (d, 8H), 7.64 (d, 8H), 7.59 to 7.68 (m, 3H), 7.71 (s, 3H), 7.81-7.84 (m, 6H), 8.00 (s, 3H), 8.04 (d, 3H)

LC/MS: ESI method (posi KCl addition) [M+K]+=1518

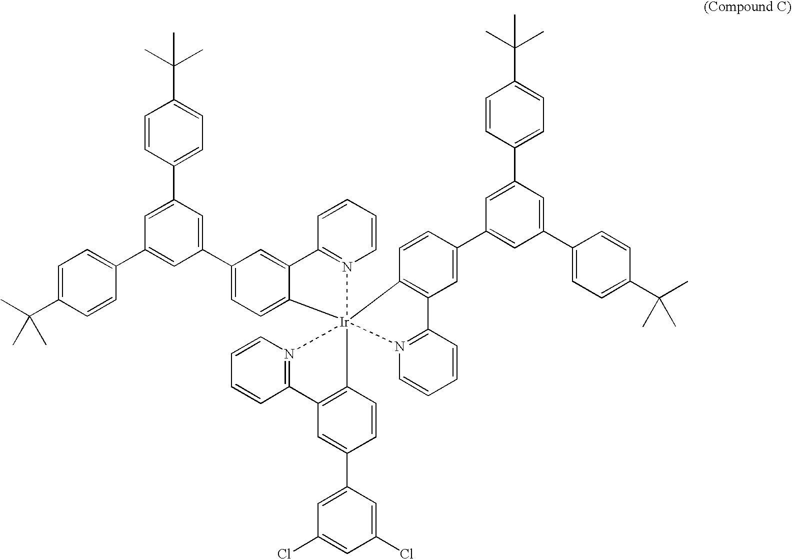

### INDUSTRIAL APPLICABILITY

A device applying the polymer material of the present invention is excellent in practical utilities such as a capability of driving at lower voltage and the like. Therefore, the polymer material of the present invention can be suitably used for light-emitting materials such as polymer LED and the like.

1. A polymer material comprising a conjugated polymer (A) and a dendrimer (B).

2. The polymer material according to claim 1 comprising a polymer containing a structure of the conjugated polymer (A) and a structure of the dendrimer (B) in the same molecule.

3. The polymer material according to claim 2 comprising a polymer containing a structure of the dendrimer (B) in the main chain of the conjugated polymer (A).

4. The polymer material according to claim 2 comprising a polymer containing a structure of the dendrimer (B) at the end of the conjugated polymer (A).

5. The polymer material according to claim 2 comprising a polymer containing a structure of the dendrimer (B) in the side chain of the conjugated polymer (A).

6. The polymer material according to claim 1 which is a composition comprising the conjugated polymer (A) and the dendrimer (B).

7. The polymer material according to claim 1 wherein the conjugated polymer (A) contains an aromatic ring in the main chain.

8. The polymer material according to claim 1 wherein the conjugated polymer (A) has a polystyrene-reduced number-average molecular weight of 10³ to 10⁸.

9. The polymer material according to claim 1 satisfying the following condition 1:
(Condition 1)
energy in the ground state (ES_{A0}) of the conjugated polymer (A), energy in the lowest excited triplet state (ET_{A}) of the conjugated polymer (A), energy in the ground state (ES_{B0}) of the dendrimer (B) and energy in the lowest excited triplet state (ET_{B}) of the dendrimer (B) satisfy the relation of
ET_{A}−ES_{A0}≧(ET_{B}−ES_{B0})−0.2 eV (Eq1).

10. The polymer material according to claim 1 wherein the conjugated polymer (A) contains at least one repeating unit of the following formula (1), formula (2), formula (3), formula (4) or formula (5) as a substituent: 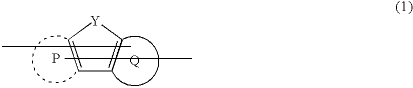
(wherein, the P ring and Q ring each independently represent an aromatic ring, but the P ring may be either existent or nonexistent. Two connecting bonds exist on the P ring and/or Q ring when the P ring exists, and exist on the 5-membered ring containing Y and/or Q ring when the P ring does not exist. Further, a substituent may exist on the aromatic ring and/or 5-membered ring containing Y. Y represents —O—, —S—, —Se—, —B(R₃₁)—, —C(R₁)(R₂)—, —Si (R₁)(R₂)—, —P(R₃)—, —PR₄(═O)—, —C(R₅₁)(R₅₂)—C(R₅₃)(R₅₄)—, —C(R₅₅)(R₅₆)—, —S—C(R₅₇)(R₅₈)—, —N—C(R₅₉)(R₆₀)—, —Si (R₆₁)(R₆₂)—C(R₆₃)(R₆₄)—, —Si(R₆₅)(R₆₆)—, Si (R₆₇)(R₆₈)—, —C(R₆₉)═C(R₇₀)—, —N═C(R₇₁)—, or —Si(R₇₂)═C(R₇₃)—, R₃₁ represents a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group or substituted silyloxy group, and R₁, to R₄ and R₅₁ to R₇₃ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, silyloxy group, substituted silyloxy group, monovalent heterocyclic group or halogen atom.) 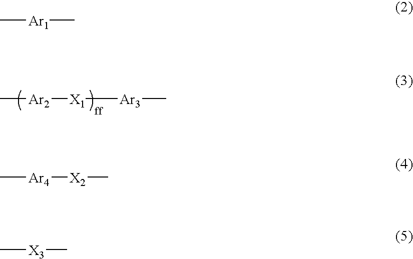
(wherein, Ar₁, Ar₂, Ar₃ and Ar₄ each independently represent an arylene group, divalent heterocyclic group or divalent group having a metal complex structure. X₁, X₂ and X₃ each independently represent —CR₁₃═CR₁₄—, —C═C—, —N(R₁₅)— or (SiR₁₆R₁₇)_{ff}—. R₁₃ and R₁₄ each independently represent a hydrogen atom, alkyl group, aryl group, monovalent heterocyclic group, carboxyl group, substituted carboxyl group or cyano group. R₁₅, R₁₆ and R₁₇ each independently represent a hydrogen atom, alkyl group, aryl group, monovalent heterocyclic group, arylalkyl group or substituted amino group. ff represents 1 or 2. m represents an integer of 1 to 12. When R₁₃, R₁₄, R₁₅, R₁₆ and R₁₇ are present each in plural number, they may be the same or different.).

11. The polymer material according to claim 10 wherein said repeating unit of the formula (1) has as a substituent a group selected from alkyl groups, alkoxy groups, alkylthio groups, aryl groups, aryloxy groups, arylthio groups, arylalkyl groups, arylalkoxy groups, arylalkylthio groups, arylalkenyl groups, arylalkynyl groups, amino group, substituted amino groups, silyl group, substituted silyl groups, acyloxy group, imine residue, amide group, acid imide group, monovalent heterocyclic group, carboxyl group and substituted carboxyl groups.

12. The polymer light-emitting material according to claim 10 wherein said repeating unit of the formula (1) is a repeating unit of the following formula (1-1), (1-2) or (1-3): 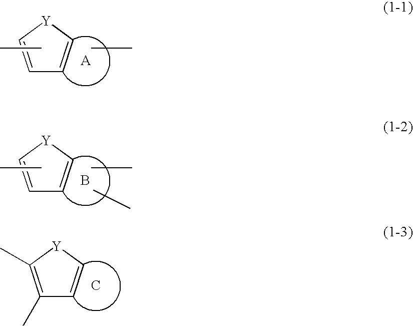
(wherein, the A ring, B ring and C ring each independently represent an aromatic ring optionally having a substituent. The formula (1-1), formula (1-2) and (1-3) may each have a substituent. Y represents the same meaning as described above.).

13. The polymer material according to claim 10 wherein said repeating unit of the formula (1) is a repeating unit of the following formula (1-4) or (1-5): 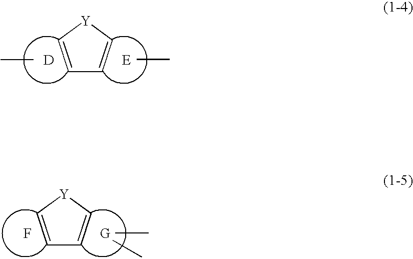
(wherein, the D ring, E ring, F ring and G ring each independently represent an aromatic ring optionally having a substituent, and Y represents the same meaning as described above.).

14. The polymer material according to claim 10 wherein the P ring, Q ring, A ring, B ring, C ring, D ring, E ring, F ring and G ring represent an aromatic hydrocarbon ring.

15. The polymer material according to claim 13 wherein said repeating unit of the formula (1-4) is a repeating unit selected from the following formulae (1-6), (1-7) and (1-8): 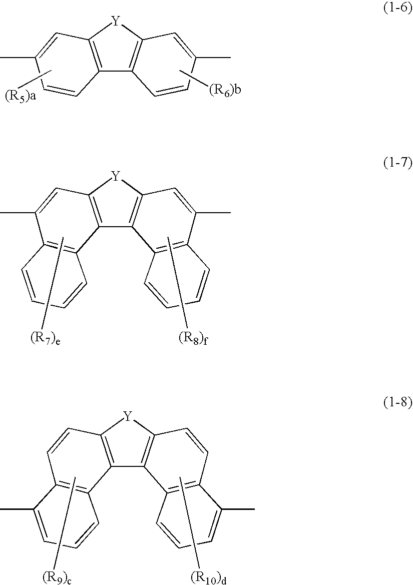
(wherein, R₅ to R₁₀ each independently represent an alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, acyloxy group, imine residue, amide group, acid imide group, monovalent heterocyclic group, carboxyl group or substituted carboxyl group. a and b each independently represent an integer of 0 to 3. c, d, e and f each independently represent an integer of 0 to 5. When R₅ to R₁₀ are present each in plural number, they may be the same or different. Y represents the same meaning as described above.).

16. The polymer material according to claim 10 wherein Y represents —O—, —S— or —C(R₁)(R₂)—:
(wherein, R₁ and R₂ represent the same meaning as described above.).

17. The polymer material according to claim 11 comprising said repeating unit of the formula (1) and at least one unit selected from said repeating units of the formula (2), formula (3), formula (4) or formula (5).

18. The polymer material according to claim 10 wherein said repeating unit of the formula (3) is a repeating unit of the following formula (6): 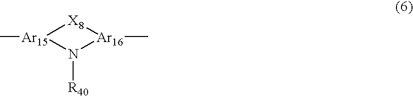
[wherein, Ar₁₅ and Ar₁₆ each independently represent a trivalent aromatic hydrocarbon group or trivalent heterocyclic group, R₄₀ represents an alkyl group, alkoxy group, alkylthio group, alkylsilyl group, alkylamino group, aryl group optionally having a substituent or monovalent heterocyclic group, and X represents a single bond or any of the following groups: 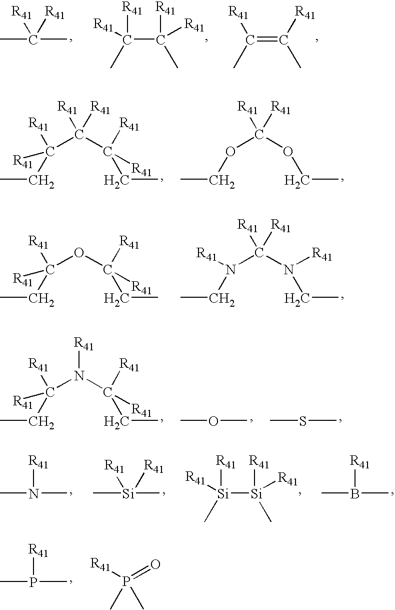
(wherein, R₄₁s each independently represent a hydrogen atom, alkyl group, alkoxy group, alkylthio group, aryl group, aryloxy group, arylthio group, arylalkyl group, arylalkoxy group, arylalkylthio group, arylalkenyl group, arylalkynyl group, amino group, substituted amino group, silyl group, substituted silyl group, halogen atom, acyl group, acyloxy group, imino group, amide group, imide group, monovalent heterocyclic group, carboxyl group, substituted carboxyl group or cyano group. When a plurality of R₄₁s are present, they may be the same or different.)].

19. The polymer material according to claim 10 wherein said repeating unit of the formula (4) is a repeating unit of the following formula (7): 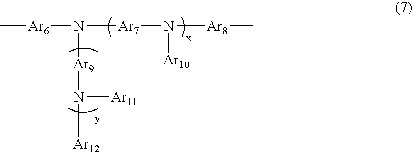
[wherein, Ar₆, Ar₇, Ar₈ and Ar₉ each independently represent an arylene group or divalent heterocyclic group. Ar₁₀, Ar₁₁ and Ar₁₂ each independently represent an arylene group or monovalent heterocyclic group. Ar₆, Ar₇, Ar₈, Ar₉ and Ar₁₀ may have a substituent. x and y each independently represent 0 or 1, and 0=x+y=1).

20. A light-emitting material comprising the polymer material according to claim 1.

21. The polymer material according to claim 1 wherein the dendrimer is represented by the following general formula (8):
CORE-[D¹]_{Z1}[D²]_{Z2} (8)
(wherein, CORE represents a (Z1+Z2)-valent atom or atomic group, and Z1 and Z2 represent an integer of 1 or more. D¹ and D² each independently represent a dendritic structure, and when D¹ and D² are present each in plural number, they may be the same or different, and at least one of D¹ and D² is a conjugated system, and contains an aromatic ring optionally having a hetero atom.).

22. The polymer material according to claim 21 wherein said CORE of the general formula (8) contains at least one of stilbene, aromatic condensed ring, heterocycle, condensed ring having a heterocycle, and metal complex structure.

23. The polymer material according to claim 21 wherein at least one of surface groups on the dendrimer is other than a hydrogen atom.

24. The polymer material according to claim 21 wherein at least one of surface groups on the dendrimer is fluorine, chlorine, bromine or iodine.

25. The polymer material according to claim 1 wherein the dendrimer has a metal complex as a partial structure.

26. The polymer material according to claim 1 further comprising at least one material selected from hole transporting materials, electron transporting materials and light-emitting materials.

27. A semiconductor material comprising the polymer material according to claim 1.

28. An ink composition comprising at least one of the polymer material according to claim 1.

29. The ink composition according to claim 28 wherein its viscosity is 1 to 100 mPa·s at 25° C.

30. A device having a layer containing the polymer material according to claim 1 between electrodes composed of an anode and a cathode.

31. The device according to claim 30 further comprising a charge transporting layer between electrodes composed of an anode and a cathode.

32. The device according to claim 30 wherein the device is a polymer light-emitting device.

33. The device according to claim 30 wherein the device is a photoelectric device.
